(19) United States
(12) Patent Application Publication
(10) Pub. No.: US 2023/0345819 A1
(43) Pub. Date: Oct. 26, 2023

(54) DISPLAY DEVICE

(71) Applicant: Samsung Display Co., Ltd., Yongin-si (KR)

(72) Inventors: BOHUN PARK, Yongin-si (KR); HYUNGU KIM, Yongin-si (KR); JAEJIN LEE, Yongin-si (KR); SEULONG KIM, Yongin-si (KR); SEOKJAE LEE, Yongin-si (KR); JIN WOO PARK, Yongin-si (KR)

(73) Assignee: Samsung Display Co., Ltd., Yongin-si (KR)

(21) Appl. No.: 18/116,083

(22) Filed: Mar. 1, 2023

(30) Foreign Application Priority Data
Apr. 26, 2022 (KR) 10-2022-0051623

(51) Int. Cl. H10K 85/60; H10K 85/40; H10K 50/15; H10K 50/17

(52) U.S. Cl. CPC H10K 85/633; H10K 85/6574; H10K 85/6572; H10K 85/636; H10K 85/40; H10K 50/15; H10K 50/17; H10K 2102/301

(57) ABSTRACT

Embodiments provide a display device that includes first, second, and third light emitting regions, and first, second, and third light emitting elements. The first, second, and third light emitting regions are spaced apart in a plan view. The first, second, and third light emitting elements respectively correspond to the first, second, and third light emitting regions. Each of the first, second, and third light emitting elements includes a first electrode, a second electrode, a first light emitting unit, a second light emitting unit, and a charge generation layer that includes a p-type charge generation layer and an n-type charge generation layer, wherein the p-type charge generation layer includes first, second, and third p-type charge generation layers.

### CROSS-REFERENCE TO RELATED APPLICATION(S)

This application claims priority to and benefits of Korean Patent Application No. 10-2022-0051623 under 35 U.S.C. § 119, filed on Apr. 26, 2022 in the Korean Intellectual Property Office, the entire contents of which are incorporated herein by reference.

### BACKGROUND

### 1. Technical Field

The disclosure relates to a display device including a light emitting element having a tandem structure.

### 2. Description of the Related Art

Development is presently proceeding for various display devices, which are to be used for multi-media devices such as a television set, a mobile phone, a tablet computer, a navigation system, a game console, and a vehicular display. In such display devices, a so-called self-luminescent display element is used, which achieves display by causing a light emitting material to emit light.

Light emitting elements produce excitons by recombining holes and electrons respectively injected from a first electrode and a second electrode in an emission layer, and light is emitted when the excitons thus produced transition to a ground state.

In the application of light emitting elements to display devices, higher luminous efficiency and longer life of the light emitting elements are desired, and there is an ongoing demand for development of light emitting elements which are capable of stably achieving such desired qualities.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device having increased display efficiency.

An embodiment provides a display device which may include a first light emitting region emitting a first color, a second light emitting region emitting a second color having a shorter wavelength than the first color, a third light emitting region emitting a third color having a shorter wavelength than the second color, a first light emitting element, a second light emitting element, and a third light emitting element. The first light emitting region, the second light emitting region, and the third light emitting region may be spaced apart in plan view, and the first, second, and third light emitting elements may respectively correspond to the first, second, and third light emitting regions. Each of the first, second, and third light emitting elements may include: a first electrode; a second electrode facing the first electrode; a first light emitting unit disposed between the first electrode and the second electrode and including a hole transport region, a first emission layer, and a first electron transport region, which are sequentially stacked; a second light emitting unit disposed on the first light emitting unit and including a second emission layer and a second electron transport region disposed on the second emission layer; and a charge generation layer disposed between the first light emitting unit and the second light emitting unit and including a p-type charge generation layer and an n-type charge generation layer. The p-type charge generation layer may include a first p-type charge generation layer overlapping the first light emitting region, a second p-type charge generation layer overlapping the second light emitting region, and a third p-type charge generation layer overlapping the third light emitting region. Thicknesses of the first, second, and third p-type charge generation layers may satisfy Equation 1. The hole transport region may include an amine compound represented by Formula 1, and the p-type charge generation layer may include an amine compound represented by Formula 1 and a p-dopant:

T₁>T₂≥T₃ [Equation 1]

In Equation 1, T₁ is a thickness of the first p-type charge generation layer, T₂ is a thickness of the second p-type charge generation layer, and T₃ is a thickness of the third p-type charge generation layer.

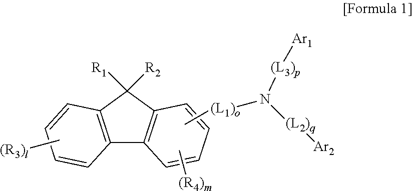

In Formula 1, Ar₁ and Ar₂ may each independently be a substituted or unsubstituted silyl group, a substituted or unsubstituted aryl group having 6 to 60 ring-forming carbon atoms, or a substituted or unsubstituted heteroaryl group having 2 to 60 ring-forming carbon atoms,

L₁ to L₃ may each independently be a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 60 ring-forming carbon atoms,

R₁ and R₂ may each independently be a substituted or unsubstituted amine group, a substituted or unsubstituted thio group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring,

R₃ and R₄ may each independently be a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,

l may be an integer from 0 to 4, m may be an integer from 0 to 3, and o, p, and q may each independently be an integer from 0 to 3,

provided that in the amine compound included in the hole transport region, R₁ and R₂ may each independently be a substituted or unsubstituted alkyl group having 1 to 30 carbon atoms, and provided that in the amine compound included in the p-type charge generation layer, R₁ and R₂ may each independently be a substituted or unsubstituted amine group, a substituted or unsubstituted thio group, a substituted or unsubstituted oxy group, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In an embodiment, the first p-type charge generation layer may have a thickness in a range of about 700 Å to about 1,200 Å, the second p-type charge generation layer may have a thickness in a range of about 300 Å to about 800 Å, and the third p-type charge generation layer may have a thickness in a range of about 200 Å to 600 Å.

In an embodiment, the amine compound included in the hole transport region may be represented by Formula 1-1:

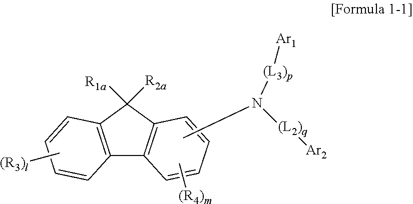

In Formula 1-1, R₁ₐ and R₂ₐ may each independently be a substituted or unsubstituted alkyl group having 1 to 30 carbon atoms; and Ar₁, Ar₂, L₂, L₃, R₃, R₄, l, m, p, and q are each the same as defined in Formula 1.

In an embodiment, the amine compound included in the p-type charge generation layer may be represented by Formula 1-2:

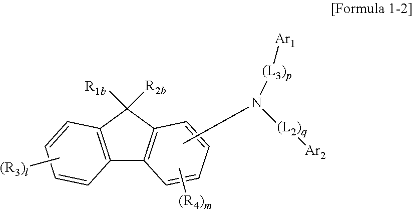

In Formula 1-2, R_{1b} and R_{2b} are each independently a substituted or unsubstituted aryl group having 6 to 30 ring-forming carbon atoms, or may be bonded to an adjacent group to form an aromatic hydrocarbon ring; and Ar₁, Ar₂, L₂, L₃, R₃, R₄, l, m, p, and q are each the same as defined in Formula 1.

In an embodiment, Ar₁ and Ar₂ may each independently be a substituted or unsubstituted phenyl group, a substituted or unsubstituted biphenyl group, a substituted or unsubstituted naphthyl group, a substituted or unsubstituted fluorenyl group, a substituted or unsubstituted dibenzofuran group, a substituted or unsubstituted carbazole group, or a substituted or unsubstituted triphenylsilyl group.

In an embodiment, wherein L₁ to L₃ may each independently be a direct linkage, a substituted or unsubstituted phenylene group, or a substituted or unsubstituted divalent biphenyl group.

In an embodiment, the first light emitting unit may include a first red light emitting unit overlapping the first light emitting region, a first green light emitting unit overlapping the second light emitting region, and a first blue light emitting unit overlapping the third light emitting region; and the second light emitting unit may include a second red light emitting unit overlapping the first light emitting region, a second green light emitting unit overlapping the second light emitting region, and a second blue light emitting unit overlapping the third light emitting region.

In an embodiment, the hole transport region may include a hole injection layer, a hole transport layer, an electron blocking layer, or any combination thereof; and at least one of the hole injection layer, the hole transport layer, or the electron blocking layer may include the amine compound represented by Formula 1.

In an embodiment, the hole transport region may include a hole transport layer disposed on the first electrode, and the hole transport layer may include the amine compound represented by Formula 1.

In an embodiment, the first electron transport region and the second electron transport region may each independently include an electron injection layer, an electron transport layer, a hole blocking layer, or any combination thereof.

In an embodiment, the first electron transport region may include a first electron transport layer disposed between the first emission layer and the charge generation layer; and the second electron transport region may include a second electron transport layer disposed on the second emission layer, and an electron injection layer disposed between the second electron transport layer and the second electrode.

In an embodiment, the n-type charge generation layer may be a common layer for the first light emitting region, the second light emitting region, and the third light emitting region.

In an embodiment, the p-type charge generation layer may be disposed adjacent to the second light emitting units, and the n-type charge generation layer may be disposed adjacent to the first light emitting units.

In an embodiment, the p-dopant may include a metal halide compound, a quinone derivative, a metal oxide, a cyano group-containing compound, or any combination thereof.

In an embodiment, the amine compound represented by Formula 1 may be selected from Compound Group 1 or Compound Group 2, which are explained below.

In an embodiment, the hole transport region may include an amine compound selected from Compound Group 1, and the p-type charge generation layer may include an amine compound selected from Compound Group 2.

Another embodiment provides a display device which may include a first light emitting region emitting a first color, a second light emitting region emitting a second color having a shorter wavelength than the first color, a third light emitting region emitting a third color having a shorter wavelength than the second color, a first light emitting element, a second light emitting element, and a third light emitting element. The first light emitting region, the second light emitting region, and the third light emitting region may be spaced apart in plan view, and the first, second, and third light emitting elements may respectively correspond to the first, second, and third light emitting regions. Each of the first, second, and third light emitting elements may include: a first electrode; a second electrode facing the first electrode; a first light emitting unit disposed between the first electrode and the second electrode and including a hole transport region; a second light emitting unit disposed between the first light emitting unit and the second electrode; and a charge generation layer disposed between the first light emitting unit and the second light emitting unit. The charge generation layer may include an n-type charge generation layer disposed as a common layer in the first emission region, the second emission region, and the third emission region, and a p-type charge generation layer disposed on the n-type charge generation layer. The p-type charge generation layer may include a first p-type charge generation layer overlapping the first light emitting region, a second p-type charge generation layer overlapping the second light emitting region, and a third p-type charge generation layer overlapping the third light emitting region. Thicknesses of the first, second, and third p-type charge generation layers may satisfy Equation 1, which is explained herein. The hole transport region and the p-type charge generation layer may each independently include an amine compound represented by Formula 1, which is explained herein.

In an embodiment, the hole transport region may include a hole injection layer, a hole transport layer, an electron blocking layer, or any combination thereof, and at least one of the hole injection layer, the hole transport layer, or the electron blocking layer may include the amine compound represented by Formula 1.

In an embodiment, the hole transport region may include a hole injection layer disposed on the first electrode, and a hole transport layer disposed on the hole injection layer; and the hole injection layer may include the amine compound represented by Formula 1.

In an embodiment, the hole transport region may include at least one compound selected from Compound Group 1, which is explained below; and the p-type charge generation layer may include at least one compound selected from Compound Group 2, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of light emitting elements according to an embodiment;

FIGS. 4A and 4B are each a schematic cross-sectional view of light emitting elements according to embodiments;

FIG. 5 is a schematic cross-sectional view of light emitting elements according to an embodiment;

FIG. 6 is a schematic cross-sectional view of light emitting elements according to an embodiment; and

FIG. 7 is a schematic cross-sectional view of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the description, the term “substituted or unsubstituted” may describe a group that is substituted or unsubstituted with at least one substituent selected from the group consisting of a deuterium atom, a halogen atom, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the description, the term “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the description, the term “adjacent group” may be interpreted as a substituent that is substituted for an atom which is directly connected to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the description, examples of a halogen atom may include a fluorine atom, a chlorine atom, a bromine atom, or an iodine atom.

In the description, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but are not limited thereto.

In the description, an alkenyl group may be a hydrocarbon group including at least one carbon-carbon double bond in the middle or an end of an alkyl group having 2 or more carbon atoms. The alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but are not limited thereto.

In the description, an alkynyl group may be a hydrocarbon group including at least one carbon-carbon triple bond in the middle or an end of an alkyl group having 2 or more carbon atoms. The alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., but are not limited thereto.

In the description, a hydrocarbon ring group may be any functional group or substituent derived from an aliphatic hydrocarbon ring. The hydrocarbon ring group may be a saturated hydrocarbon ring group having 5 to 20 ring-forming carbon atoms.

In the description, an aryl group may be any functional group or substituent derived from an aromatic hydrocarbon ring. The aryl group may be monocyclic or polycyclic. The number of ring-forming carbon atoms in an aryl group may be 6 to 50, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but are not limited thereto.

In the description, a fluorenyl group may be substituted, and two substituents may be bonded to each other to form a spiro structure. Examples of substituted fluorenyl groups are as follows. However, embodiments are not limited thereto.

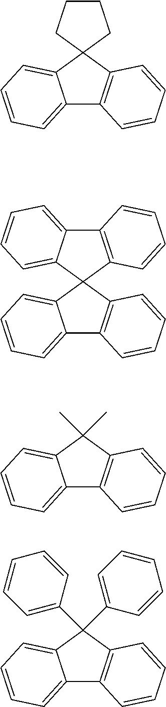

In the description, a heterocyclic group may be any functional group or substituent derived from a ring including at least one of B, O, N, P, Si, or S as a heteroatom. The heterocyclic group may be an aliphatic heterocyclic group or an aromatic heterocyclic group.

An aromatic heterocyclic group may be a heteroaryl group. The aliphatic heterocycle and the aromatic heterocycle may each independently be monocyclic or polycyclic.

In the description, the heterocyclic group may include at least one of B, O, N, P, Si, or S as a heteroatom. When the heterocyclic group contains two or more heteroatoms, the two or more heteroatoms may be the same as or different from each other. In the description, a heterocyclic group may be monocyclic or polycyclic, and a heterocyclic group may be a heteroaryl group. The number of ring-forming carbon atoms in a heterocyclic group may be 2 to 50, 2 to 30, 2 to 20, or 2 to 10.

In the description, an aliphatic heterocyclic group may include at least one of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but are not limited to thereto

In the description, a heteroaryl group may include at least one of B, O, N, P, Si, or S as a heteroatom. When the heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 50, 2 to 30, 2 to 20, or 2 to 10. Examples of a heteroaryl group may include a thiophene group, a furan group, a pyrrole group, an imidazole group, a triazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but are not limited thereto.

In the description, the above description of the aryl group may be applied to an arylene group, except that the arylene group is a divalent group. The above description of the heteroaryl group may be applied to a heteroarylene group, except that the heteroarylene group is a divalent group.

In the description, a boron group may be a boron atom that is bonded to an alkyl group or aryl group as defined above. A boron group may an alkyl boron group or an aryl boron group. Examples of a boron group may include a dimethyl boron group, a diethyl boron group, a t-butylmethyl boron group, a diphenyl boron group, a phenyl boron group, etc., but are not limited thereto.

In the description, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but are not limited thereto.

In the description, the number of carbon atoms in a carbonyl group is not particularly limited, but may be 1 to 40, 1 to 30, or 1 to 20. For example, a carbonyl group may have one of the following structures as shown below, but is not limited thereto.

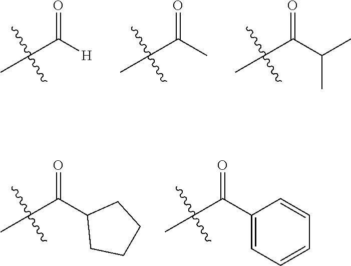

In the description, the number of carbon atoms in a sulfinyl group or in a sulfonyl group is not particularly limited, but may each independently be 1 to 30. The sulfinyl group may include an alkyl sulfinyl group and an aryl sulfinyl group. A sulfonyl group may be an alkyl sulfonyl group or an aryl sulfonyl group.

In the description, a thio group may be an alkyl thio group or an aryl thio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but are not limited to thereto.

In the description, an oxy group may be an oxygen atom that is bonded to an alkyl group or aryl group as defined above. The oxy group may be an alkoxy group or an aryl oxy group. An alkoxy group may be linear, branched, or cyclic. The number of carbon atoms in an alkoxy group is not particularly limited, but may be, for example, 1 to 20, or 1 to 10. Examples of an oxy group may include methoxy, ethoxy, n-propoxy, isopropoxy, butoxy, pentyloxy, hexyloxy, octyloxy, nonyloxy, decyloxy, benzyloxy, etc., but are not limited thereto.

In the description, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but are not limited thereto.

In the description, examples of an alkyl group may include an alkylthio group, an alkyl sulfoxy group, an alkylaryl group, an alkylamino group, an alkyl boron group, an alkyl silyl group, and an alkyl amine group.

In the description, examples of an aryl group may include an aryloxy group, an arylthio group, an aryl sulfoxy group, an arylamino group, an aryl boron group, an aryl silyl group, and an aryl amine group.

In the description, a direct linkage may be a single bond.

In the description, the symbols

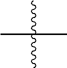

or -* each represent a bonding site to a neighboring atom.

Hereinafter, embodiments will be described with reference to the accompanying drawings.

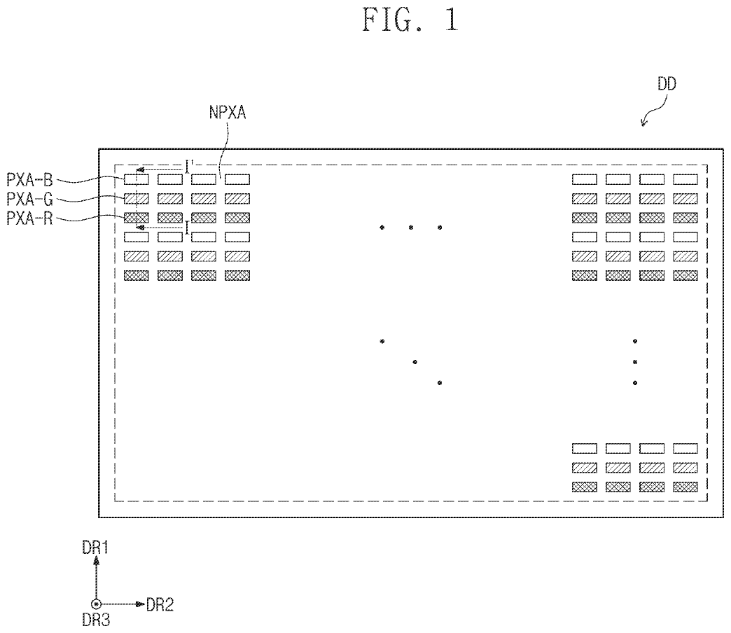

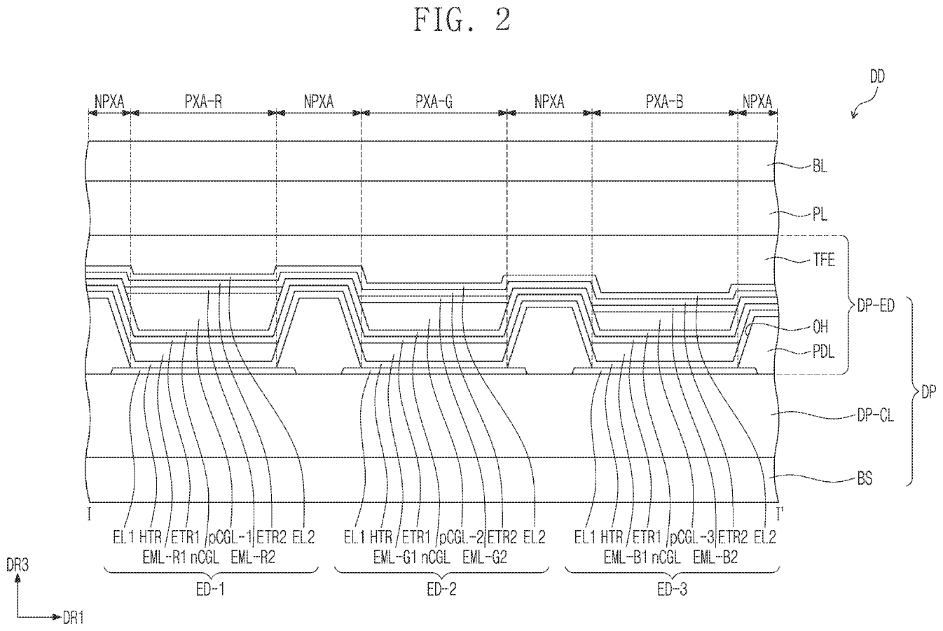

FIG. 1 is a plan view showing an embodiment of a display device DD. FIG. 2 is a schematic cross-sectional view of a display device DD according to an embodiment. FIG. 2 is a schematic cross-sectional view showing a portion taken along line I-I′ of FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PL may be disposed on the display panel DP and may control light that is reflected at the display panel DP from an external light. The optical layer PL may include, for example, a polarizing layer or a color filter layer. Although not shown in the drawings, in an embodiment, the optical layer PL may be omitted from the display device DD.

A base substrate BL may be disposed on the optical layer PL. The base substrate BL may provide a base surface on which the optical layer PL is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic resin, a silicone-based resin, or an epoxy-based resin.

The display panel DP may include a base layer BS, a circuit layer DP-CL provided on the base layer BS, and a display element layer DP-ED. The display element layer DP-ED may include pixel defining films PDL, light emitting elements ED-1, ED-2, and ED-3 disposed between portions of the pixel defining films PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

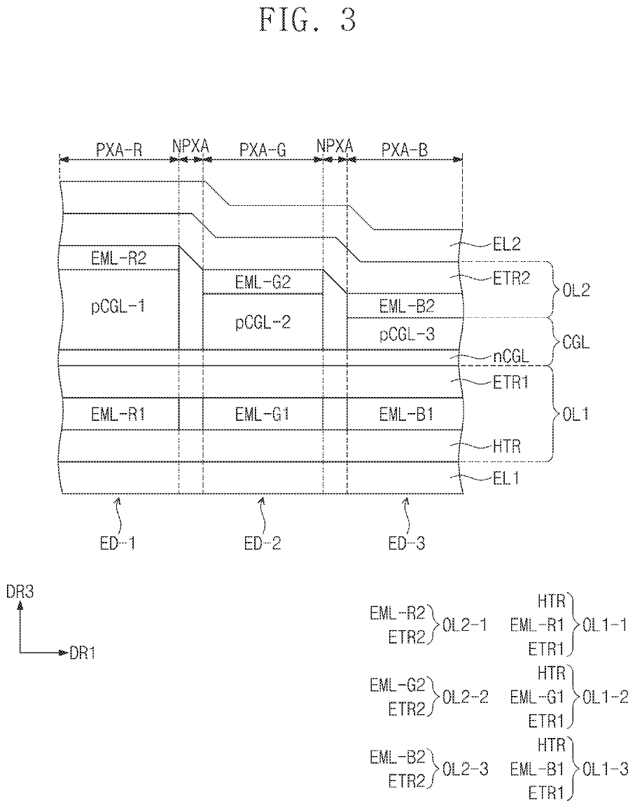

The light emitting elements ED-1, ED-2, and ED-3 may each have a structure of the light emitting elements ED-1, ED-2, ED-3 of an embodiment according to any of FIGS. 3 to 6, which will be described later. The light emitting elements ED-1, ED-2, and ED-3 may each include a first electrode EL1, a first light emitting unit OL1 (FIG. 3), a charge generation layer CGL (FIG. 3), a second light emitting unit OL2 (FIG. 3), and a second electrode EL2. The first light emitting unit OL1 and the second light emitting unit OL2 may each include an electron transport region, an emission layer, and a hole transport region, which will be described later. For example, each of the light emitting elements ED-1, ED-2, and ED-3 included in the display device DD may be light emitting elements having a tandem structure including multiple emission layers. In FIGS. 2 to 6, the light emitting elements ED-1, ED-2, and ED-3 are each shown to include a first light emitting unit OL1 and a second light emitting unit OL2, but embodiments are not limited thereto, and the light emitting elements ED-1, ED-2, and ED-3 may each independently include three or more light emitting units.

FIG. 2 shows an embodiment in which the light emitting units OL1 and OL2 (FIG. 3) of the light emitting elements ED-1, ED-2, and ED-3 are disposed in openings OH defined in the pixel defining films PDL, and a hole transport region HTR, electron transport regions ETR1 and ETR2, an n-type charge generation layer nCGL, and a second electrode EL2 are each provided as a common layer for the light emitting elements ED-1, ED-2, and ED-3. However, embodiments are not limited thereto. Although not shown in FIG. 2, in an embodiment, the hole transport region HTR and the electron transport regions ETR1 and ETR2 may each be patterned and provided inside the openings OH defined in the pixel defining films PDL. For example, in an embodiment, the hole transport region HTR, emission layers EML-R1, EML-R2, EML-G1, EML-G2, EML-B1, and EML-B2, and the electron transport regions ETR1 and ETR2, etc., of the light emitting elements ED-1, ED-2, and ED-3 may each be patterned and provided through an inkjet printing method.

An encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a stack of multiple layers. The encapsulation layer TFE may include at least one insulating layer. The encapsulation layer TFE according to an embodiment may include at least one inorganic film (hereinafter, an encapsulation inorganic film). The encapsulation layer TFE according to an embodiment may include at least one organic film (hereinafter, an encapsulation organic film) and at least one encapsulation inorganic film.

The encapsulation inorganic film may protect the display element layer DP-ED from moisture and/or oxygen, and the encapsulation organic film may protect the display element layer DP-ED from foreign substances such as dust particles. The encapsulation inorganic film may include silicon nitride, silicon oxy nitride, silicon oxide, titanium oxide, aluminum oxide, etc., but is not limited thereto. The encapsulation organic layer may include an acrylic compound, an epoxy-based compound, etc. The encapsulation organic layer may include a photopolymerizable organic material, without limitation.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from the light emitting elements ED-1, ED-2, and ED-3, respectively. The light emitting regions PXA-R, PXA-G, and PXA-B may be spaced apart from each other in a plan view.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may be regions that correspond to the pixel defining films PDL. For example, in an embodiment, the light emitting regions PXA-R, PXA-G, and PXA-B may each respectively correspond to a pixel. The pixel defining films PDL may separate the light emitting elements ED-1, ED-2, and ED-3. The emission layers EML-R1, EML-R2, EML-G1, EML-G2, EML-B1, and EML-B2 of the light emitting elements ED-1, ED-2, and ED-3 may be separated by being disposed in the openings OH defined in the pixel defining films PDL.

The light emitting regions PXA-R, PXA-G, and PXA-B may be arranged into groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, are illustrated as an example. For example, the display device DD according to an embodiment may include a first light emitting region PXA-R, a second light emitting region PXA-G, and a third light emitting region PXA-B, which are separated from each other. In an embodiment, the first light emitting region PXA-R may emit a first color, the second light emitting region PXA-G may emit a second color, and the third light emitting region PXA-B may emit a third color. For example, the first light emitting region PXA-R may correspond to a red light emitting region, the second light emitting region PXA-G may correspond to a green light emitting region, and the third light emitting region PXA-B may correspond to a blue light emitting region.

In the display device DD according to an embodiment, the light emitting elements ED-1, ED-2, and ED-3 may emit light having wavelength ranges that are different from each other. For example, in an embodiment, the display device DD may include a first light emitting element ED-1 that emits a first color, a second light emitting element ED-2 that emits a second color having a shorter wavelength than the first color, and a third light emitting element ED-3 that emits a third color having a shorter wavelength than the second color. For example, in an embodiment, the display device DD may include a first light emitting element ED-1 emitting red light, a second light emitting element ED-2 emitting green light, and a third light emitting element ED-3 emitting blue light. The first light emitting element ED-1 may emit red light having a wavelength in a range of about 625 nm to about 675 nm. The second light emitting element ED-2 may emit green light having a wavelength in a range of about 500 nm to about 570 nm. The third light emitting element ED-3 may emit blue light having a wavelength in a range of about 410 nm to about 480 nm. The first light emitting element ED-1 may correspond to the first light emitting region PXA-R, which is a red light emitting region. The second light emitting element ED-2 may correspond to the second light emitting region PXA-G, which is a green light emitting region. The third light emitting element ED-3 may correspond to the third light emitting region PXA-B, which is a blue light emitting region.

However, embodiments are not limited thereto, and the first to third light emitting elements ED-1, ED-2, and ED-3 may emit light in a same wavelength range or may emit light in at least one different wavelength range. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the first light emitting regions PXA-R, the second light emitting regions PXA-G, and the third light emitting regions PXA-B may each be arranged along a second directional axis DR2. In another embodiment, the first light emitting region PXA-R, the second light emitting region PXA-G, and the third light emitting region PXA-B may be alternately arranged by turns along a first directional axis DR1.

FIGS. 1 and 2 show that the light emitting regions PXA-R, PXA-G, and PXA-B are similar in size to each other, but embodiments are not limited thereto, and the light emitting regions PXA-R, PXA-G, and PXA-B may be different in size from each other according to a wavelength range of emitted light. For example, the areas of the light emitting regions PXA-R, PXA-G, and PXA-B may be areas in a plan view that are defined by the first directional axis DR1 and the second directional axis DR2.

The arrangement of the light emitting regions PXA-R, PXA-G, and PXA-B is not limited to what is shown in FIG. 1, and the configuration in which the first light emitting region PXA-R, the second light emitting region PXA-G, and the third light emitting region PXA-B are arranged may be provided in various combinations, according to display quality characteristics which are required for the display device DD. For example, the light emitting regions PXA-R, PXA-G, and PXA-B may be arranged in a pentile configuration (such as a PENTILE™ configuration) or may be arranged in a diamond configuration (such as a Diamond Pixel™ configuration).

The areas of each of the light emitting regions PXA-R, PXA-G, and PXA-B may be different in size from one another. For example, in an embodiment, the area of the second light emitting region PXA-G may be smaller than the area of the third light emitting region PXA-B, but embodiments are not limited thereto.

FIGS. 3 to 6 are each a schematic cross-sectional view of a light emitting element according to an embodiment. Hereinafter, referring to FIGS. 3 to 6, the light emitting elements ED-1, ED-2, and ED-3 included in the display device DD according to an embodiment will be described in detail.

Referring to FIG. 3, the light emitting elements ED-1, ED-2, and ED-3 according to an embodiment may each include a first electrode EL1, a second electrode EL2 facing the first electrode EL1, a first light emitting unit OL1 disposed between the first electrode EL1 and the second electrode EL2, a second light emitting unit OL2 disposed on the first light emitting unit OL1, and a charge generation layer CGL disposed between the first light emitting unit OL1 and the second light emitting unit OL2.

The light emitting elements ED-1, ED-2, and ED-3 may each include the first light emitting unit OL1, the charge generation layer CGL, and the second light emitting unit OL2, which are sequentially stacked along the third directional axis DR3. Referring to FIG. 3, the light emitting elements ED-1, ED-2, and ED-3 according to an embodiment may each include the first electrode EL1, the first light emitting unit OL1, the charge generation layer CGL, the second light emitting unit OL2, and the second electrode EL2, which are sequentially stacked.

In an embodiment, the first light emitting unit OL1 may include a first red light emitting unit OL1-1 overlapping the first light emitting region PXA-R, a first green light emitting unit OL1-2 overlapping the second light emitting region PXA-G, and a first blue light emitting unit overlapping the third light emitting region PXA-B. The second light emitting unit OL2 may include a second red light emitting unit OL2-1 overlapping the first light emitting region PXA-R, a second green light emitting unit OL2-2 overlapping the second light emitting region PXA-G, and a second blue light emitting unit OL2-3 overlapping the third light emitting region PXA-B. Thus, the first red light emitting unit OL1-1 and the second red light emitting unit OL2-1 may correspond to the first light emitting region PXA-R, the first green light emitting unit OL1-2 and the second green light emitting unit OL2-2 may correspond to the second light emitting region PXA-G, and the first blue light emitting unit OL1-3 and the second blue light emitting unit OL2-3 may correspond to the third light emitting region PXA-B.

In an embodiment, the first light emitting unit OL1 may include the hole transport region HTR, first emission layers EML-R1, EML-G1, and EML-B1, and the first electron transport region ETR1. For example, the first red light emitting unit OL1-1 may include the hole transport region HTR, a first red emission layer EML-R1, and a first electron transport region ETR1, which are sequentially stacked on the first electrode EL1. The second green light emitting unit OL1-2 may include the hole transport region HTR, a first green emission layer EML-G1, and a first electron transport region ETR1, which are sequentially stacked on the first electrode EL1. The first blue light emitting unit OL1-3 may include the hole transport region HTR, a first blue emission layer EML-B1, and a first electron transport region ETR1, which are sequentially stacked on the first electrode EL1.

The charge generation layer CGL may be disposed between the first light emitting unit OL1 and the second light emitting unit OL2 to regulate balance in holes and/or charges between the first light emitting unit OL1 and the second light emitting unit OL2. For example, the charge generation layer CGL may facilitate movement of the holes and/or charges between the first light emitting unit OL1 and the second light emitting unit OL2. The charge generation layer CGL may include an n-type charge generation layer nCGL and a p-type charge generation layer pCGL.

The second light emitting unit OL2 may be disposed on the charge generation layer CGL and may include second emission layers EML-R2, EML-G2, and EML-B2 and the second electron transport region ETR2. For example, the second red light emitting unit OL2-1 may include a second red emission layer EML-R2 and the second electron transport region ETR2, which are sequentially stacked on the charge generation layer CGL. The second green light emitting unit OL1-2 may include a second green emission layer EML-G2 and the second electron transport region ETR2, which are sequentially stacked on the first electrode EL1. The second blue light emitting unit OL2-3 may include a second blue emission layer EML-B2 and the second electron transport region ETR2, which are sequentially stacked on the charge generation layer CGL. Although not shown in the drawings, in an embodiment, the second light emitting unit OL2 may further include a hole transport region between the charge generation layer CGL and the second emission layers EML-R2, EML-G2, and EML-B2.

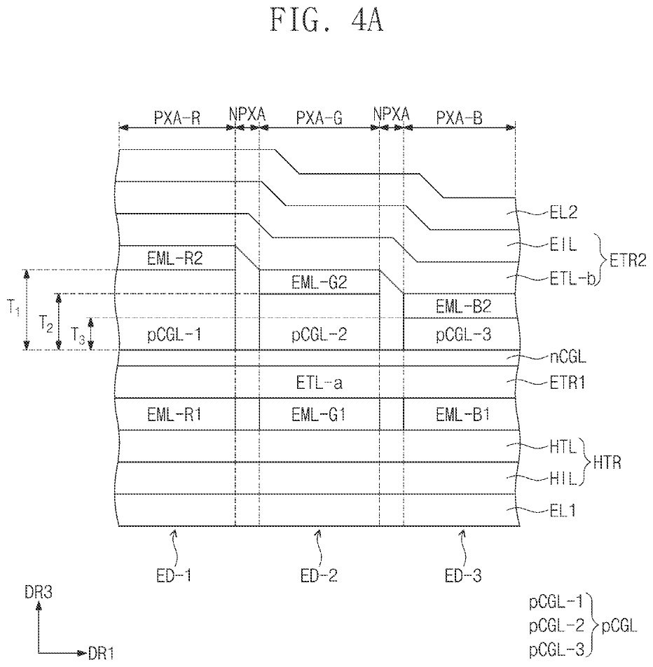

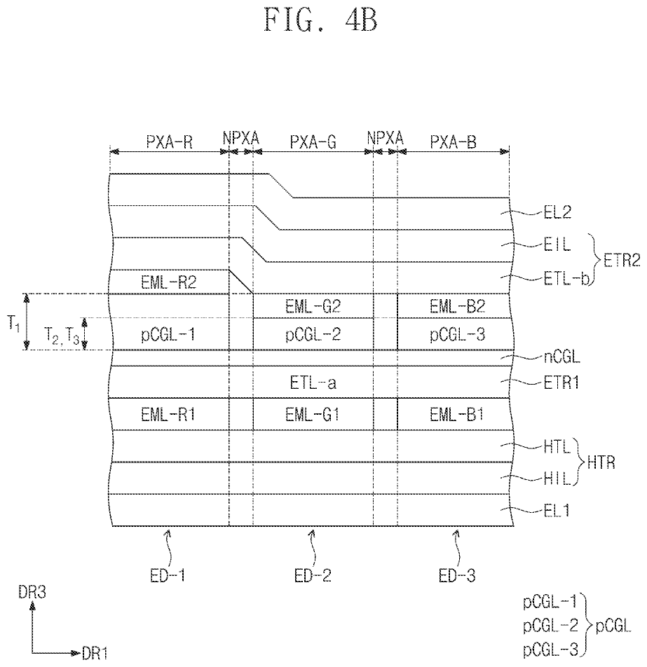

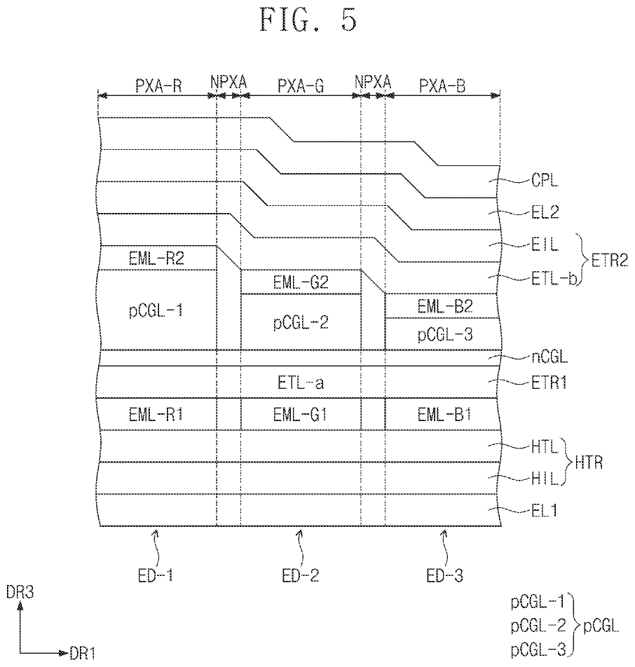

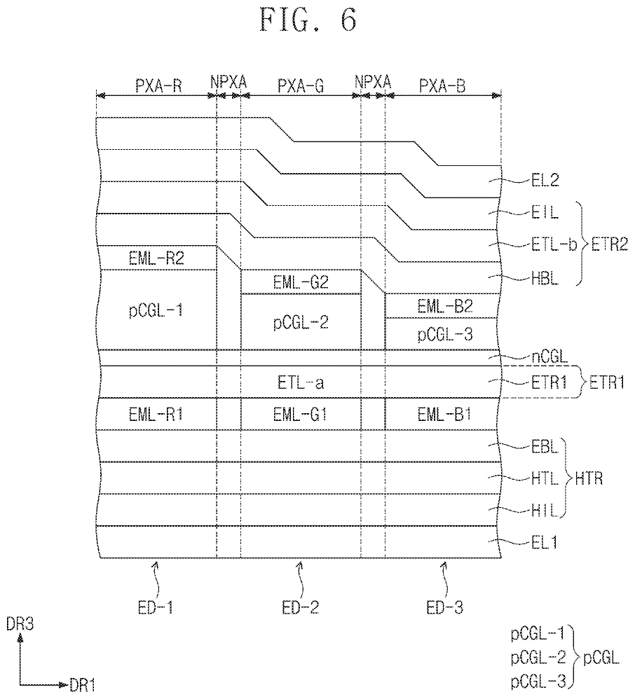

In comparison to FIG. 3, FIG. 4A is a schematic cross-sectional view of light emitting elements ED-1, ED-2, and ED-3 according to an embodiment in which the hole transport region HTR includes a hole injection layer HIL and a hole transport layer HTL, the first electron transport region ETR1 includes a first electron transport layer ETL-a, and the second electron transport region ETR2 includes an electron injection layer EIL and a second electron transport layer ETL-b. In comparison to FIG. 4A, FIG. 4B is a schematic cross-sectional view of light emitting elements ED-1, ED-2, and ED-3 according to an embodiment in which a second p-type charge generation layer pCGL-2 and a third p-type charge generation layer pCGL-3 have a same thickness. In comparison to FIG. 4A, FIG. 5 is a schematic cross-sectional view of light emitting elements ED-1, ED-2, and ED-3 according to an embodiment that further includes a capping layer CPL disposed on the second electrode EL2. In comparison to FIG. 3, FIG. 6 is a schematic cross-sectional view of light emitting elements ED-1, ED-2, and ED-3 according to an embodiment in which the hole transport region HTR includes a hole injection layer HIL, a hole transport layer HTL, and an electron blocking layer EBL, and the second electron transport region HTR2 includes an electron injection layer EIL, a second electron transport layer ETL-b, and a hole blocking layer HBL.

The light emitting elements ED-1, ED-2, and ED-3 may include an amine compound which may be represented by Formula 1, which will be described later, in the hole transport region HTR and the p-type charge generation layer pCGL. In the hole transport region HTR of the light emitting elements ED-1, ED-2, and ED-3 according to an embodiment, at least one of the hole injection layer HIL, the hole transport layer HTL, or the electron blocking layer EBL may include the amine compound according to an embodiment. For example, in the light emitting elements ED-1, ED-2, and ED-3, the hole injection layer HIL may include the amine compound. In the light emitting elements ED-1, ED-2, and ED-3 may include the amine compound in each of the first to third p-type charge generation layers pCGL-1, pCGL-2, and pCGL-3. The amine compounds included in the first to third p-type charge generation layers pCGL-1, pCGL-2, and pCGL-3 may be the same as or different from each other.

In the light emitting elements ED-1, ED-2, and ED-3 according to embodiments, the first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

When the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO. However, embodiments are not limited thereto. The first electrode EL1 may include the above-described metal materials, a combination of two or more metal materials selected from the above-described metal materials, or oxides of the above-described metal materials. The first electrode EL1 may have a thickness in a range of about 700 Å to about 10,000 Å. For example, the first electrode EL1 may have a thickness in a range of about 1,000 Å to about 3,000 Å.

The hole transport region HTR is provided on the first electrode EL1. The hole transport region HTR may be a layer formed of a single material, a layer formed of different materials, or a structure having multiple layers formed of different materials.

The hole transport region HTR may include at least one among a hole injection layer HIL, a hole transport layer HTL, and an electron blocking layer EBL. Although not shown in the drawings, in an embodiment, the hole transport region HTR may include multiple hole transport layers that are stacked.

In other embodiments, the hole transport region HTR may have a single-layer structure formed of a hole injection layer HIL or a hole transport layer HTL, or a single-layer structure formed of a hole injection material or a hole transport material. In an embodiment, the hole transport region HTR may have a single-layer structure formed of different materials, or a structure in which a hole injection layer HIL/hole transport layer HTL, a hole injection layer HIL/hole transport layer HTL/buffer layer (not shown), a hole injection layer HIL/buffer layer (not shown), or a hole transport layer HTL/buffer layer (not shown) are stacked in its respective stated order from the first electrode EL1, but embodiments are not limited thereto.

The hole transport region HTR may have, for example, a thickness in a range of about 50 Å to about 15,000 Å.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting elements ED-1, ED-2, and ED-3, the hole transport region HTR may include the amine compound which may be represented by Formula 1. In the light emitting elements ED-1, ED-2, and ED-3 according to an embodiment, the hole transport region HTR may include a hole injection layer HIL, a hole transport layer HTL, an electron blocking layer EBL, or any combination thereof. In the light emitting elements ED-1, ED-2, and ED-3 according to embodiments, at least one of the electron injection layer EIL, the hole transport layer HTL, or the electron blocking layer EBL may include the amine compound represented by Formula 1. For example, the hole transport region HTR may include a hole injection layer HIL and a hole transport layer HTL, which are disposed on the first electrode EL1, and the hole injection layer HIL may include the amine compound represented by Formula 1.

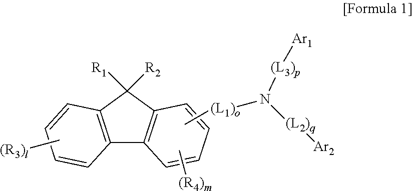

In Formula 1, Ar₁ and Ar₂ may each independently be a substituted or unsubstituted silyl group, a substituted or unsubstituted aryl group having 6 to 60 ring-forming carbon atoms, or a substituted or unsubstituted heteroaryl group having 2 to 60 ring-forming carbon atoms. For example, in an embodiment, Ar₁ and Ar₂ may each independently be a substituted or unsubstituted phenyl group, a substituted or unsubstituted biphenyl group, a substituted or unsubstituted naphthyl group, a substituted or unsubstituted fluorenyl group, a substituted or unsubstituted dibenzofuran group, a substituted or unsubstituted carbazole group, or a substituted or unsubstituted triphenylsilyl group. However, embodiments are not limited thereto.

In Formula 1, o, p, and q may each independently be an integer from 0 to 3. In Formula 1, L₁ to L₃ may each independently be a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 60 ring-forming carbon atoms. For example, in an embodiment, L₁ to L₃ may each independently be a direct linkage, a substituted or unsubstituted phenylene group, or a substituted or unsubstituted divalent biphenyl group.

In Formula 1, R₁ and R₂ may each independently be a substituted or unsubstituted amine group, a substituted or unsubstituted thio group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring, For example, R₁ and R₂ may each independently be a substituted or unsubstituted alkyl group having 1 to 10 carbon atoms, a substituted or unsubstituted phenyl group, or a substituted or unsubstituted biphenyl group. However, embodiments are not limited thereto.

In an embodiment, in the amine compound represented by Formula 1 included in the hole transport region HTR, R₁ and R₂ may each independently be a substituted or unsubstituted alkyl group having 1 to 30 carbon atoms. For example, the hole transport layer HTL and/or the hole injection layer HIL may each independently include an amine compound represented by Formula 1 in which R₁ and R₂ are each independently a substituted or unsubstituted alkyl group having 1 to 30 carbon atoms. As such, the light emitting elements ED-1, ED-2, and ED-3 may have excellent hole transport properties. For example, the light emitting elements ED-1, ED-2, and ED-3 may achieve sufficient hole injection properties and hole transport properties, and may thus have increased luminous efficiency and element lifespan.

In Formula 1, R₃ and R₄ may each independently be a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, R₃ and R₄ may each independently be a hydrogen atom or a deuterium atom.

In Formula 1, 1 may be an integer from 0 to 4, and m may be an integer from 0 to 3. A case where 1 is 0 may be the same as a case where 1 is 4 and each R₃ is a hydrogen atom. A case where m is 0 may be the same as a case where m is 3 and each R₄ is a hydrogen atom. In an embodiment, when 1 is 2 or greater, multiple R₃ groups may all be the same or at least one thereof may be different from the others. In Formula 1, when 1 is 0, a fluorene moiety may not be substituted with R₃. When m is 2 or greater, multiple R₄ groups may all be the same or at least one thereof may be different from the others. In Formula 1, when m is 0, a fluorene moiety may not be substituted with R₄.

In an embodiment, the amine compound represented by Formula 1 included in the hole transport region HTR may be represented by Formula 1-1. In Formula 1-1, Ar₁, Ar₂, L₂, L₃, R₃, R₄, l, m, p, and q are each the same as defined in Formula 1.

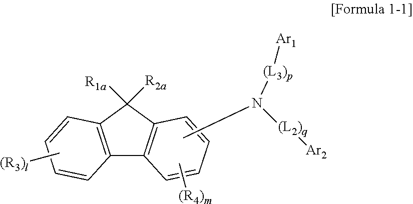

In Formula 1-1, R₁ₐ and R₂ₐ may each independently be a substituted or unsubstituted alkyl group having 1 to 30 carbon atoms. For example, R₁ₐ and R₂ₐ may each independently be a substituted or unsubstituted methyl group, a substituted or unsubstituted ethyl group, a substituted or unsubstituted n-propyl group, a substituted or unsubstituted isopropyl group, a substituted or unsubstituted t-butyl group, or the like, but embodiments are not limited thereto.

The amine compound represented by Formula 1 may be any compound selected from Compound Group 1 or Compound Group 2. The hole transport region HTR of the light emitting element ED may include at least one compound selected from Compound Group 1. For example, the hole injection layer HIL of the light emitting elements ED-1, ED-2, and ED-3 may include at least one compound selected from Compound Group 1:

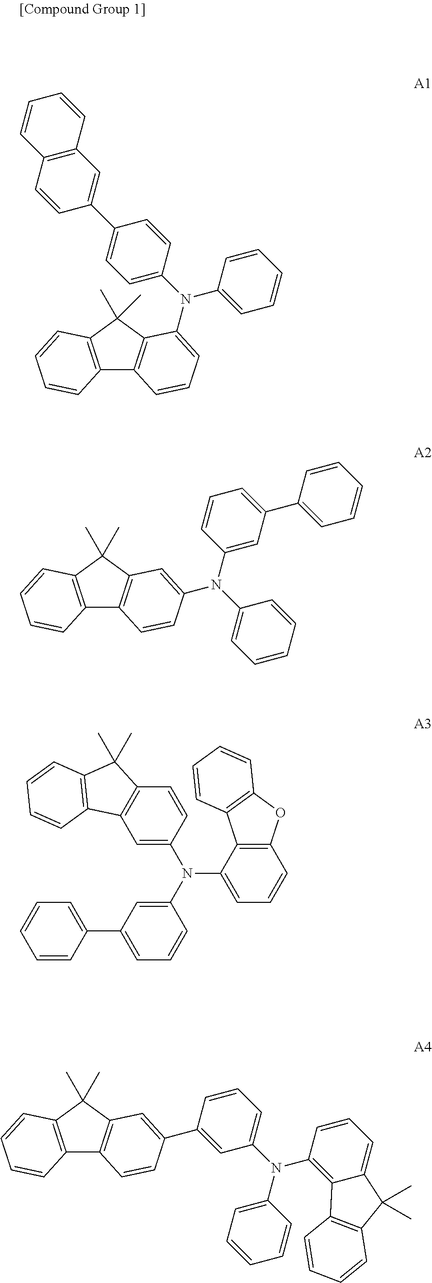 [SMILES: CC1(C)c2ccccc2-c2cccc(N(c3ccccc3)c3ccc(-c4ccc5ccccc5c4)cc3)c21 ; CC1(C)c2ccccc2-c2ccc(N(c3ccccc3)c3cccc(-c4ccccc4)c3)cc21 ; CC1(C)c2ccccc2-c2cc(N(c3cccc(-c4ccccc4)c3)c3cccc4oc5ccccc5c34)ccc21 ; CC1(C)c2ccccc2-c2ccc(-c3cccc(N(c4ccccc4)c4cccc5c4-c4ccccc4C5(C)C)c3)cc21]

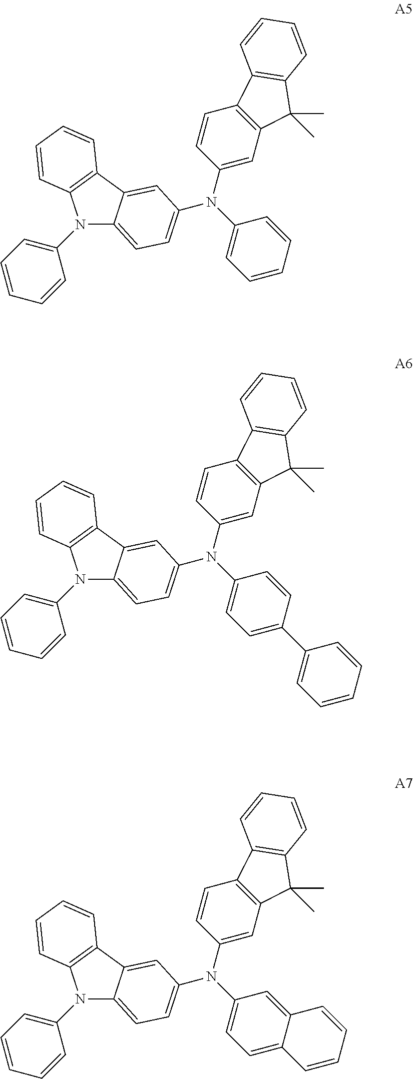 [SMILES: CC1(C)c2ccccc2-c2ccc(N(c3ccccc3)c3ccc4c(c3)c3ccccc3n4-c3ccccc3)cc21 ; CC1(C)c2ccccc2-c2ccc(N(c3ccc(-c4ccccc4)cc3)c3ccc4c(c3)c3ccccc3n4-c3ccccc3)cc21 ; CC1(C)c2ccccc2-c2ccc(N(c3ccc4ccccc4c3)c3ccc4c(c3)c3ccccc3n4-c3ccccc3)cc21]

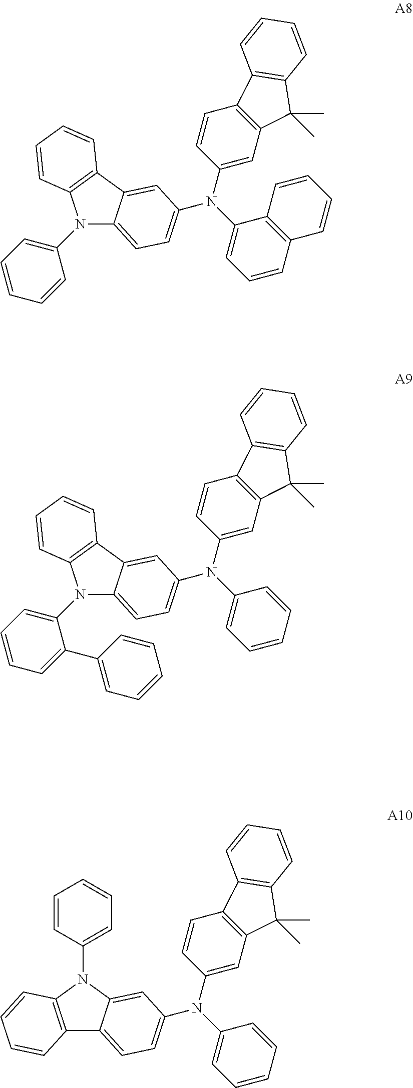 [SMILES: CC1(C)c2ccccc2-c2ccc(N(c3ccc4c(c3)c3ccccc3n4-c3ccccc3)c3cccc4ccccc34)cc21 ; CC1(C)c2ccccc2-c2ccc(N(c3ccccc3)c3ccc4c(c3)c3ccccc3n4-c3ccccc3-c3ccccc3)cc21 ; CC1(C)c2ccccc2-c2ccc(N(c3ccccc3)c3ccc4c5ccccc5n(-c5ccccc5)c4c3)cc21]

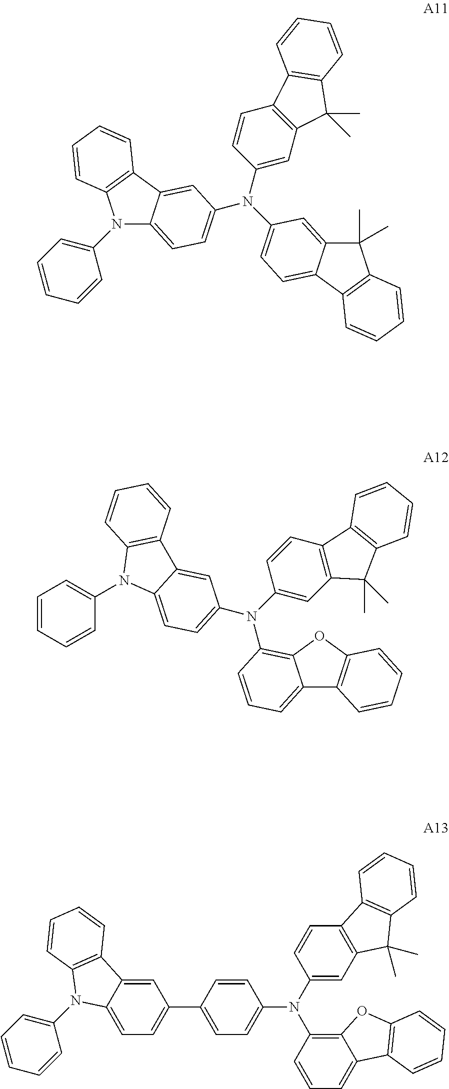 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc4c(c3)c3ccccc3n4-c3ccccc3)c3cccc4c3oc3ccccc34)cc21 ; CC1(C)c2ccccc2-c2ccc(N(c3ccc(-c4ccc5c(c4)c4ccccc4n5-c4ccccc4)cc3)c3cccc4c3oc3ccccc34)cc21]

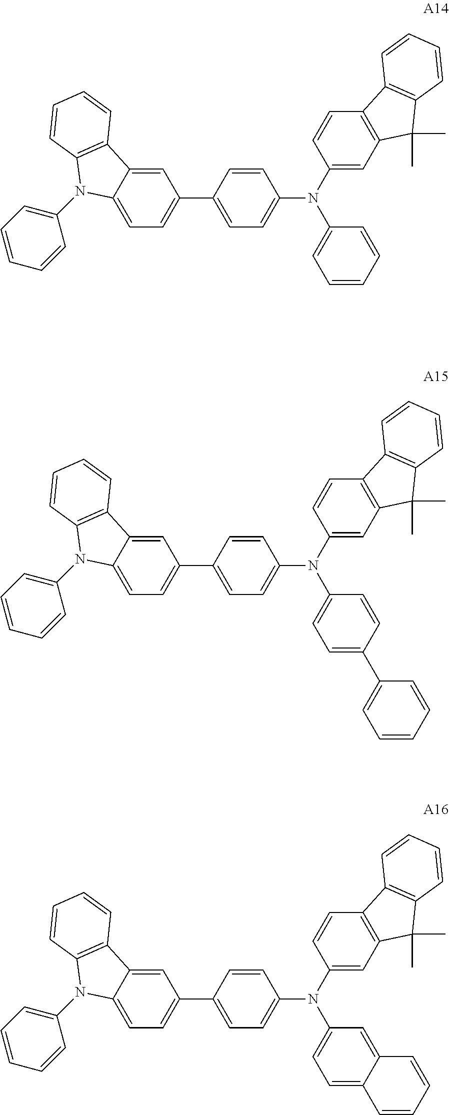 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3ccc4ccccc4c3)cc21]

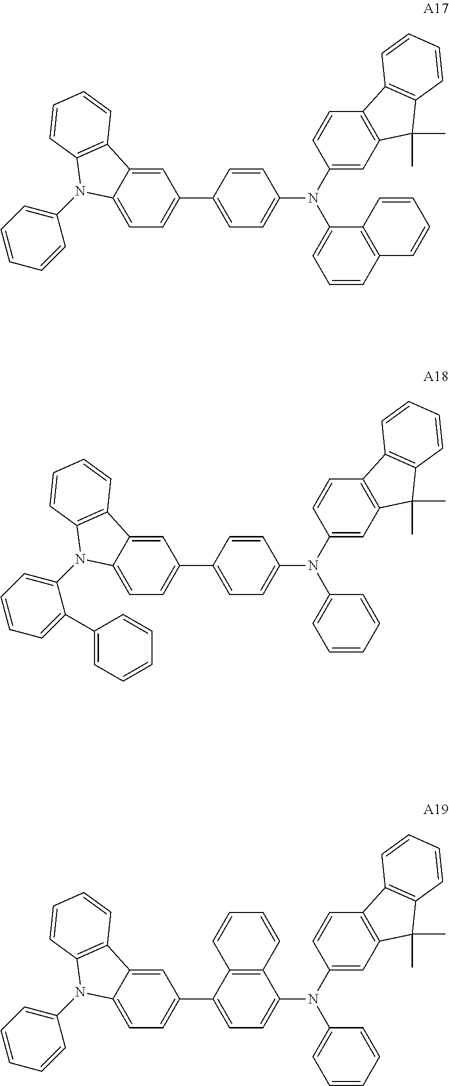 [SMILES: CC1(C)c2ccccc2-c2ccc(N(c3ccc(-c4ccc5c(c4)c4ccccc4n5-c4ccccc4)cc3)c3cccc4ccccc34)cc21 ; CC1(C)c2ccccc2-c2ccc(N(c3ccccc3)c3ccc(-c4ccc5c(c4)c4ccccc4n5-c4ccccc4-c4ccccc4)cc3)cc21 ; CC1(C)c2ccccc2-c2ccc(N(c3ccccc3)c3ccc(-c4ccc5c(c4)c4ccccc4n5-c4ccccc4)c4ccccc34)cc21]

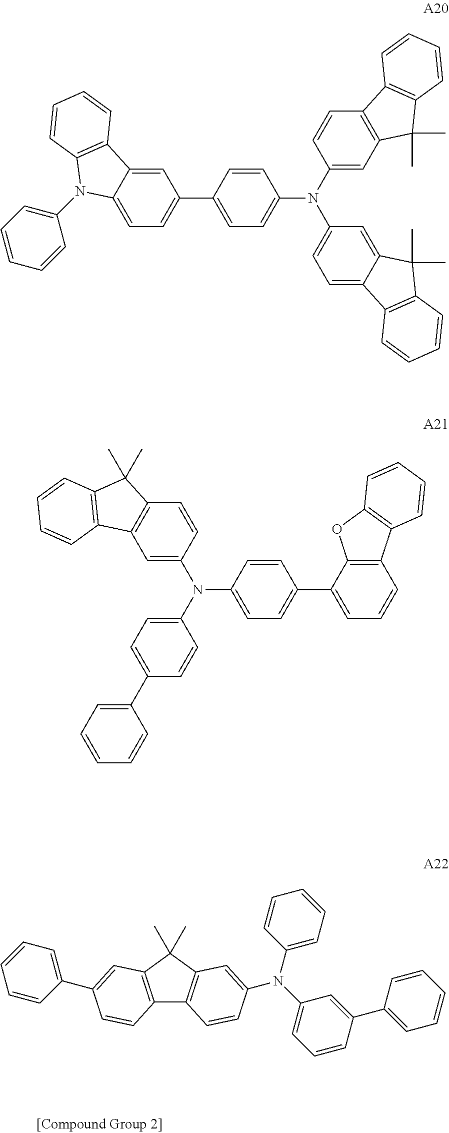 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2cc(N(c3ccc(-c4ccccc4)cc3)c3ccc(-c4cccc5c4oc4ccccc45)cc3)ccc21 ; CC1(C)c2cc(-c3ccccc3)ccc2-c2ccc(N(c3ccccc3)c3cccc(-c4ccccc4)c3)cc21]

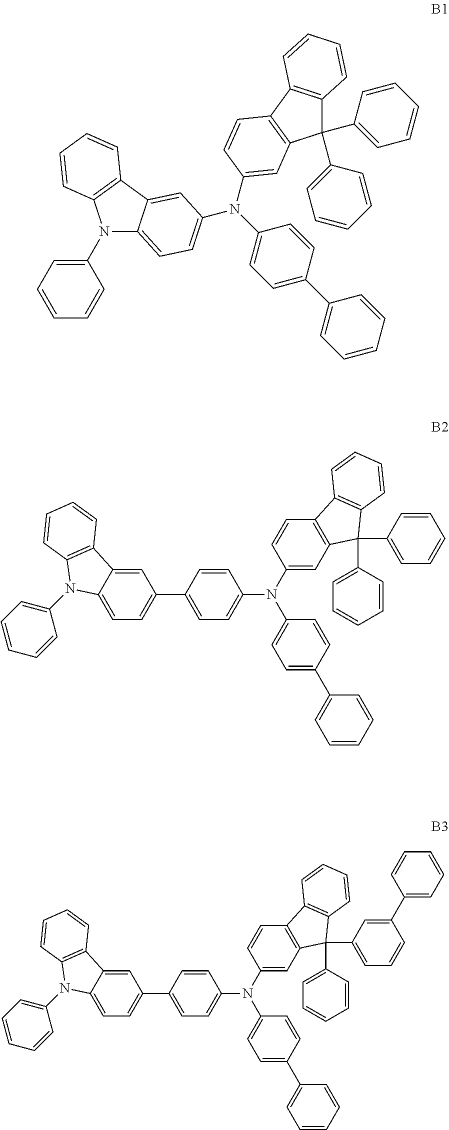 [SMILES: c1ccc(-c2ccc(N(c3ccc4c(c3)C(c3ccccc3)(c3ccccc3)c3ccccc3-4)c3ccc4c(c3)c3ccccc3n4-c3ccccc3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3cccc(-c5ccccc5)c3)c3ccccc3-4)cc2)cc1]

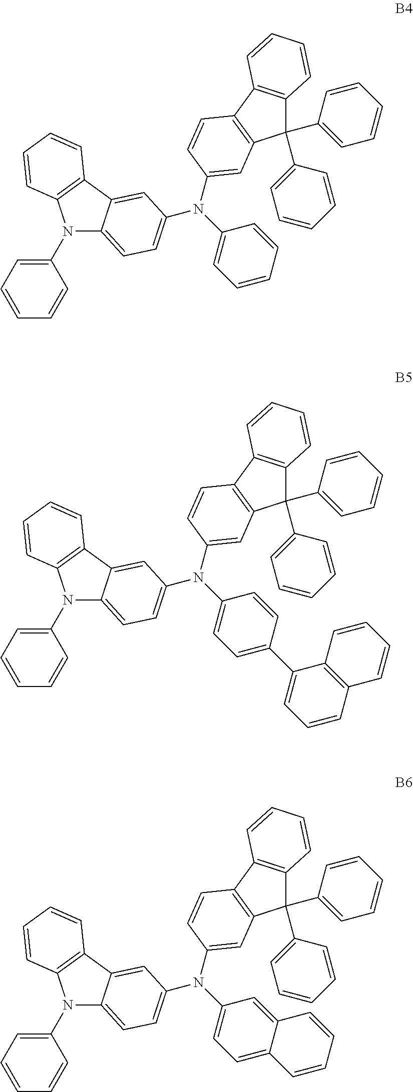 [SMILES: c1ccc(N(c2ccc3c(c2)C(c2ccccc2)(c2ccccc2)c2ccccc2-3)c2ccc3c(c2)c2ccccc2n3-c2ccccc2)cc1 ; c1ccc(-n2c3ccccc3c3cc(N(c4ccc(-c5cccc6ccccc56)cc4)c4ccc5c(c4)C(c4ccccc4)(c4ccccc4)c4ccccc4-5)ccc32)cc1 ; c1ccc(-n2c3ccccc3c3cc(N(c4ccc5c(c4)C(c4ccccc4)(c4ccccc4)c4ccccc4-5)c4ccc5ccccc5c4)ccc32)cc1]

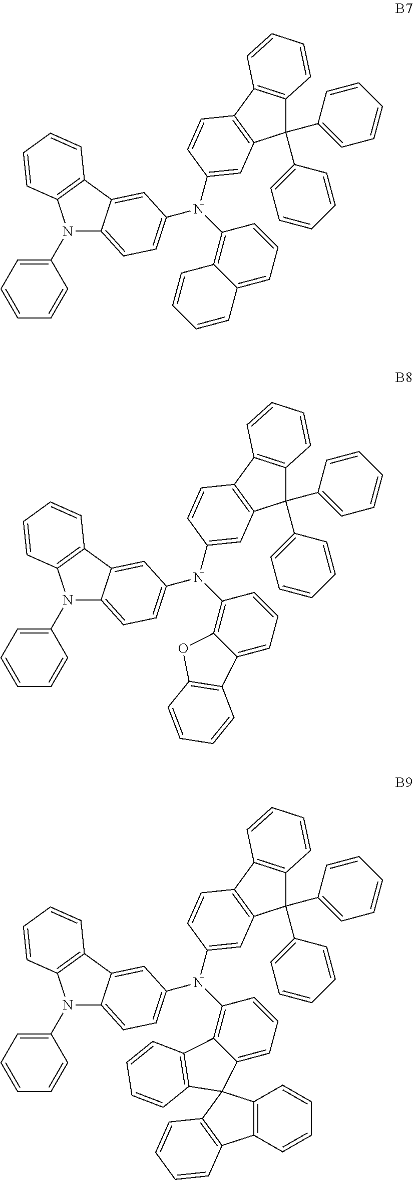 [SMILES: c1ccc(-n2c3ccccc3c3cc(N(c4ccc5c(c4)C(c4ccccc4)(c4ccccc4)c4ccccc4-5)c4cccc5ccccc45)ccc32)cc1 ; c1ccc(-n2c3ccccc3c3cc(N(c4ccc5c(c4)C(c4ccccc4)(c4ccccc4)c4ccccc4-5)c4cccc5c4oc4ccccc45)ccc32)cc1 ; c1ccc(-n2c3ccccc3c3cc(N(c4ccc5c(c4)C(c4ccccc4)(c4ccccc4)c4ccccc4-5)c4cccc5c4-c4ccccc4C54c5ccccc5-c5ccccc54)ccc32)cc1]

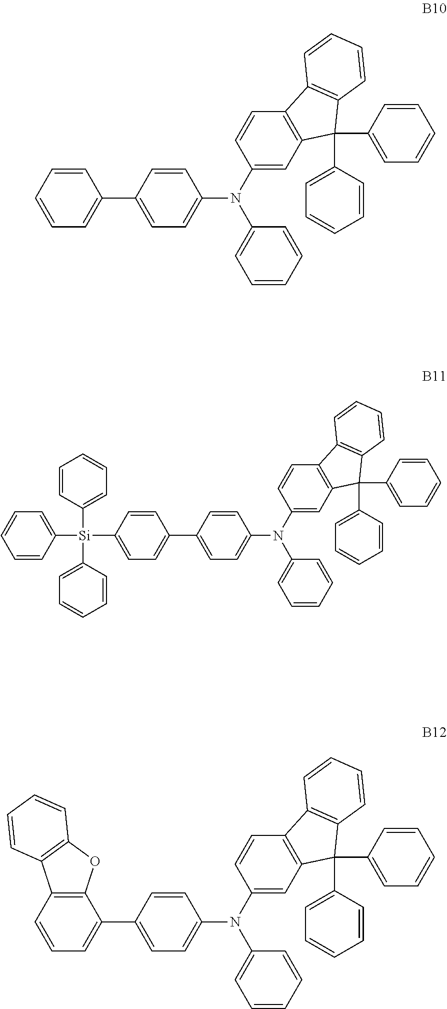 [SMILES: c1ccc(-c2ccc(N(c3ccccc3)c3ccc4c(c3)C(c3ccccc3)(c3ccccc3)c3ccccc3-4)cc2)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1 ; c1ccc(N(c2ccc(-c3cccc4c3oc3ccccc34)cc2)c2ccc3c(c2)C(c2ccccc2)(c2ccccc2)c2ccccc2-3)cc1]

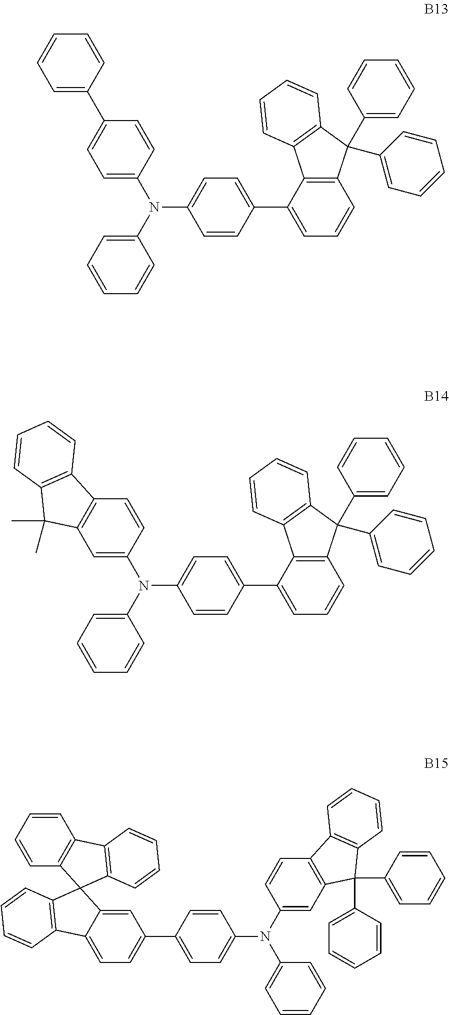 [SMILES: c1ccc(-c2ccc(N(c3ccccc3)c3ccc(-c4cccc5c4-c4ccccc4C5(c4ccccc4)c4ccccc4)cc3)cc2)cc1 ; CC1(C)c2ccccc2-c2ccc(N(c3ccccc3)c3ccc(-c4cccc5c4-c4ccccc4C5(c4ccccc4)c4ccccc4)cc3)cc21 ; c1ccc(N(c2ccc(-c3ccc4c(c3)C3(c5ccccc5-c5ccccc53)c3ccccc3-4)cc2)c2ccc3c(c2)C(c2ccccc2)(c2ccccc2)c2ccccc2-3)cc1]

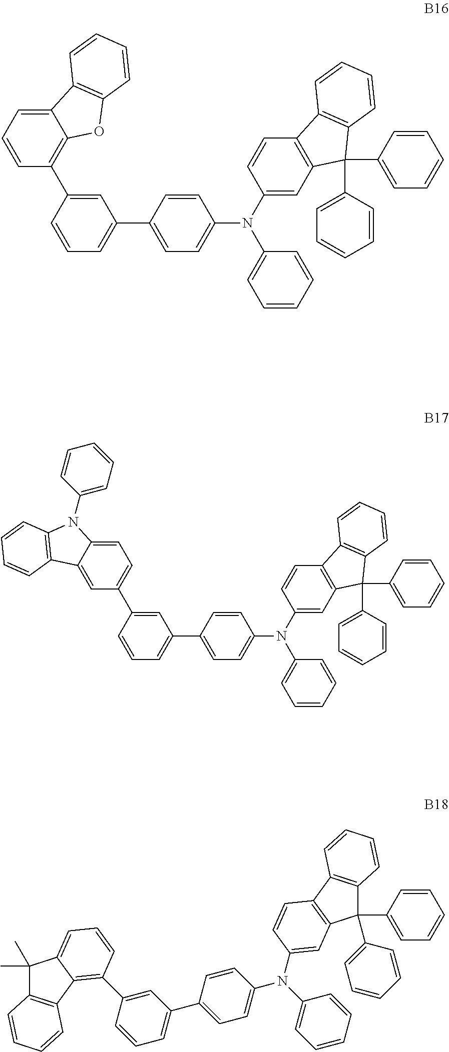 [SMILES: c1ccc(N(c2ccc(-c3cccc(-c4cccc5c4oc4ccccc45)c3)cc2)c2ccc3c(c2)C(c2ccccc2)(c2ccccc2)c2ccccc2-3)cc1 ; c1ccc(N(c2ccc(-c3cccc(-c4ccc5c(c4)c4ccccc4n5-c4ccccc4)c3)cc2)c2ccc3c(c2)C(c2ccccc2)(c2ccccc2)c2ccccc2-3)cc1 ; CC1(C)c2ccccc2-c2c(-c3cccc(-c4ccc(N(c5ccccc5)c5ccc6c(c5)C(c5ccccc5)(c5ccccc5)c5ccccc5-6)cc4)c3)cccc21]

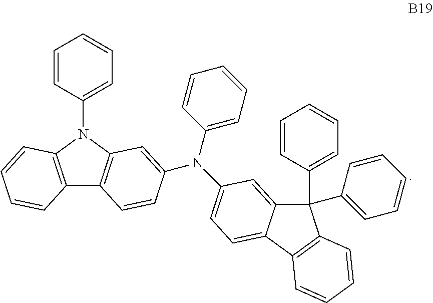 [SMILES: c1ccc(N(c2ccc3c(c2)C(c2ccccc2)(c2ccccc2)c2ccccc2-3)c2ccc3c4ccccc4n(-c4ccccc4)c3c2)cc1]

In an embodiment, the hole transport region HTR may further include a compound represented by Formula H-1:

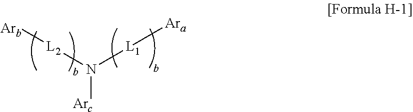

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms, or a substituted or unsubstituted heteroarylene group having 2 to 30 ring-forming carbon atoms.

In Formula H-1, Arₐ and Ar_{b} may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar_{c} may be a substituted or unsubstituted aryl group having 6 to 30 ring-forming carbon atoms.

In an embodiment, a compound represented by Formula H-1 may be a monoamine compound. In another embodiment, a compound represented by Formula H-1 may be a diamine compound in which at least one of Arₐ to Ar_{c} includes an amine group as a substituent. In still another embodiment, a compound represented by Formula H-1 may be a carbazole-based compound including a substituted or unsubstituted carbazole group in at least one of Arₐ or Ar_{b} or a substituted or unsubstituted fluorene-based group in at least one of Arₐ or Ar_{b}.

The compound represented by Formula H-1 may be any compound selected from Compound Group H. However, the compounds listed in Compound Group H are only examples, and the compound represented by Formula H-1 is not limited to Compound Group H:

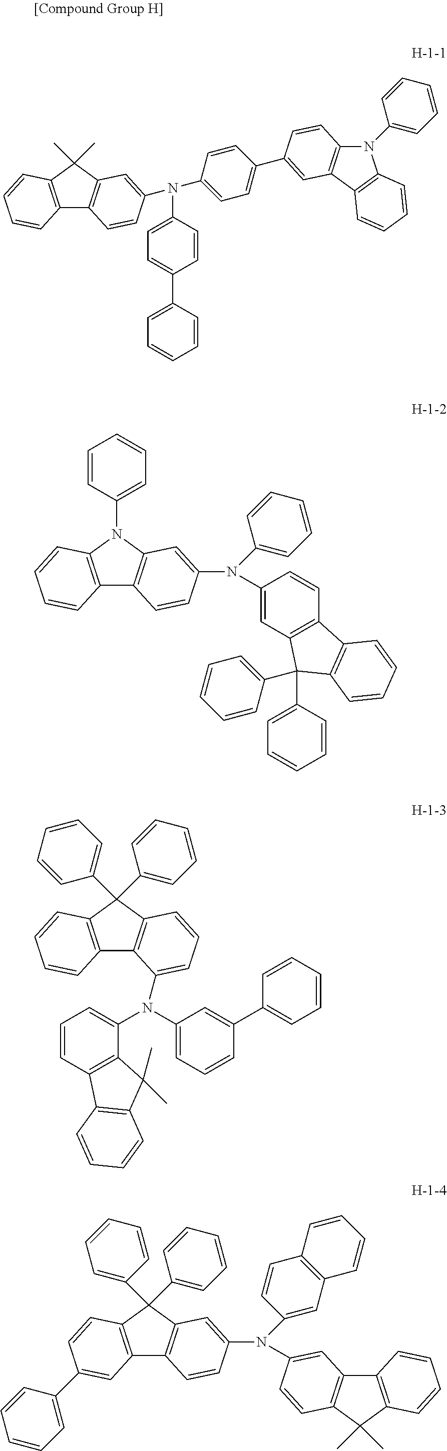 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

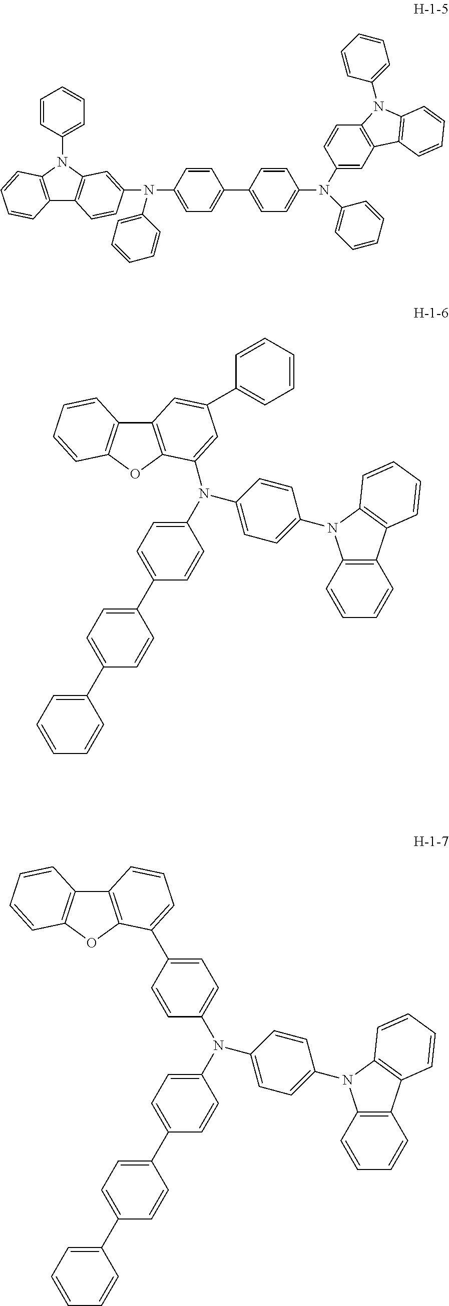 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

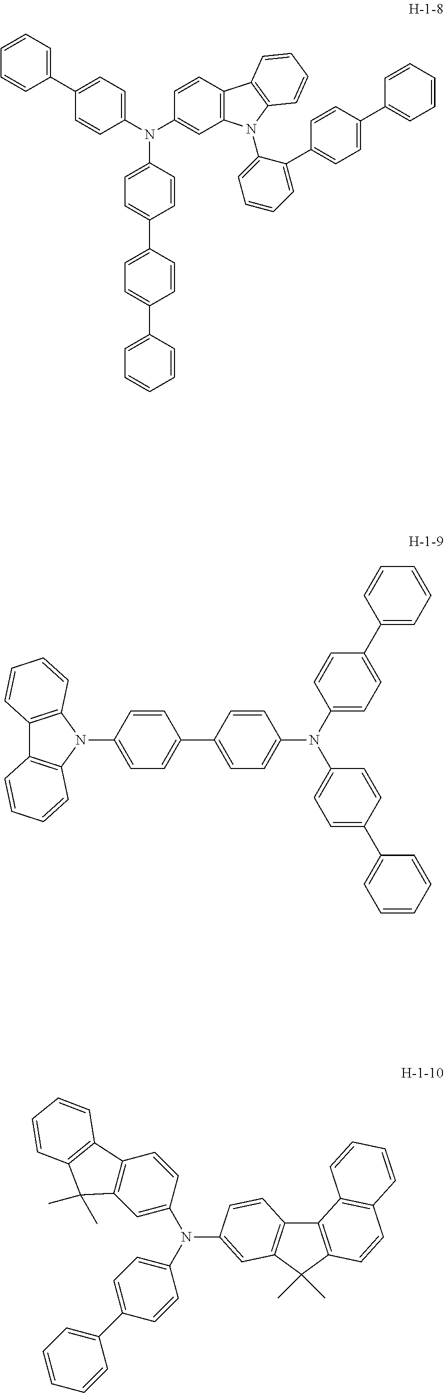 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

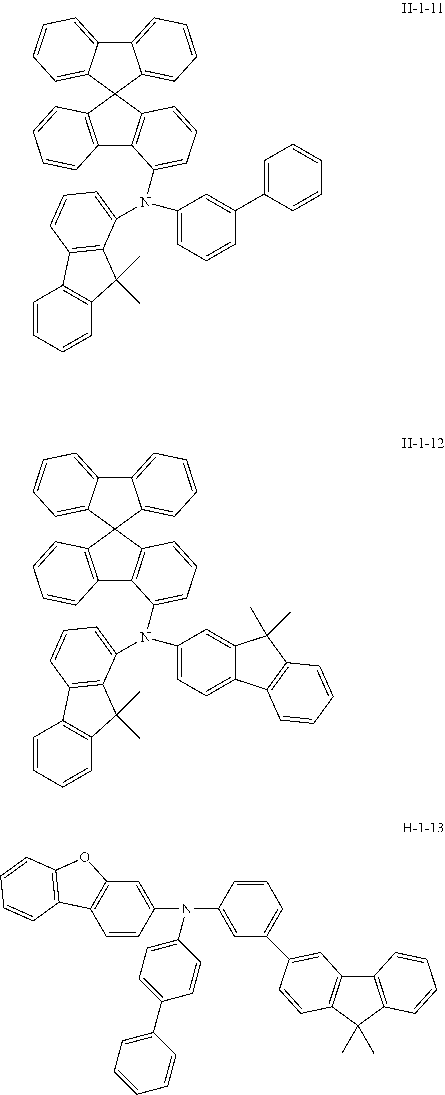 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

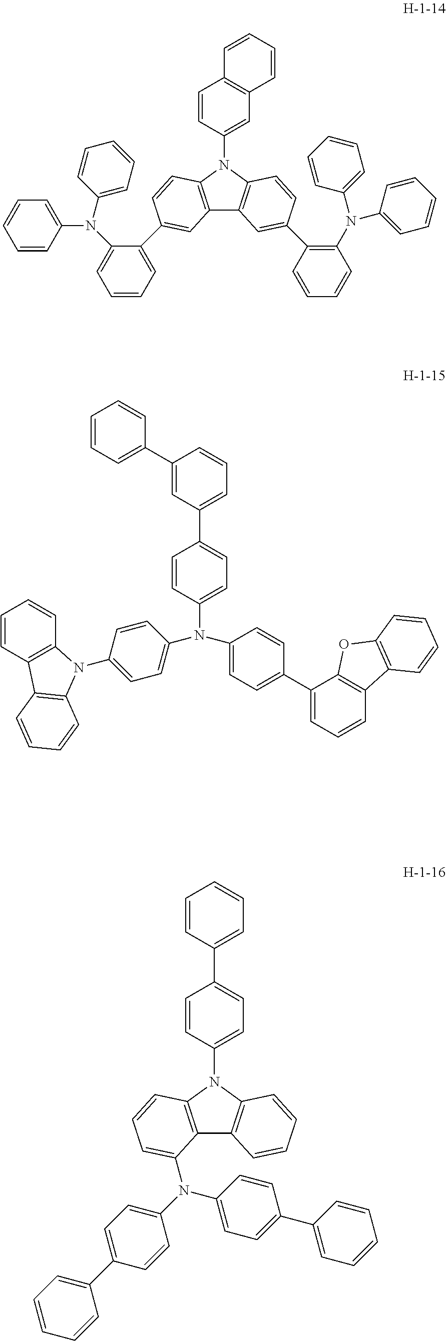 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

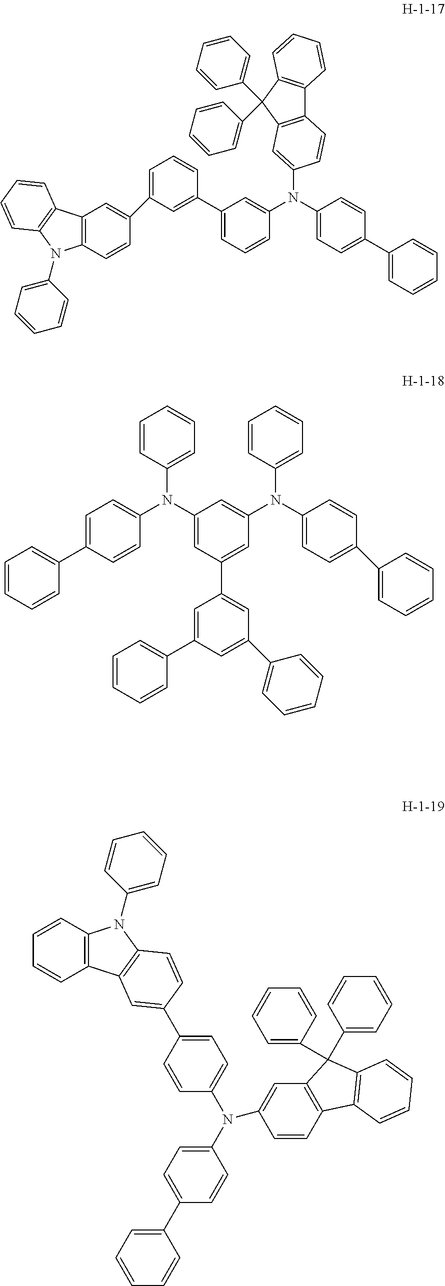 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In embodiments, the hole transport region HTR may further include a hole transport material of the related art.

For example, the hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine (DNTPD), 4,4′,4′-[tris(3-methylphenyl)phenylamino]triphenylamine] (m-MTDATA), 4,4′,4″-tris(N,N-diphenylamino)triphenylamine (TDATA), 4,4′,4″-tris[N(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB or NPD), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HATCN), etc.

The hole transport region HTR may include carbazole-based derivatives such as N-phenyl carbazole and polyvinyl carbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalee-l-yl)-N,N′-diphenyl-benzidine (NPB), 4,4′-Cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may further include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region described above in at least one of a hole injection layer HTL, a hole transport layer HTL, or an electron blocking layer EBL.

The hole transport region HTR may have a thickness in a range of about 100 Å to about 10,000 Å. For example, the hole transport region HTR may have a thickness in a range of about 100 Å to about 5,000 Å. When the hole transport region HTR includes a hole injection layer HTL, the hole injection layer HIL may have a thickness, for example, in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness, for example, in a range of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include halogenated metal compounds, quinone derivatives, metal oxides, cyano group-containing compounds, or any combination thereof. However, embodiments are not limited thereto. For example, the p-dopant may include halogenated metal compounds such as CuI and RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f: 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but is not limited thereto.

As described above, the hole transport region HTR may further include a buffer layer (not shown) in addition to the hole injection layer HIL, the hole transport layer HTL, and the electron blocking layer EBL. The buffer layer (not shown) may compensate for a resonance distance according to wavelengths of light emitted from an emission layer EML, and may thus increase light emitting efficiency. Materials which may be included in the hole transport region HTR may be used as materials included in the buffer layer (not shown).

The light emitting elements ED-1, ED-2, and ED-3 may include emission layers EML-R1, EML-R2, EML-G1, EML-G2, EML-B1, and EML-B2. For example, in each of the light emitting elements ED-1, ED-2, and ED-3, the first light emitting unit OL1 may include first emission layers EML-R1, EML-G1, and EML-B1, and the second light emitting unit OL2 may include second emission layers EML-R2, EML-G2, and EML-B2. In an embodiment, the first light emitting unit OL1 may include a first red emission layer EML-R1 corresponding to the first light emitting region PXA-R, a first green emission layer EML-G1 corresponding to the second light emitting region PXA-G, and a first blue emission layer EML-B1 corresponding to the third light emitting region PXA-B. The second light emitting unit OL2 may include a second red emission layer EML-R2 corresponding to the first light emitting region PXA-R, a second green emission layer EML-G2 corresponding to the second light emitting region PXA-G, and a second blue emission layer EML-B2 corresponding to the third light emitting region PXA-B. In a plan view, the first red emission layer EML-R1 may overlap the second red emission layer EML-R2, the first green emission layer EML-G1 may overlap the second green emission layer EML-G2, and the first blue emission layer EML-B1 may overlap the second blue emission layer EML-B2. The first emission layers EML-R1, EML-G1, and EML-B1 and the second emission layers EML-R2, EML-G2, and EML-B2 may not overlap the non-light emitting region NPXA.

In an embodiment, the first emission layers EML-R1, EML-G1, and EML-B1 included in the first light emitting unit OL1 may be provided on the hole transport region HTR, the second emission layers EML-R2, EML-G2, and EML-B2 included in the second light emitting unit OL2 may be provided on the charge generation layer CGL. For example, the first light emitting element ED-1 may include the first electrode EL1, the hole transport region HTR, the first red emission layer EML-R1, the first electron transport region ETR1, the charge generation layer CGL, the second red emission layer EML-R2, the second electron transport region ETR2, and the second electrode EL2, which are sequentially stacked. The second light emitting element ED-2 may include the first electrode EL1, the hole transport region HTR, the first green emission layer EML-G1, the first electron transport region ETR1, the charge generation layer CGL, the second green emission layer EML-G2, the second electron transport region ETR2, and the second electrode EL2, which are sequentially stacked. The third light emitting element ED-3 may include the first electrode EL1, the hole transport region HTR, the first blue emission layer EML-B1, the first electron transport region ETR1, the charge generation layer CGL, the second blue emission layer EML-B2, the second electron transport region ETR2, and the second electrode EL2, which are sequentially stacked.

The first emission layers EML-R1, EML-G1, and EML-B1, and the second emission layers EML-R2, EML-G2, and EML-B2 may each independently have a thickness in a range of about 100 Å to about 1,000 Å. For example, the first emission layers EML-R1, EML-G1, and EML-B1, and the second emission layers EML-R2, EML-G2, and EML-B2 may each independently have a thickness in a range of about 100 Å to about 300 Å. The emission layers EML-R1, EML-R2, EML-G1, EML-G2, EML-B1, and EML-B2 may each independently be a layer formed of a single material, a layer formed of different materials, or a structure having multiple layers formed of different materials.

The light emitting elements ED-1, ED-2, and ED-3 each independently include an amine compound according to an embodiment, which is described above in the hole transport region HTR, and may thus exhibit high efficiency and long life in the red, green, and blue light emitting regions. However, embodiments are not limited thereto.

In the light emitting elements ED-1, ED-2, and ED-3, the first emission layers EML-R1, EML-G1, and EML-B1 and the second emission layers EML-R2, EML-G2, and EML-B2 may include the same or different compounds. The first emission layers EML-R1, EML-G1, and EML-B1, and the second emission layers EML-R2, EML-G2, and EML-B2 may each independently include an anthracene derivative, a pyrene derivative, a fluoranthene derivative, a chrysene derivative, a dihydrobenzanthracene derivative, or a triphenylene derivative.

In the light emitting elements ED-1, ED-2, and ED-3 as shown in FIGS. 3 to 6, the emission layers EML-R1, EML-R2, EML-G1, EML-G2, EML-B1, and EML-B2 may each independently include a host and a dopant, and the emission layers EML-R1, EML-R2, EML-G1, EML-G2, EML-B1, and EML-B2 may include a compound represented by Formula E-1. The compound represented by Formula E-1 may be used as a fluorescent host material:

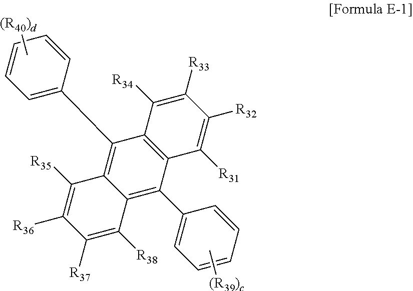

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula E-1, R₃₁ to R₄₀ may be linked to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compounds E1 to E19:

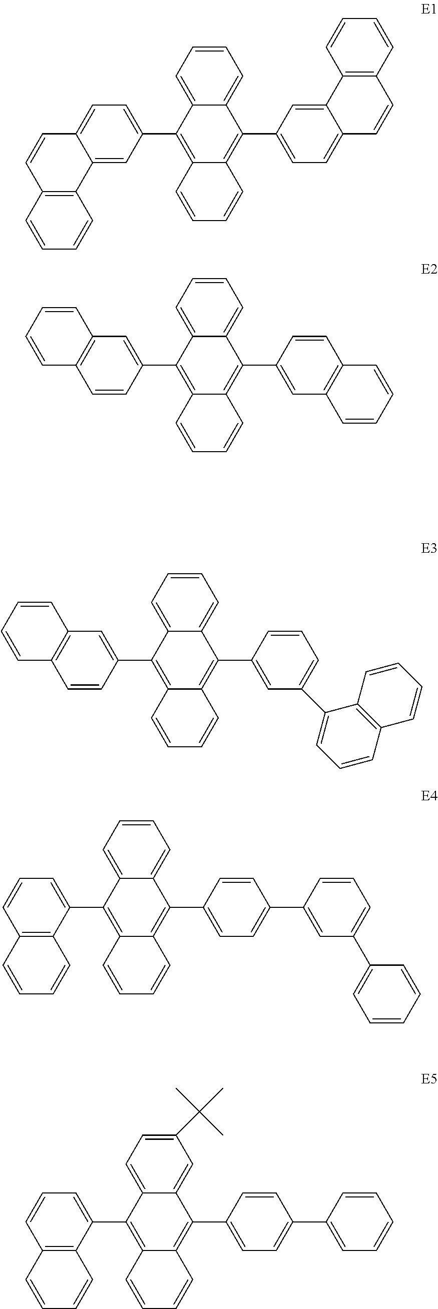

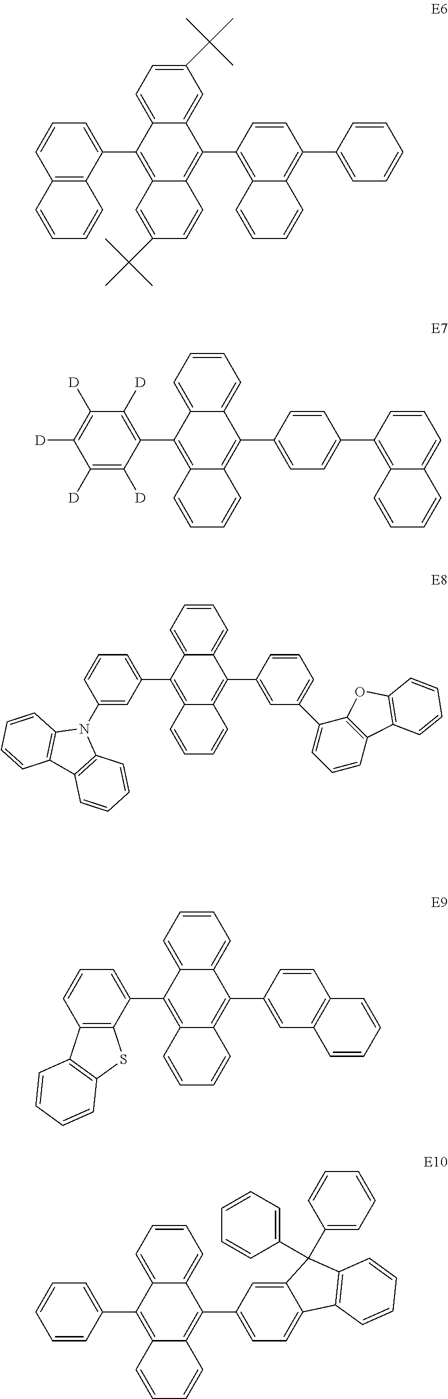

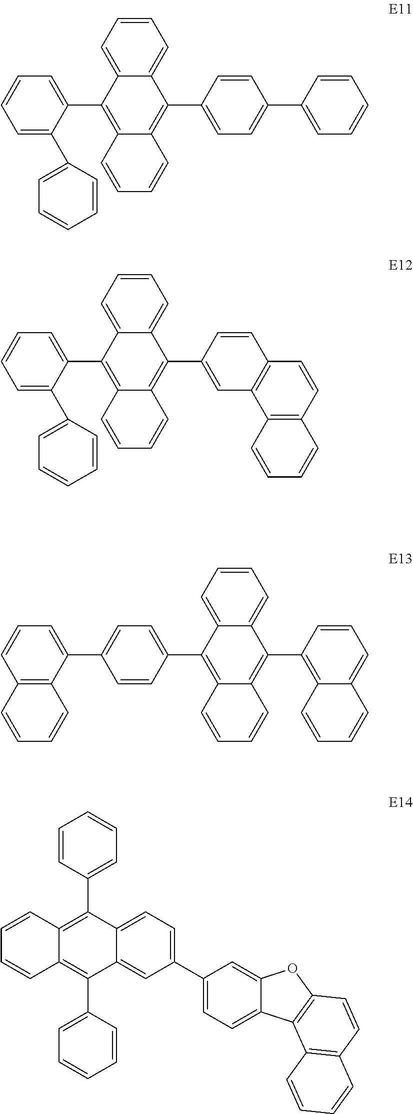

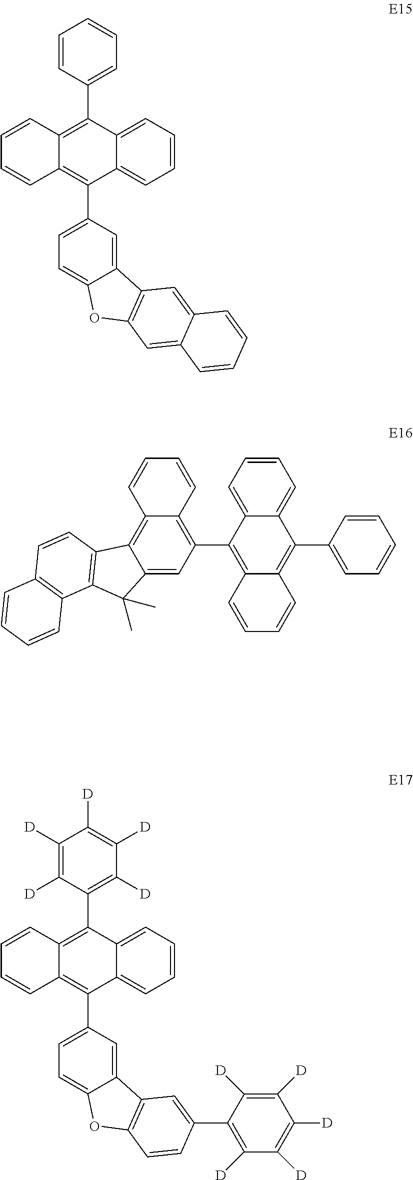

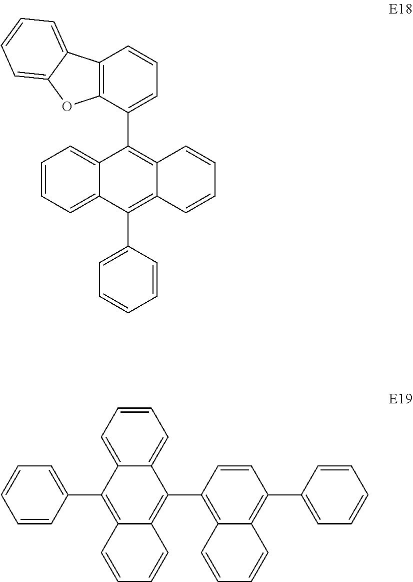

In an embodiment, the emission layers EML-R1, EML-R2, EML-G1, EML-G2, EML-B1, and EML-B32 may each independently include a compound represented by Formula E-2a or Formula E-2b. The compound represented by Formula E-2a or Formula E-2b may be used as a phosphorescent host material:

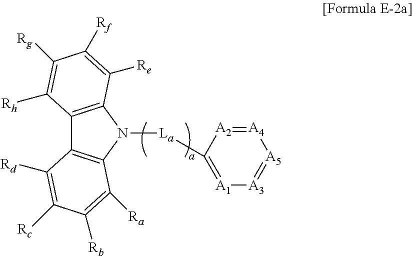

In Formula E-2a, a may be an integer from 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc. as a ring-forming atom.

In Formula E-2a, two or three of A₁ to A₅ may each be N, and the remainder of A₁ to A₅ may each independently be C(Rᵢ).

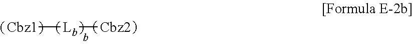

In Formula E-2b, Cbz1 and Cbz2 may each independently be an unsubstituted carbazole group or carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or greater, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

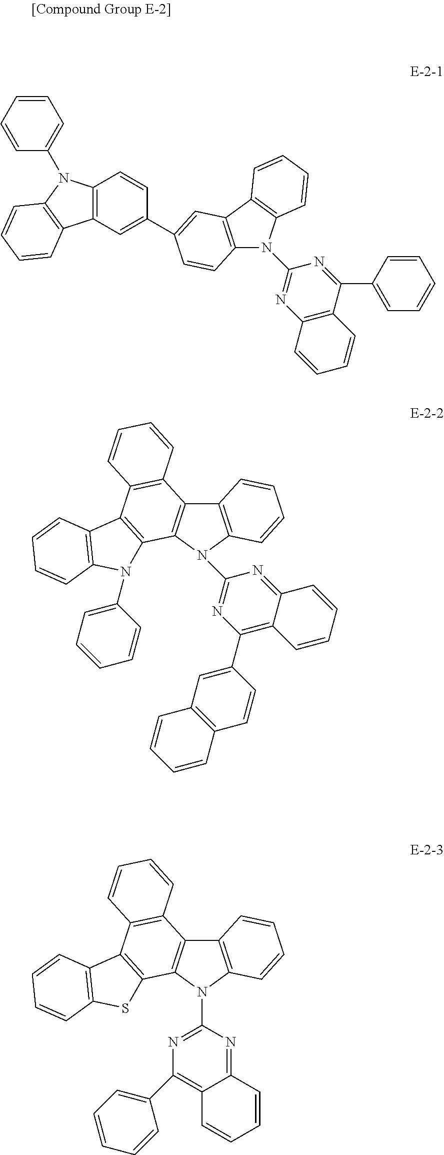 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

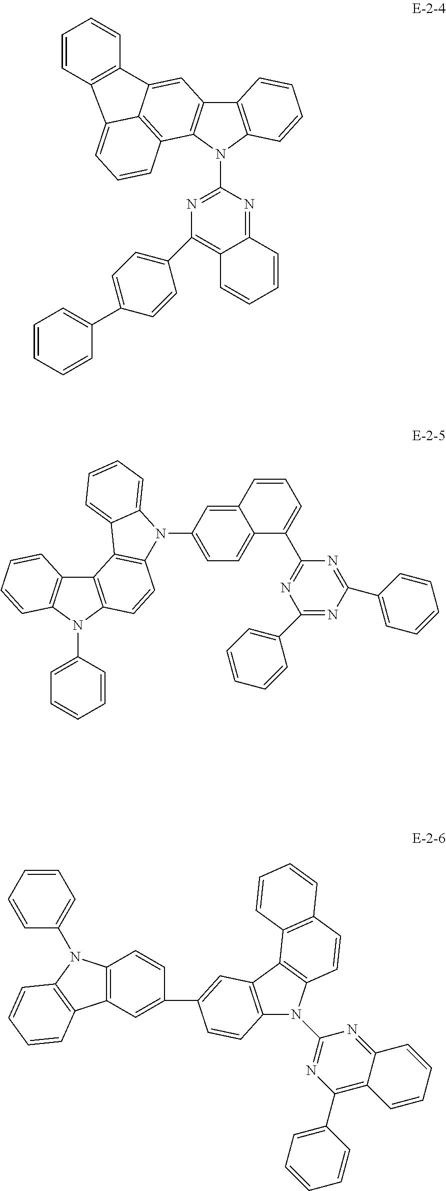 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

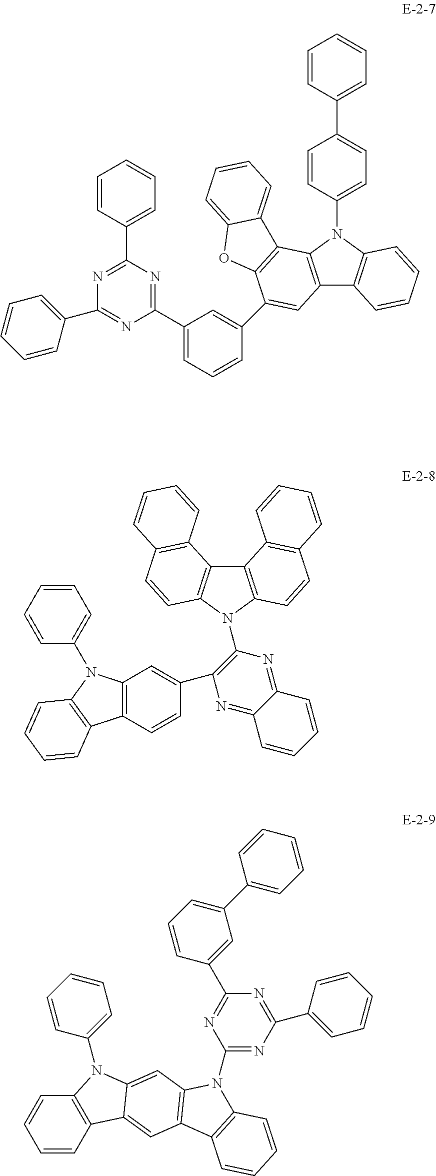 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

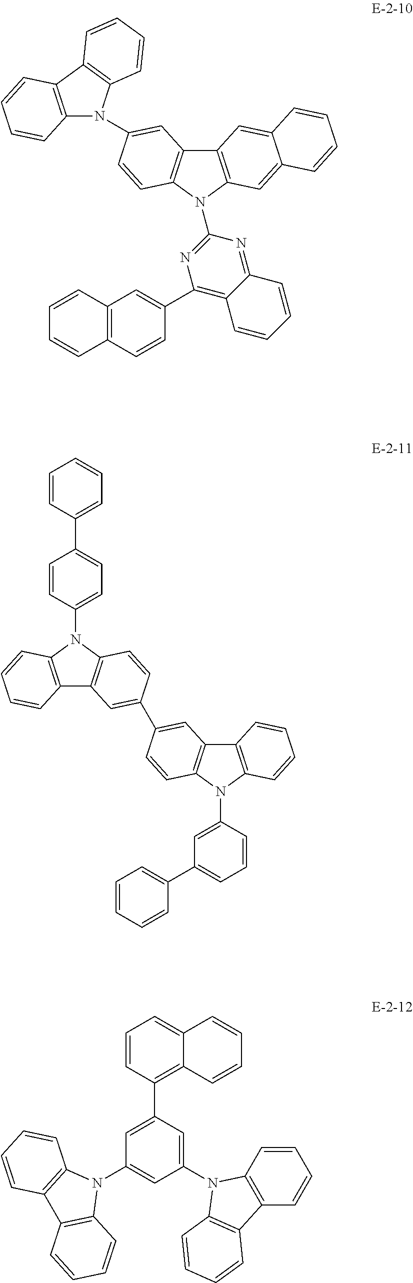 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

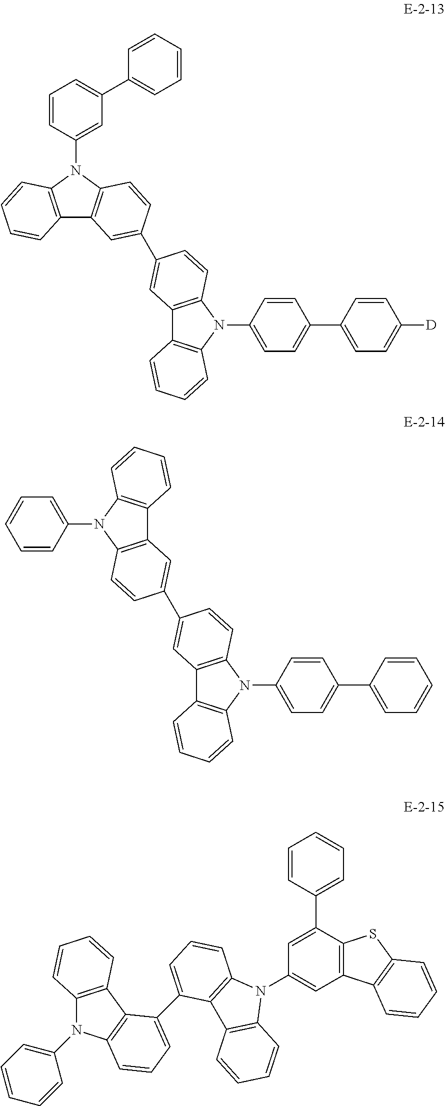 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

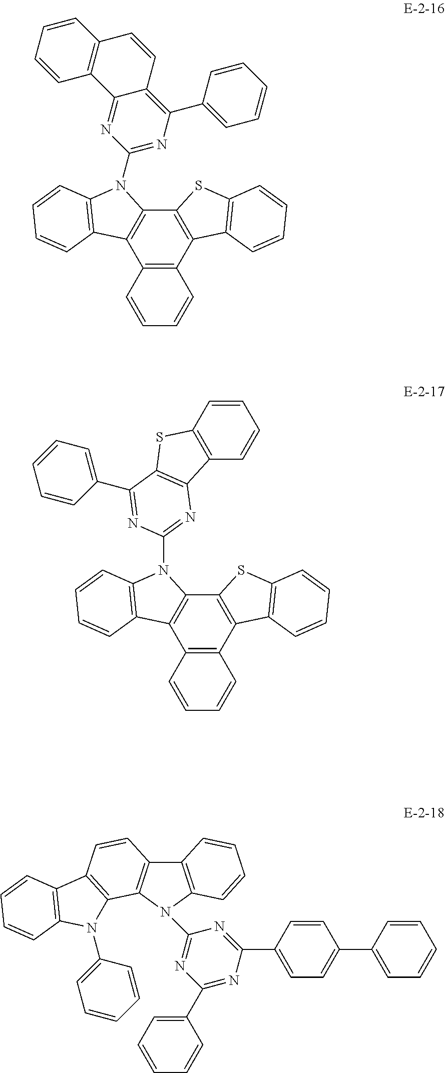 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

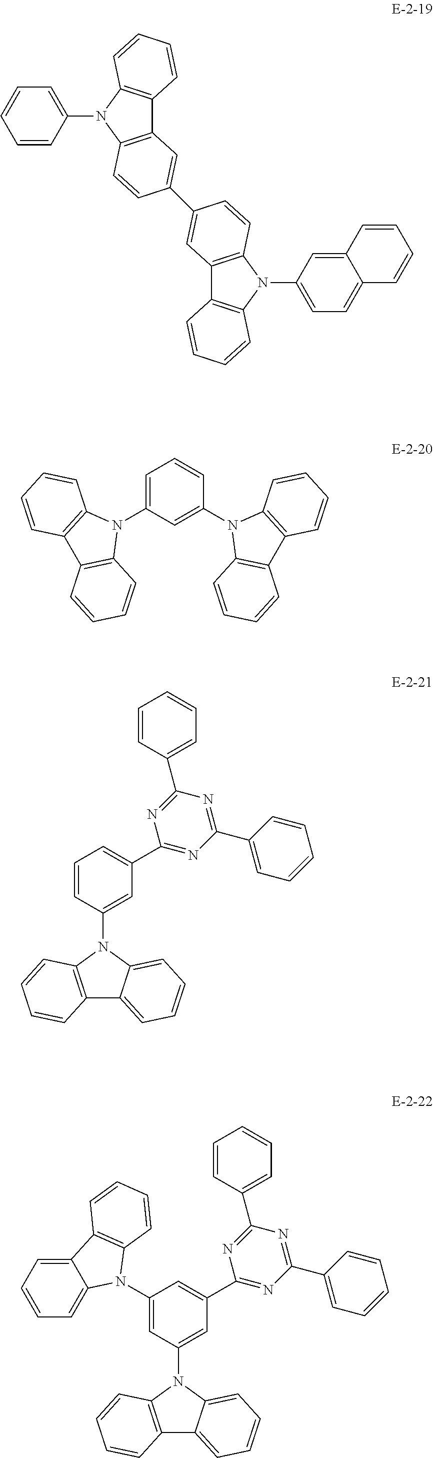 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

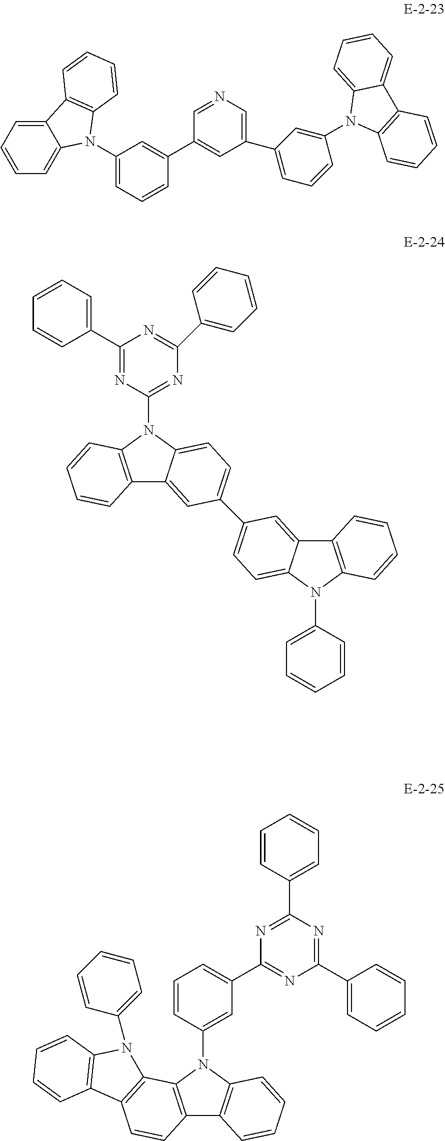 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3cccc(-n4c5ccccc5c5ccc6c7ccccc7n(-c7ccccc7)c6c54)c3)n2)cc1]

The emission layers EML-R1, EML-R2, EML-G1, EML-G2, EML-B1, and EML-B2 may each independently further include a material of the related art as a host material. For example, the emission layers EML-R1, EML-R2, EML-G1, EML-G2, EML-B1, and EML-B2 may each independently include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, embodiments are not limited thereto. For example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

The emission layers EML-R1, EML-R2, EML-G1, EML-G2, EML-B1, and EML-B2 may each independently include a compound represented by Formula M-a or Formula M-b. The compound represented by Formula M-a or Formula M-b may be used as a phosphorescent dopant material. In an embodiment, the compound represented by Formula M-a or Formula M-b may be used an assistant dopant material.

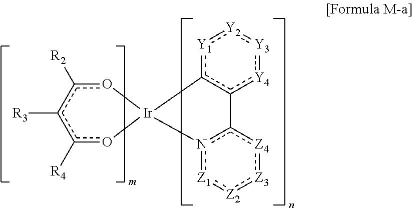

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

The compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

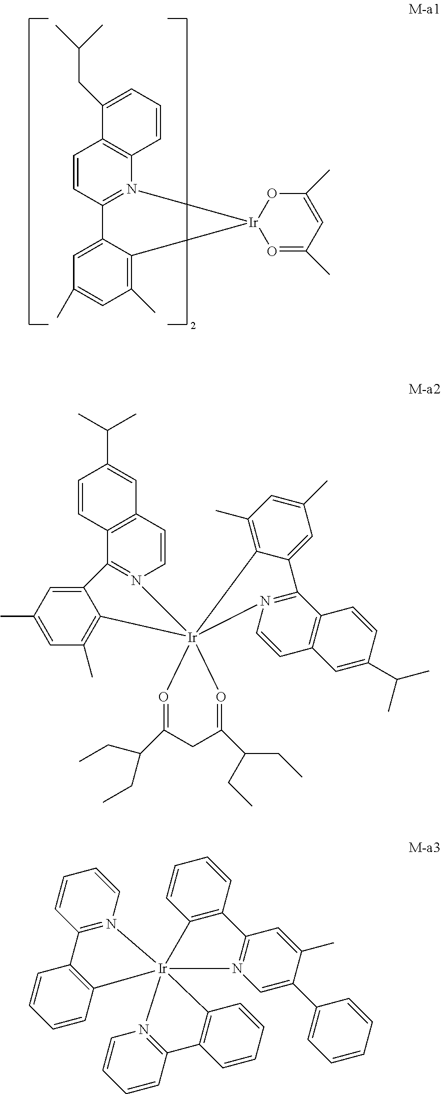

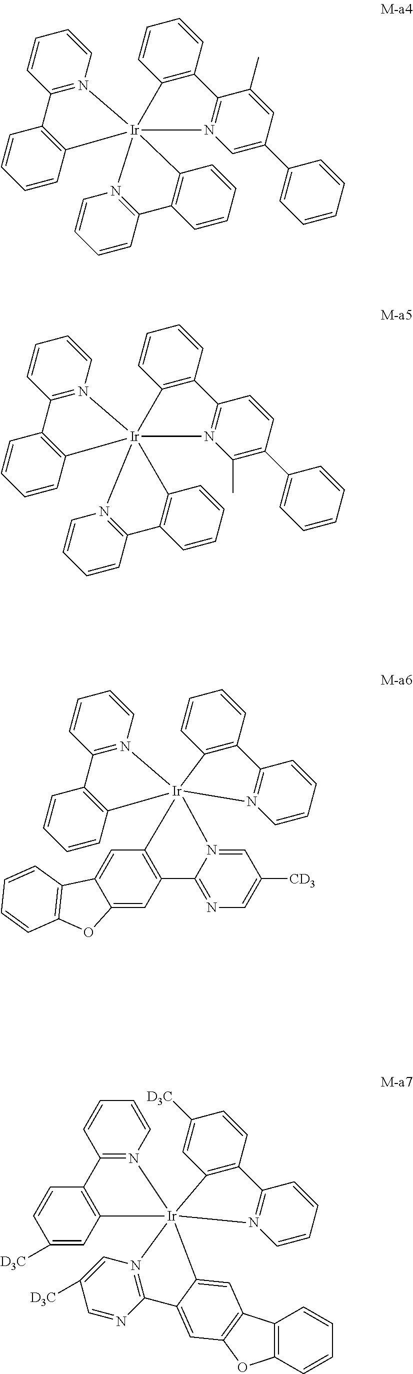

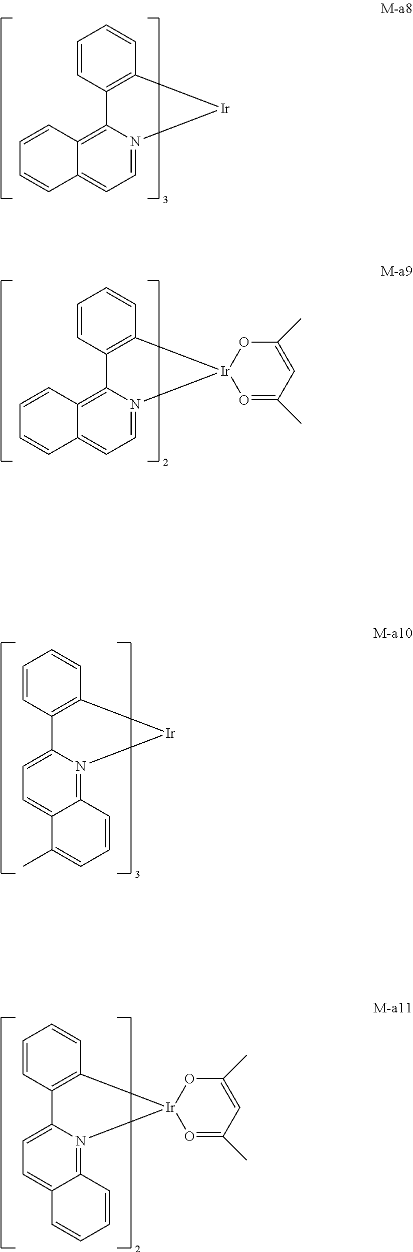

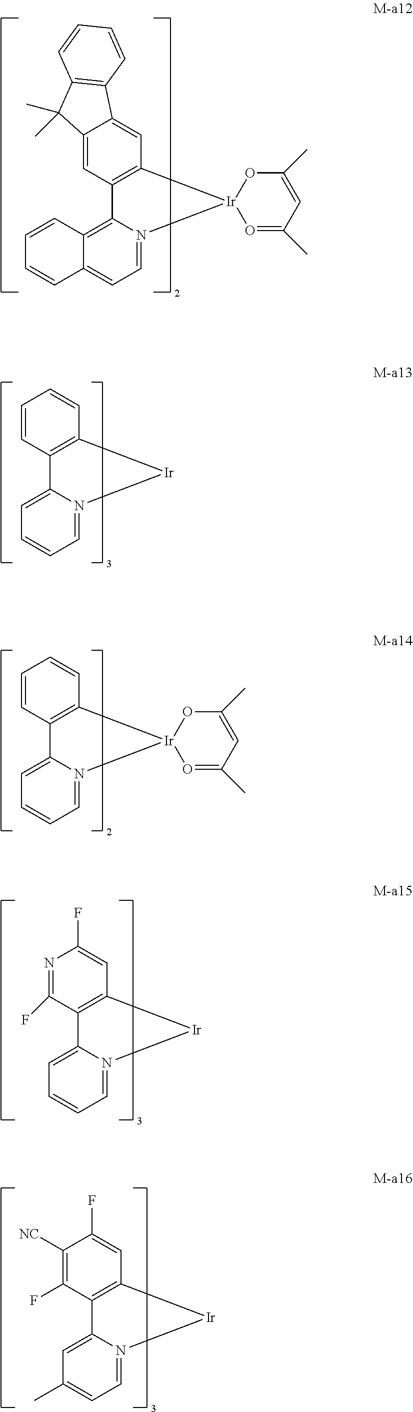

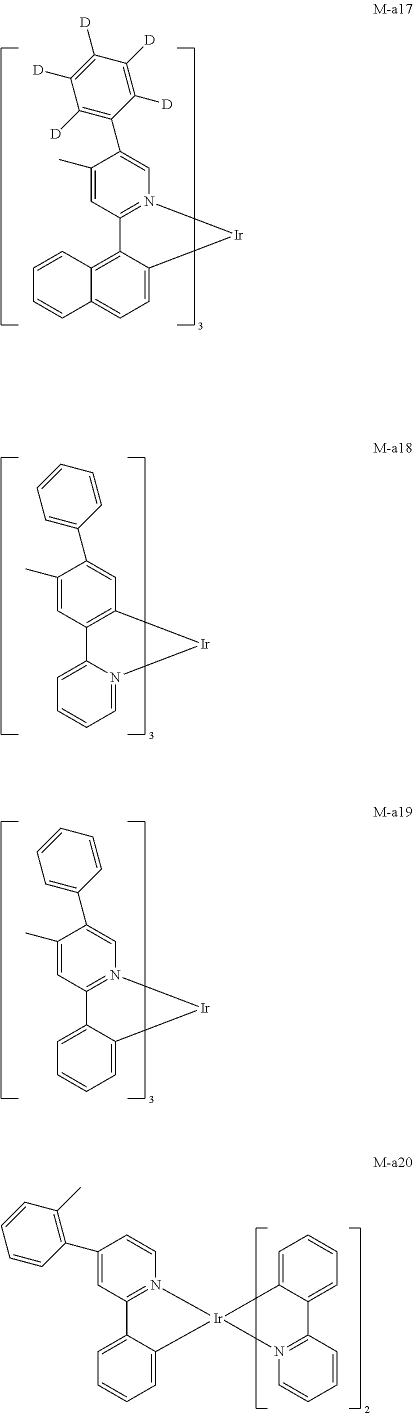

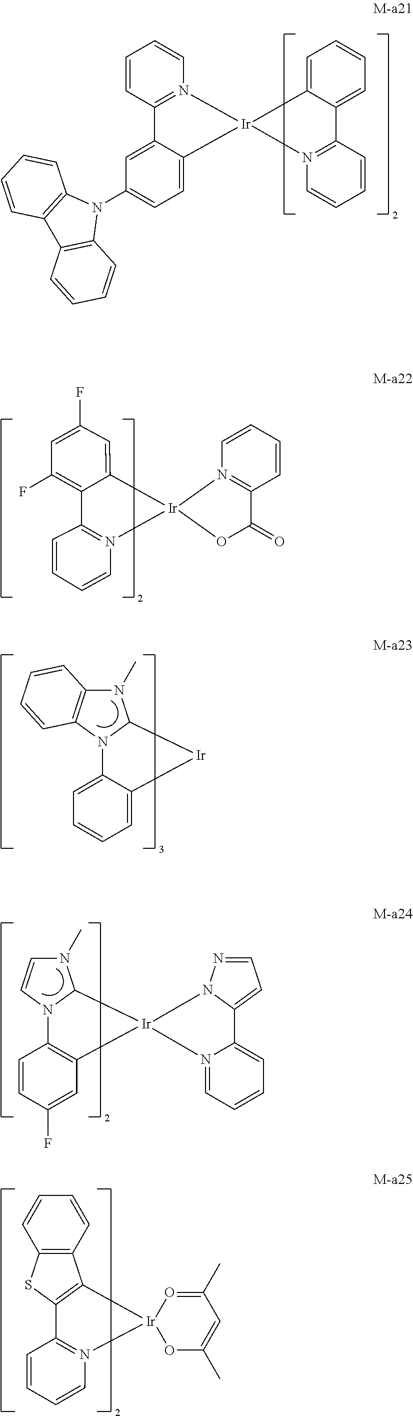

Compound M-a1, Compound M-a2, and Compound M-a11 may each be used as a red dopant material, and Compounds M-a3 to M-a7, and Compound M-a13 may each be used as a green dopant material.

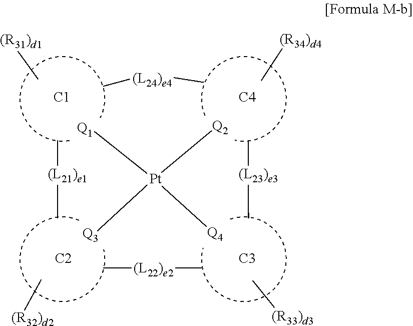

In Formula M-b, Q₁ to Q₄ may each independently be C or N; and C1 to C4 may each independently be a substituted or unsubstituted hydrocarbon ring having 5 to 30 ring-forming carbon atoms, or a substituted or unsubstituted heterocycle having 2 to 30 ring-forming carbon atoms. In Formula M-b, L₂₁ to L₂₄ may each independently be a direct linkage,

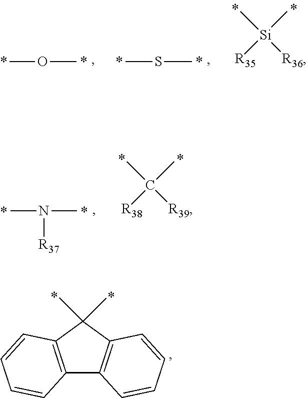

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; and el to e4 may each independently be 0 or 1. In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; and d1 to d4 may each independently be an integer from 0 to 4.

The compound represented by Formula M-b may be used as a blue phosphorescent dopant or a green phosphorescent dopant. In an embodiment, the compound represented by Formula M-b may be further included as an auxiliary dopant in the emission layers EML-R1, EML-R2, EML-G1, EML-G2, EML-B1, and EML-B2.

The compound represented by Formula M-b may be any compound selected from Compounds M-b-1 to M-b-11. However, Compounds M-b-1 to M-b-11 are only examples, and the compound represented by Formula M-b is not limited to Compounds M-b-1 to M-b-11:

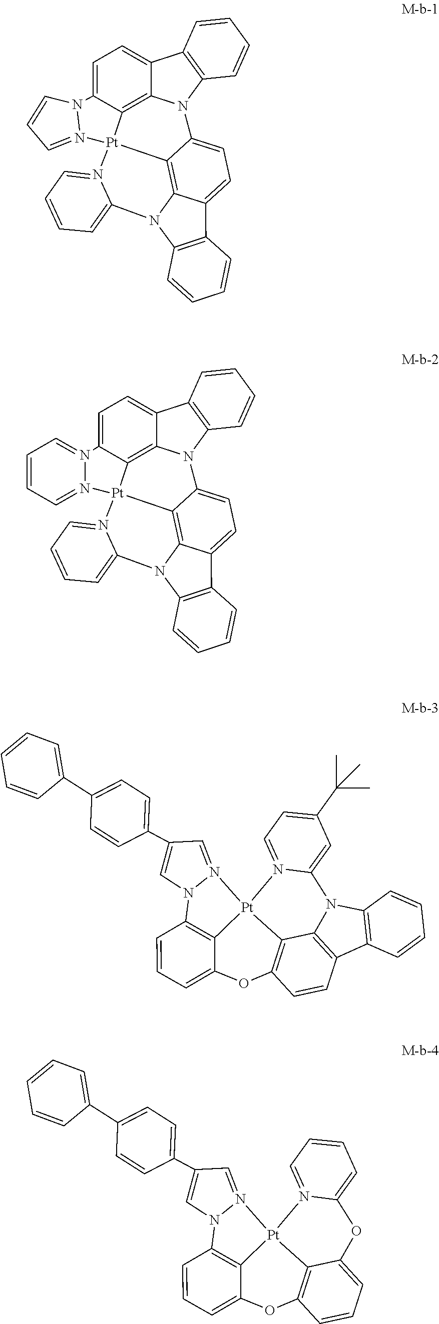

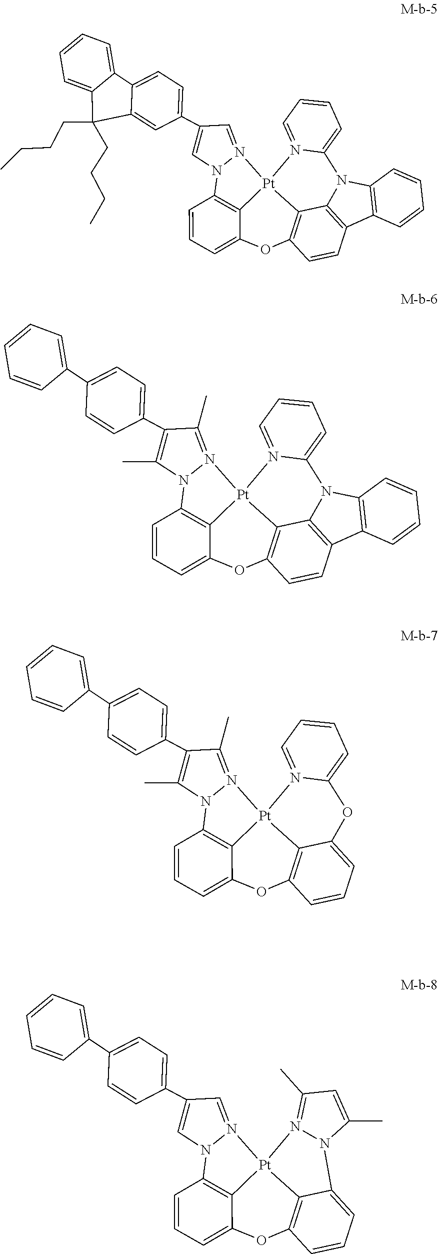

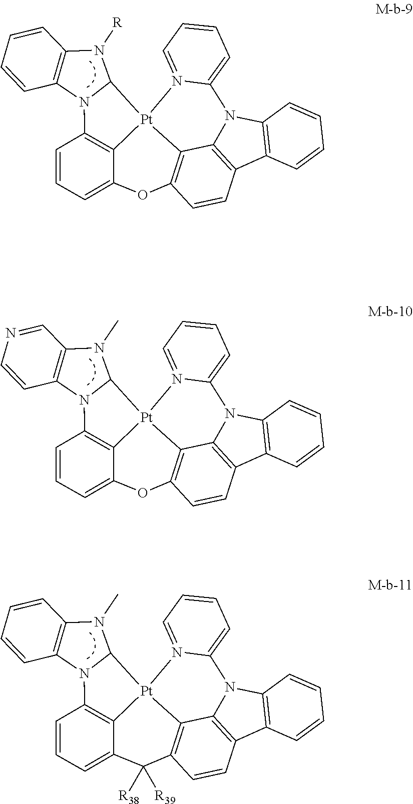

In Compounds M-b-1 to M-b-11, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layers EML-R1, EML-R2, EML-G1, EML-G2, EML-B1, and EML-B2 may further include a compound represented by any one of Formulas F-a to F-c. The compounds represented by Formulas F-a to F-c below may be used as a fluorescent dopant material.

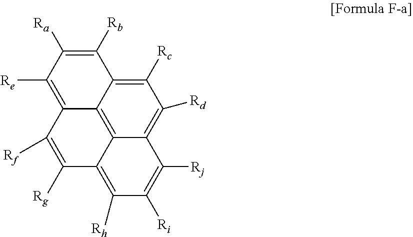

In Formula F-a above, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula F-a, in the group represented by *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

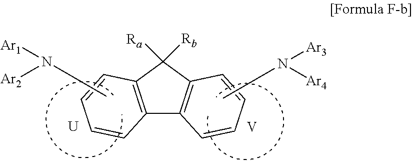

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a fused polycyclic compound having four rings. When U and V are each 0, a fused ring having a fluorene core of Formula F-b may be a fused polycyclic compound having three rings. When U and V are each 1, a fused ring having a fluorene core of Formula F-b may be a fused polycyclic compound having five rings.

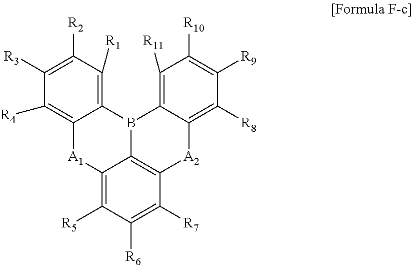

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula F-c, A₁ and A₂ may each independently be bonded to substituents of neighboring rings to form a fused ring. For example, when A₁ and A₂ are each independently N(Rₘ), A₁ may be bonded to R₄ or R₅ to form a ring. For example, A₂ may be bonded to R₇ or R₈ to form a ring.

In embodiments, the emission layers EML-R1, EML-R2, EML-G1, EML-G2, EML-B1, and EML-B2 may include, as a dopant material of the related art, styryl derivatives (e.g., 1,4-bis[2-(3-N-ethylcarbazoryl)vinyl]benzene (BCzVB), 4-(di-p-tolylamino)-4″-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), etc.

In an embodiment, at least one of the emission layers EML-R1, EML-R2, EML-G1, EML-G2, EML-B1, or EML-B2 may include a phosphorescent dopant material of the related art. For example, a phosphorescent dopant may include a metal complex including iridium (Ir), platinum (Pt), osmium (Os), gold (Au), titanium (Ti), zirconium (Zr), hafnium (Hf), europium (Eu), and terbium (Tb), or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), platinum octaethyl porphyrin (PtOEP), etc. may be used as a phosphorescent dopant. However, embodiments are not limited thereto.

In an embodiment, the emission layers EML-R1, EML-R2, EML-G1, EML-G2, EML-B1, and EML-B2 may include a hole transporting host and an electron transporting host. In an embodiment, the emission layers EML-R1, EML-R2, EML-G1, EML-G2, EML-B1, and EML-B2 may include an auxiliary dopant and a light emitting dopant. The auxiliary dopant may include a phosphorescent dopant material or a thermally activated delayed fluorescent dopant material. For example, in an embodiment, the emission layer EML may include a hole transporting host, an electron transporting host, an auxiliary dopant, and a light emitting dopant.

In in the emission layers EML-R1, EML-R2, EML-G1, EML-G2, EML-B1, and EML-B2, the hole transporting host and the electron transporting host may form an exciplex. A triplet energy level of the exciplex formed by the hole transporting host and the electron transporting host may correspond to T1, which is a gap between a lowest unoccupied molecular orbital (LUMO) energy level of the electron transporting host and a highest occupied molecular orbital (HOMO) energy level of the hole transporting host.

In an embodiment, a triplet energy level T1 of the exciplex formed by the hole transporting host and the electron transporting host may be in a range of about 2.4 eV to about 3.0 eV. In an embodiment, a value of the triplet energy level of the exciplex may less than an energy gap of each host material. Accordingly, the exciplex may have a triplet energy level equal or less than about 3.0 eV, which is an energy gap between the hole transporting host and the electron transporting host.

In an embodiment, at least one of the emission layers EML-R1, EML-R2, EML-G1, EML-G2, EML-B1, or EML-B2 may include a quantum dot. The quantum dot may be a Group II-VI compound, a Group III-VI compound, a Group 1-III-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof, or any combination thereof.

The Group III-VI compound may include: a binary compound such as In₂S₃ and In₂Se₃; a ternary compound such as InGaS₃ and InGaSe₃; or any combination thereof.

The Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, or any mixture thereof, a quaternary compound such as AgInGaS₂ and CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof, or any combination thereof. In an embodiment, the Group III-V compound may further include a Group II metal. For example, InZnP, etc. may be selected as a Group III-II-V compound.

The Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof, a quaternary compound selected from the group consisting of SnPbSSe, SnPbSeTe, SnPbSTe, and a mixture thereof; or any combination thereof. The Group IV element may be Si, Ge, or a mixture thereof. The Group IV compound may include a binary compound selected from the group consisting of SiC, SiGe, and a mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which a quantum dot surrounds another quantum dot. A quantum dot having a core/shell structure may have a concentration gradient in which the concentration of a material that is present in the shell decreases towards the core.

In embodiments, a quantum dot may have a core/shell structure including a core having nanocrystals and a shell surrounding the core. The shell of the quantum dot may serve as a protection layer to prevent the chemical deformation of the core so as to keep semiconductor properties, and/or may serve as a charging layer to impart electrophoresis properties to the quantum dot. The shell may be a single layer or multiple layers. Examples of the shell of the quantum dot may include a metal oxide, a non-metal oxide, a semiconductor compound, or any combination thereof.

For example, the metal oxide or the non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO; a ternary compound such as MgAl₂O₄, CoFe₂O₄, NiFe₂O₄, and CoMn₂O₄; or any combination thereof. However, embodiments are not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum equal to or less than about 45 nm. For example, a quantum dot may have a FWHM of an emission wavelength spectrum equal to or less than about 40 nm. For example, a quantum dot may have a FWHM of an emission wavelength spectrum equal to or less than about 30 nm. Color purity or color reproducibility may be enhanced in the above ranges. Light emitted through such a quantum dot may be emitted in all directions, so that a wide viewing angle may be improved.

The form of a quantum dot is not particularly limited, as long as it is any form that is used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplatelets, etc.

The quantum dot may control the colors of emitted light according to a particle size thereof. Accordingly, the quantum dot may have various light emission colors such as blue, red, green, etc.

In the light emitting elements ED-1, ED-2, and ED-3 according to embodiment shown in FIGS. 3 to 6, a charge generation layer CGL including an n-type charge generation layer nCGL and a p-type charge generation layer pCGL is provided between the first light emitting unit OL1 and the second light emitting unit OL2.

In an embodiment, the n-type charge generation layer nCGL may be disposed adjacent to the first light emitting unit OL1, and the p-type charge generation layer pCGL may be disposed adjacent to the second light emitting unit OL2. The n-type charge generation layer nCGL may be provided as a common layer for the first light emitting region PXA-R, the second light emitting region PXA-G, and the third light emitting region PXA-B on the first light emitting unit OL1. For example, in a plan view the n-type charge generation layer nCGL may overlap (for example, completely overlap) the first light emitting region PXA-R, the second light emitting region PXA-G, the third light emitting region PXA-B, and the non-light emitting region NPXA. The n-type charge generation layer nCGL may have a thickness, for example, in a range of about 50 Å to about 300 Å.

The n-type charge generation layer n-CGL may be formed of a single layer of an n-type material or may be a layer in which an n-type dopant is doped into an electron transport material serving as a matrix. As the electron transport material, materials of the related art may be employed without limitation, and the material may be selected from examples of materials for the first and second electron transport regions ETR1 and ETR2, which will be described later. For example, the n-type dopant may be an arylamine-based organic compound such as α-NPD, 2-TNATA, TDATA, MTDATA, spiro-TAD, or spiro-NPB.

The n-type charge generation layer n-CGL may include a same material as any one of an electron transport layer or an electron injection layer of the first electron transport region ETR1 as a matrix, and may be a layer doped with an n-type dopant. When the n-type charge generation layer n-CGL includes an n-type dopant, a doping ratio of the n-type dopant may be in a range of about 1 wt % to about 10 wt % with respect to a total weight of the n-type charge generation layer n-CGL. For example, a doping ratio of the n-type dopant may be in a range of about 2 wt % to about 5 wt % with respect to a total weight of the n-type charge generation layer n-CGL. However, embodiments are not limited thereto.

The p-type charge generation layer pCGL may include a first p-type charge generation layer pCGL-1, a second p-type charge generation layer pCGL-2, and a third p-type charge generation layer pCGL-3, which are disposed on the n-type charge generation layer nCGL and spaced apart from each other. The first to third p-type charge generation layers pCGL-1, pCGL-2, and pCGL-3 may overlap the first to third light emitting regions PXA-R, PXA-G, and PXA-B in a plan view, and may not overlap the non-light emitting regions NPXA. The p-type charge generation layer pCGL may provide holes to the second light emitting unit OL2. Accordingly, the second light emitting unit OL2 may not include a hole transport region.

In an embodiment, the first to third p-type charge generation layers pCGL-1, pCGL-2, and pCGL-3 may have different thicknesses. For example, the first p-type charge generation layer pCGL-1 overlapping the first light emitting region PXA-R may have a greater thickness than the second p-type charge generation layer pCGL-2 overlapping the second light emitting region PXA-G. For example, the second p-type charge generation layer pCGL-2 may have a thickness greater than or equal to that of the third p-type charge generation layer pCGL-3 overlapping the third light emitting region PXA-B. Accordingly, an organic layer that is directly disposed on the first to third p-type charge generation layers pCGL-1, pCGL-2, and pCGL-3 (for example, the second emission layers EML-R2, EML-G2, EML-B2) may have a step difference.

In the light emitting elements ED-1, ED-2, and ED-3 according to embodiments shown in FIGS. 3 to 6, the p-type charge generation layer pCGL may include the amine compound represented by Formula 1 as described herein.

In an embodiment, in the amine compound represented by Formula 1 included in the p-type charge generation layer pCGL, R₁ and R₂ may each independently be a substituted or unsubstituted amine group, a substituted or unsubstituted thio group, a substituted or unsubstituted oxy group, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, in the amine compound represented by Formula 1 included in the p-type charge generation layer pCGL, R₁ and R₂ may each independently be a substituted or unsubstituted aryl group having 6 to 30 ring-forming carbon atoms, or may be bonded to an adjacent group to form an aromatic hydrocarbon ring.

In an embodiment, the amine compound represented by Formula 1 included in the p-type charge generation layer pCGL may be represented by Formula 1-2. In Formula 1-2, Ar₁, Ar₂, L₂, L₃, R₃, R₄, l, m, p, and r are each the same as defined in Formula 1.

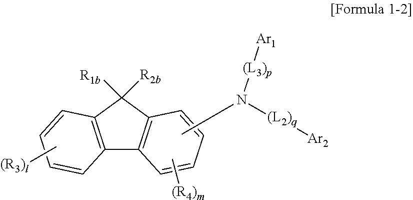

In Formula 1-2, R_{1b} and R_{2b} may each independently be a substituted or unsubstituted aryl group having 6 to 30 ring-forming carbon atoms, or may be bonded to an adjacent group to form an aromatic hydrocarbon ring. For example, R_{1b} and R_{2b} may each independently be a substituted or unsubstituted phenyl group, or a substituted or unsubstituted biphenyl group. However, embodiments are not limited thereto.

For example, in the light emitting elements ED-1, ED-2, and ED-3, the p-type charge generation layer pCGL may include at least one compound selected from Compound Group 2, as described herein. For example, the first to third p-type charge generation layers pCGL-1, pCGL-2, and pCGL-3 may each independently include at least one compound selected from Compound Group 2.

The p-type charge generation layer pCGL may be formed of a single layer of an amine compound represented by Formula 1, or may be a layer in which the amine compound represented by Formula 1 is doped with a p-type dopant. In an embodiment, materials of the related art may be employed as the p-type dopant of the p-type charge generation layer pCGL, without limitation. In another embodiment, a p-dopant that is included in the hole transport region HTR as described above may be employed as the p-type dopant of the p-type charge generation layer pCGL. When the p-type charge generation layer pCGL includes the p-type dopant, a doping ratio of the p-type dopant may be in a range of about 2 wt % to about 15 wt % with respect to a total weight of the p-type charge generation layer p-CGL. The doping ratios of the first p-type charge generation layer pCGL-1, the second p-type charge generation layer pCGL-2, and the third p-type charge generation layer pCGL-3 having different thicknesses may be different from each other to control luminous efficiency of the corresponding emission layers.

Thicknesses of the first, second, and third p-type charge generation layers pCGL-1, pCGL-2, and pCGL-3 may satisfy Equation 1:

T₁>T₂≥T₃ [Equation 1]

In Equation 1, T₁ is a thickness of the first p-type charge generation layer, T₂ is a thickness of the second p-type charge generation layer, and T₃ is a thickness of the third p-type charge generation layer. For example, T₁ is a thickness of the first p-type charge generation layer corresponding to the first light emitting region PXA-R, T₂ is a thickness of the second p-type charge generation layer corresponding to the second light emitting region PXA-G, and T₃ is a thickness of the third p-type charge generation layer corresponding to the third light emitting region PXA-B.

For example, a thickness T₁ of the first p-type charge generation layer pCGL-1 may be in a range of about 700 Å to about 1,200 Å. For example, a thickness T₂ of the second p-type charge generation layer pCGL-2 may be in a range of about 300 Å to about 800 Å. For example, a thickness T₃ of the third p-type charge generation layer pCGL-3 may be in a range of about 200 Å to about 600 Å.

In an embodiment, a thickness T₂ of the second p-type charge generation layer pCGL-2 and a thickness T₃ of the third p-type charge generation layer pCGL-3 may be the same as or different from each other. As shown in FIG. 4A, the thickness T₂ of the second p-type charge generation layer pCGL-2 may be greater than the thickness T₃ of the third p-type charge generation layer pCGL-3. In another embodiment, the thickness T₂ of the second p-type charge generation layer pCGL-2 may be the same as the thickness T₃ of the third p-type charge generation layer pCGL-3, as shown in FIG. 4B.

In the light emitting elements ED-1, ED-2, and ED-3 according to embodiments, the thicknesses of the first to third p-type charge generation layers pCGL-1, pCGL-2, and pCGL-3 satisfy Equation 1, and the first to third p-type charge generation layers pCGL-1, pCGL-2, and pCGL-3, and the hole transport region HTR may each independently include an amine compound represented by Formula 1, thereby resulting in increased luminous efficiency and element lifespan.

In the light emitting elements ED-1, ED-2, and ED-3 according to embodiments shown in FIGS. 3 to 6, the first electron transport region ETR1 is provided on the first emission layers EML-R1, EML-G1, and EML-B1, and the second electron transport region ETR2 is provided on the second emission layers EML-R2, EML-G2, and EML-B2. Each of the first and second electron transport regions ETR1 and ETR2 may include a hole blocking layer, an electron transport layer, an electron injection layer, or any combination thereof, but embodiments are not limited thereto.

The first and second electron transport regions ETR1 and ETR2 may each independently be a layer formed of a single material, a layer formed of different materials, or a structure having multiple layers formed of different materials.

For example, the first electron transport region ETR1 may have a single layer structure of a first electron transport layer ETL-a, or may have a single layer structure formed of an electron injection material and an electron transport material. Although not shown in the drawings, the first electron transport region ETR1 may have a single layer structure of an electron injection layer, may have a single layer structure formed of different materials, or may have a structure in which a first electron transport layer ETL-a/electron injection layer, a hole blocking layer/first electron transport layer ETL-a/electron injection layer, or a first electron transport layer ETL-a/buffer layer/electron injection layer are stacked in its respective stated order from the emission layers EML-R1, EML-G1, and EML-B1, but is not limited thereto.

The second electron transport region ETR2 may have a single layer structure of a second electron transport layer ETL-b, or may have a single layer structure formed of an electron injection material and an electron transport material. In embodiments, the second electron transport region ETR2 may have a single layer structure formed of different materials, or may have a structure in which a second electron transport layer ETL-b/electron injection layer EIL, a hole blocking layer HBL/second electron transport layer ETL-b/electron injection layer EIL, or a second electron transport layer ETL-b/buffer layer (not shown)/electron injection layer EIL are stacked in its respective stated order from the emission layers EML-R2, EML-G2, and EML-B2, but is not limited thereto.

The first and second electron transport regions ETR1 and ETR2 may each independently have a thickness, for example, in a range of about 1,000 Å to about 1,500 Å.

The first and second electron transport regions ETR1 and ETR2 may each be formed using various methods such as a vacuum deposition method, a spin coating method, a cast method, a Langmuir-Blodgett (LB) method, an inkjet printing method, a laser printing method, and a laser induced thermal imaging (LITI) method.

The first and second electron transport regions ETR1 and ETR2 may each independently include a compound represented by Formula ET-1:

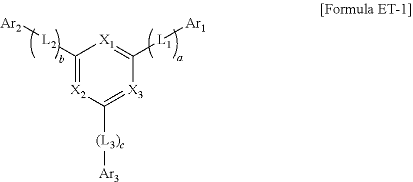

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Arₙ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are 2 or greater, multiple groups of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The first and second electron transport regions ETR1 and ETR2 may each independently include an anthracene-based compound. However, embodiments are not limited thereto, and the first and second electron transport regions ETR1 and ETR2 may each independently include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

The first and second electron transport regions ETR1 and ETR2 may each independently include at least one of Compounds ET1 to ET36:

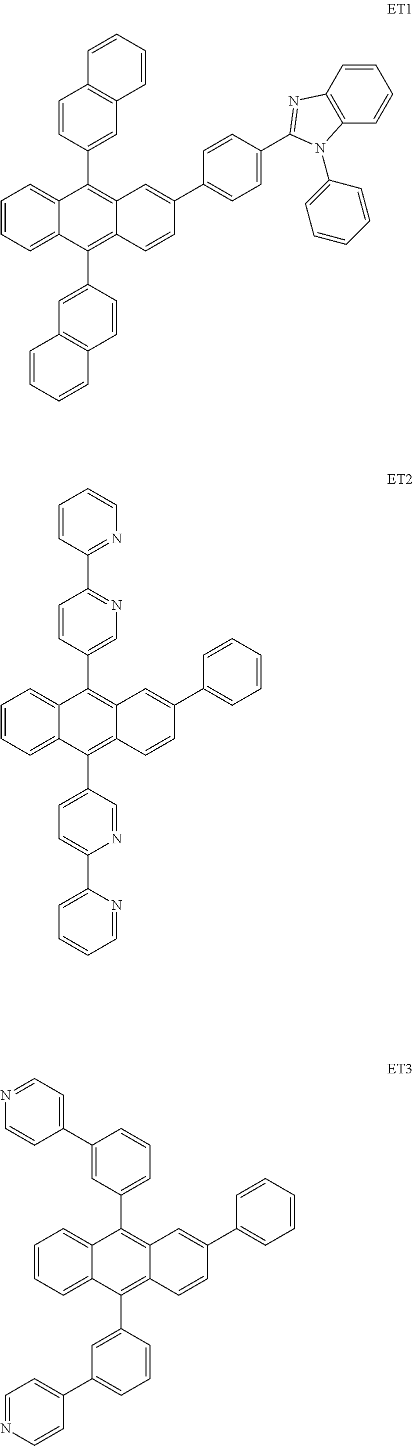 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

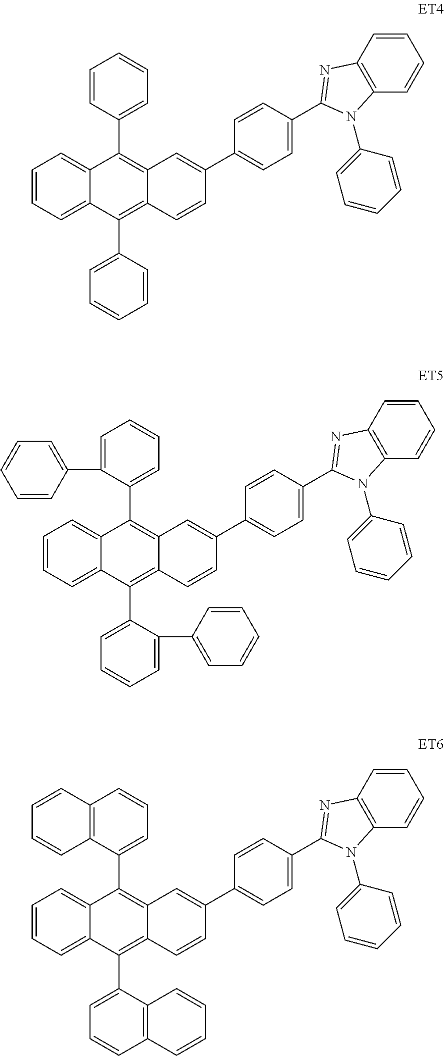 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

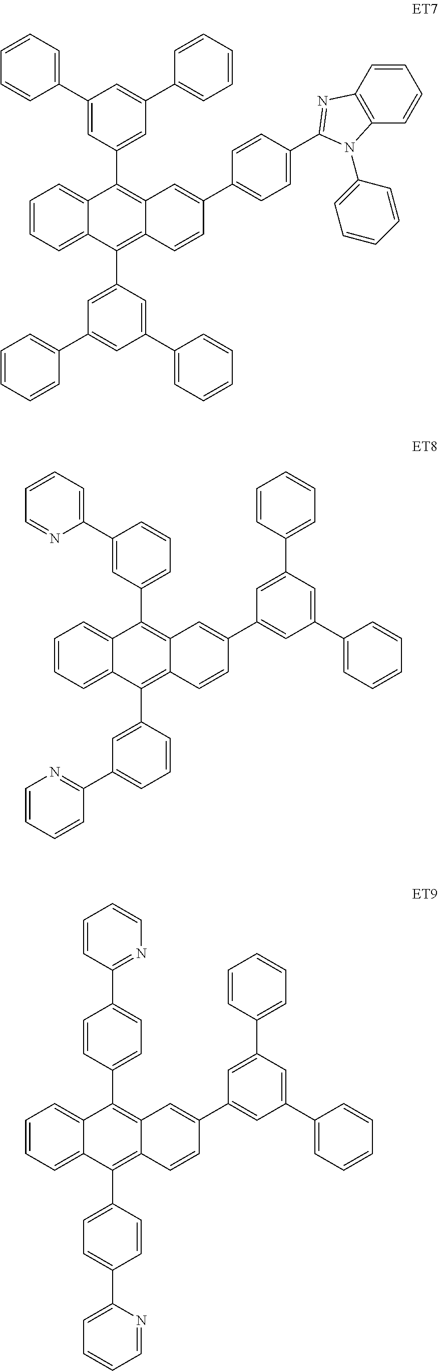 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

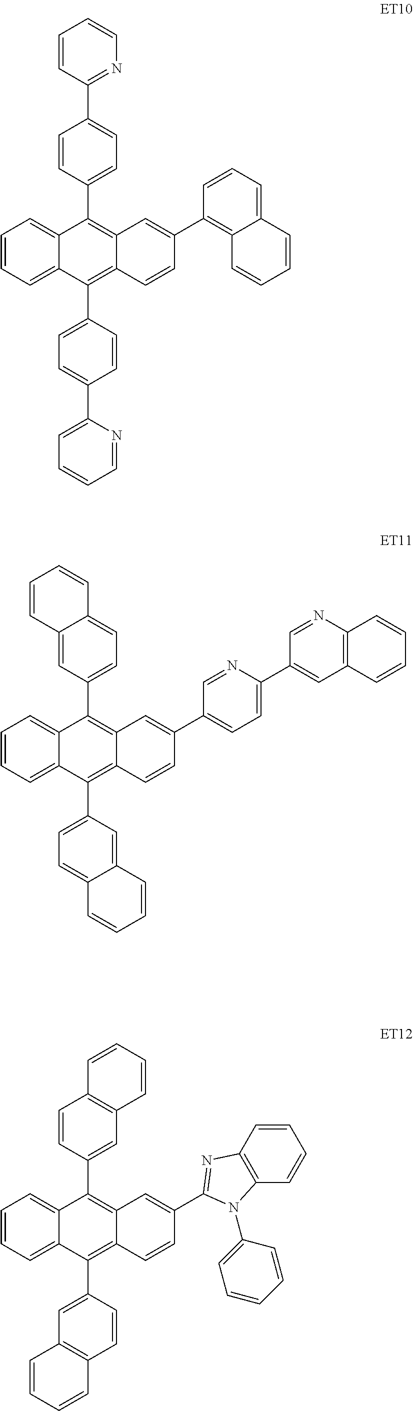 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

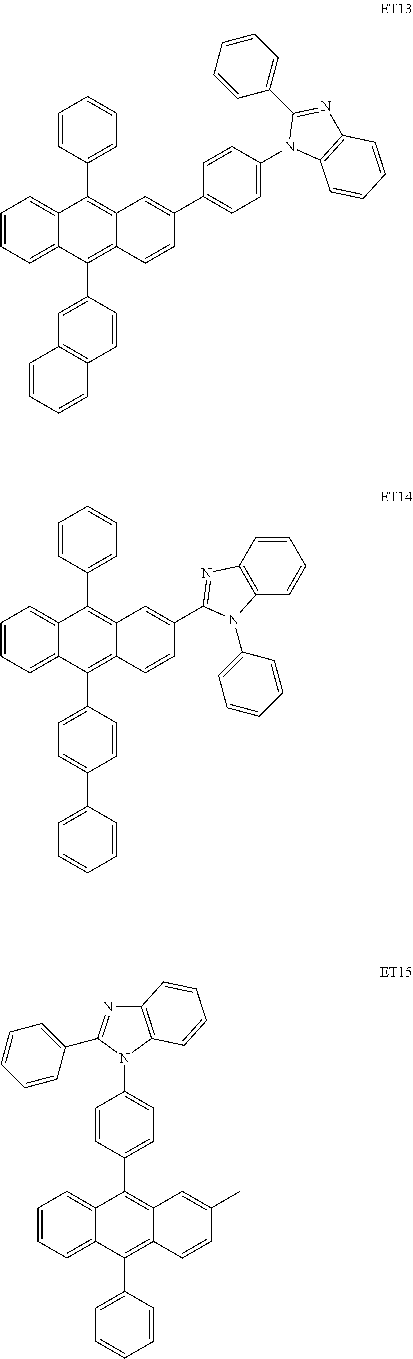 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

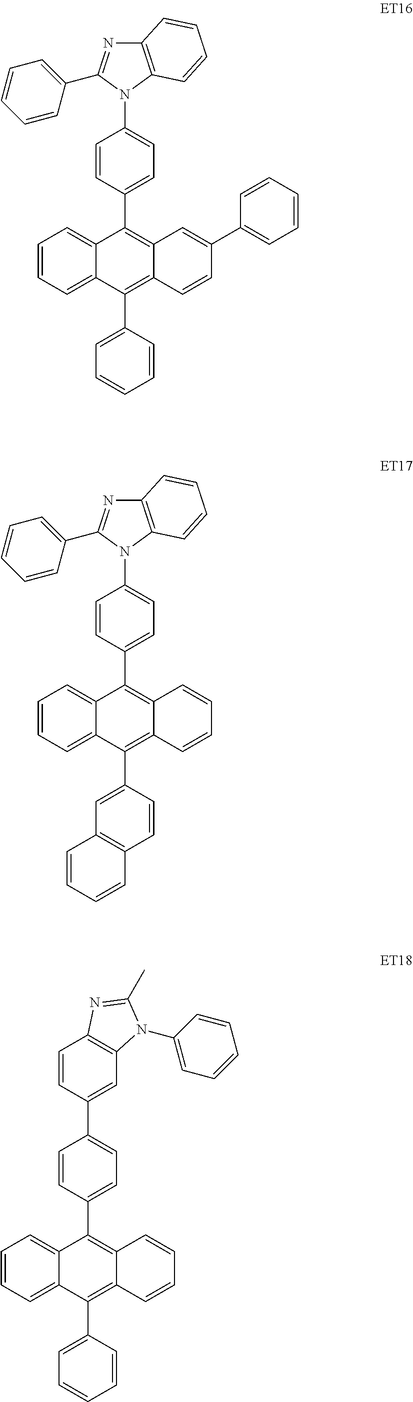 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

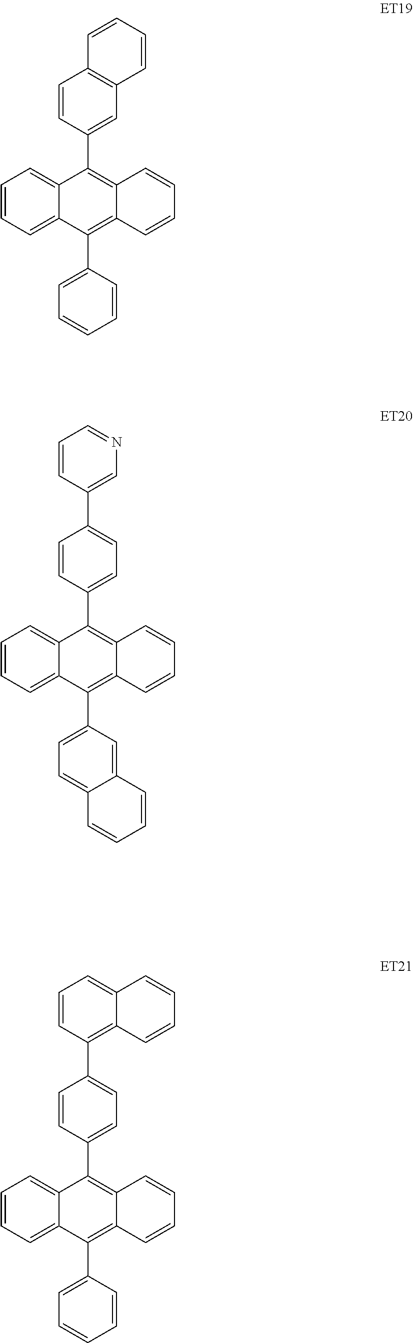

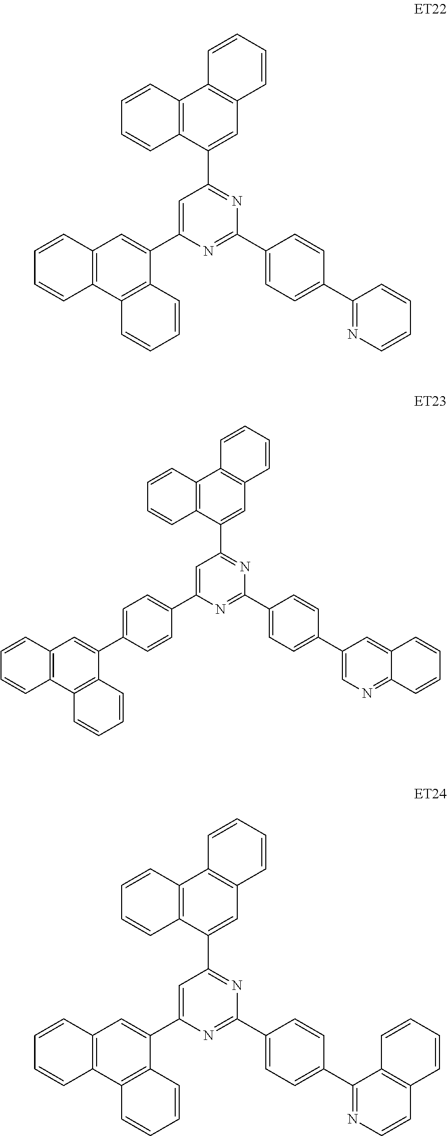 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

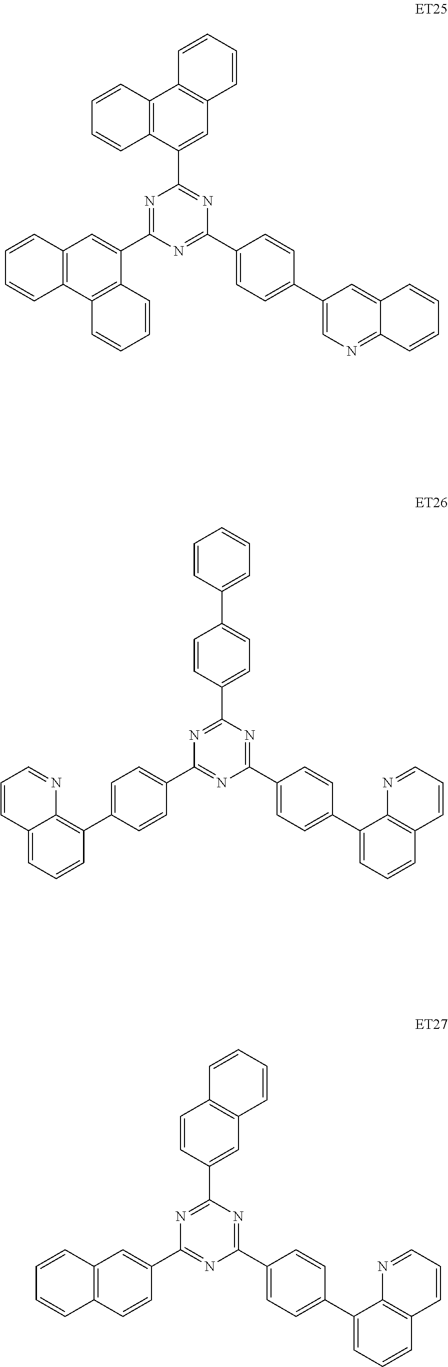 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

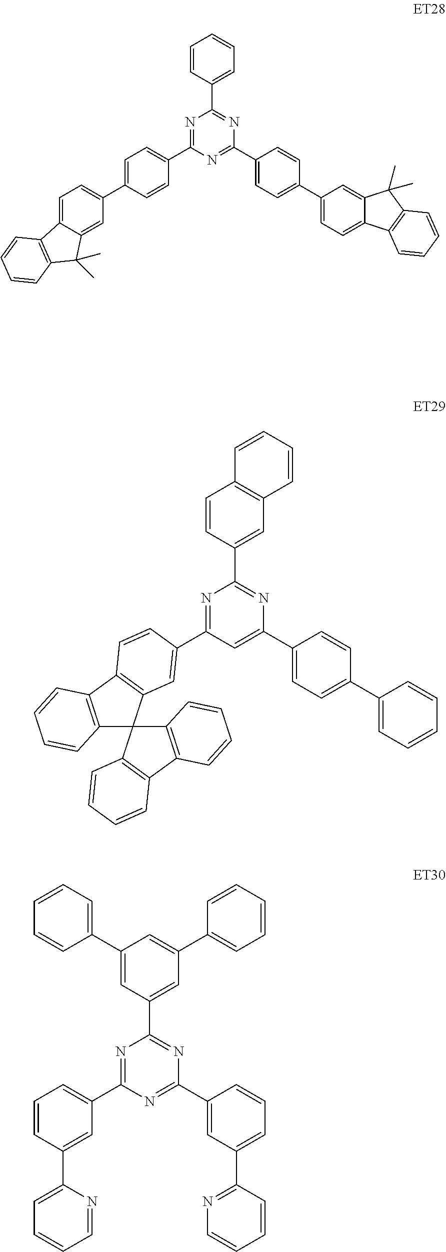 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

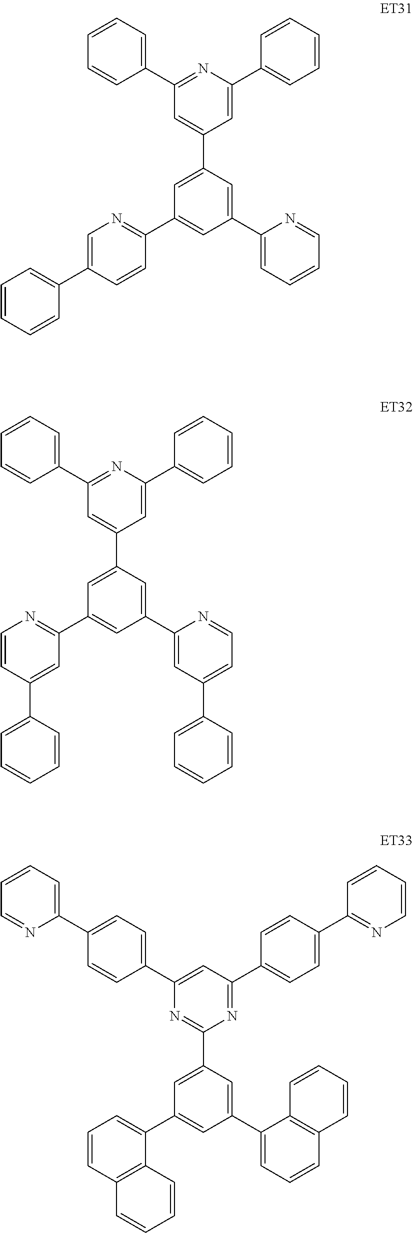 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

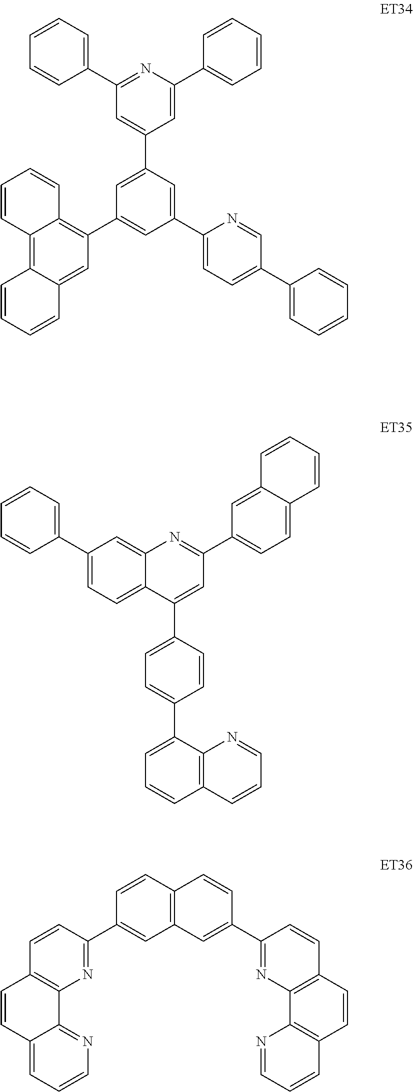 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The first and second electron transport regions ETR1 and ETR2 may each independently include: halogenated metals such as LiF, NaCl, CsF, RbCl, RbI, CuI, and KI; lanthanide metals such as Yb; or co-deposition materials of a halogenated metal and a lanthanide metal. For example, the first and second electron transport regions ETR1 and ETR2 may each independently include KI:Yb, RbI:Yb, LiF:Yb etc. as a co-deposition material. The first and second electron transport regions ETR1 and ETR2 may each independently include a metal oxide such as Li₂O and BaO, or 8-hydroxyl-lithium quinolate (Liq), etc., but embodiments are not limited thereto. In an embodiment, the first and second electron transport regions ETR1 and ETR2 may each independently be formed of a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The first and second electron transport regions ETR1 and ETR2 may each independently further include, for example, at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described above, but embodiments are not limited thereto.

The first and second electron transport regions ETR1 and ETR2 may each independently include the compounds of the electron transport region in at least one of an electron injection layer EIL, electron transport layers ETL-a and ETL-b, or a hole blocking layer HBL.

When the first and second electron transport regions ETR1 and ETR2 include the first and second electron transport layers ETL-a and ETL-b, respectively, the first and second electron transport layers ETL-a and ETL-b may each independently have a thickness in a range of about 100 Å to about 1,000 Å. For example, the first and second electron transport layers ETL-a and ETL-b may each independently have a thickness in a range of about 150 Å to about 500 Å. When the thicknesses of the first and second electron transport layers ETL-a and ETL-b satisfy any of the above-described ranges, satisfactory electron transport properties may be obtained without a substantial increase in driving voltage. When any of the first and second electron transport regions ETR1 and ETR2 include an electron injection layer EIL, the electron injection layer EIL may have a thickness in a range of about 1 Å to about 100 Å. For example, the electron injection layer EIL may have a thickness in a range of about 3 Å to about 90 Å. When the thickness of the electron injection layer EIL satisfies any of the above-described ranges, satisfactory electron injection properties may be obtained without a substantial increase in driving voltage.

The second electrode EL2 is provided on the second electron transport region ETR2. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., AgMg, AgYb, or MgYb). In another embodiment, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, or oxides of the above-described metal materials.

Although not shown in the drawings, the second electrode EL2 may be electrically connected to an auxiliary electrode. When the second electrode EL2 is electrically connected to an auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol sol-9-yl)triphenylamine (TCTA), etc., or may include epoxy resins or acrylates such as methacrylates. However, embodiments are not limited thereto. In an embodiment, the capping layer CPL may include at least one of Compounds P1 to P5:

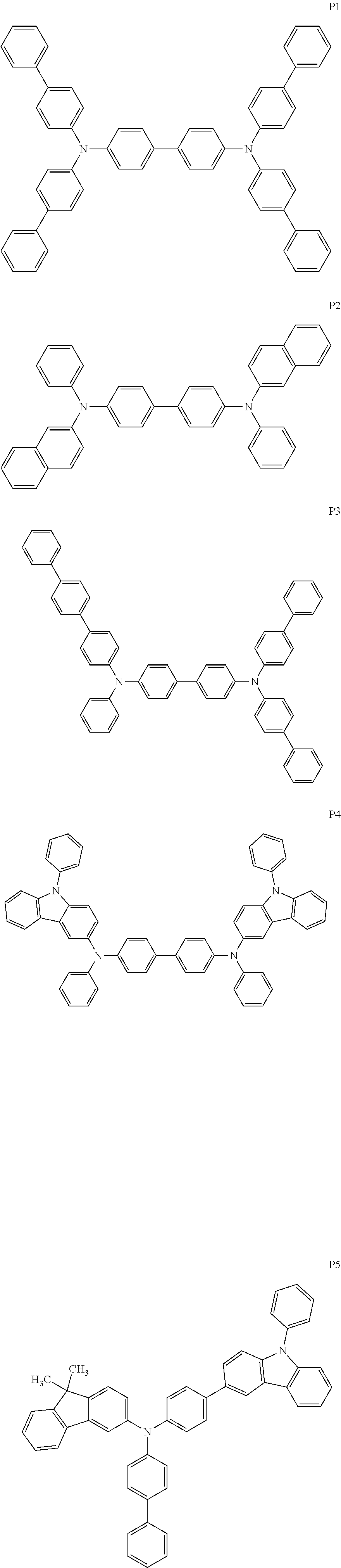 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index equal to or greater than about 1.6. For example, the capping layer CPL may have a refractive index equal to or greater than about 1.6 with respect to light in a wavelength range of about 550 nm to about 660 nm.

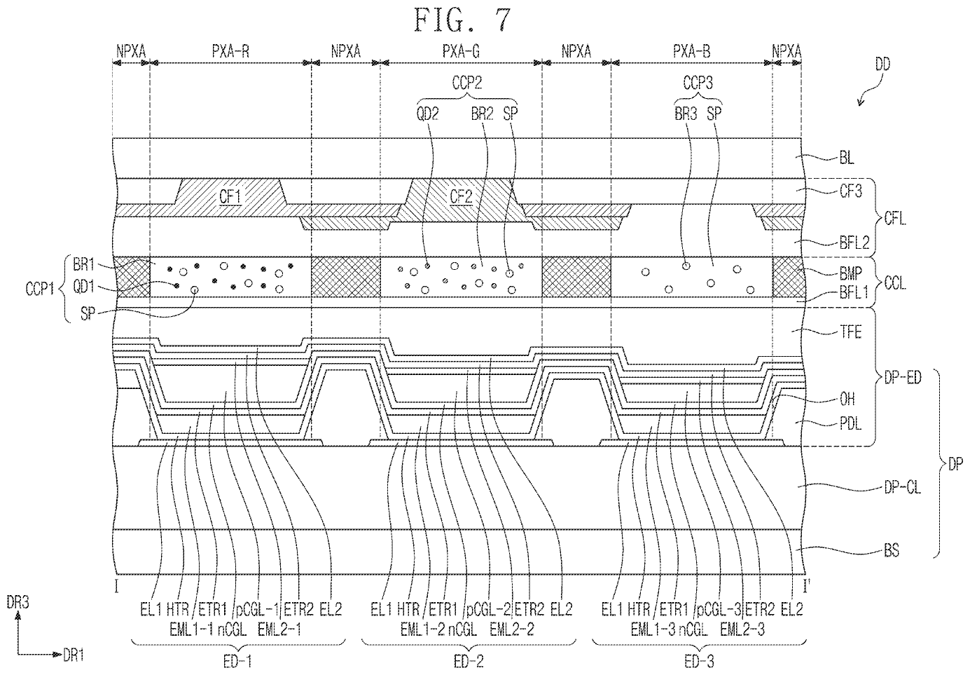

FIG. 7 is a schematic cross-sectional view of a display device according to an embodiment. In the description of the display device according to an embodiment with reference to FIG. 7, the features which have been explained above with respect to FIGS. 1 to 6 will not be described again, and the differing features will be described.

Referring to FIG. 7, a display device DD according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display element layer DP-ED, and the element layer DP-ED may include light emitting elements ED-1, ED-2, and ED-3.

The light emitting elements ED-1, ED-2, and ED-3 may each include a first electrode EL1, a first light emitting unit OL1 (FIG. 3) disposed on the first electrode EL1, a charge generation layer CGL (FIG. 3) disposed on the first light emitting unit OL1 (FIG. 3), a second light emitting unit OL2 disposed on the charge generation layer CGL (FIG. 3), and a second electrode EL2 disposed on the second light emitting unit OL2. In embodiments, a structure of the light emitting elements ED-1, ED-2, and ED-3 shown in FIG. 7 may each independently be the same as a structure of a light emitting element according to any of FIGS. 3 to 6 as described herein.

The hole transport region HTR and the first to third p-type charge generation layers pCGL-1, pCGL-2, and pCGL-3 of the light emitting elements ED-1, ED-2, and ED-3 included in the display device DD may each independently include an amine compound represented by Formula 1 as described herein.

Referring to FIG. 7, emission layers EML1-1, EML1-2, EML1-3, EML2-1, EML2-2, and EML2-3 may be disposed in the openings OH defined in the pixel defining films PDL. The emission layers EML1-1, EML1-2, EML1-3 of the first light emitting units may be disposed to be spaced apart from each other in a plan view. The emission layers EML2-1, EML2-2, and EML2-3 of the second light emitting units may be disposed to be spaced apart from each other in a plan view. For example, the emission layers EML1-1, EML1-2, EML1-3, EML2-1, EML2-2, and EML2-3 separated by the pixel defining films PDL and provided corresponding to each of the light emitting regions PXA-R, PXA-G, and PXA-B may each emit light in a same wavelength range. In an embodiment, in the display device DD, the emission layers EML1-1, EML1-2, EML1-3, EML2-1, EML2-2, and EML2-3 may each emit blue light. Although not shown in the drawings in an embodiment, the emission layer of the first light emitting units and the emission layer of the second light emitting units may each be provided as a common layer for all of the light emitting regions PXA-R, PXA-G, and PXA-B.

The light control layer CCL may be disposed on the display panel DP. The light control layer CCL may include a light converter. The light converter may be a quantum dot or a phosphor. The light converter may convert the wavelength of a provided light and may emit the resulting light. For example, the light control layer CCL may be a layer including quantum dots or a layer including phosphors.

The light control layer CCL may include light control units CCP1, CCP2, and CCP3. The light control units CCP1, CCP2, and CCP3 may be spaced apart from each other.

Referring to FIG. 7, a division pattern BMP may be disposed between the light control units CCP1, CCP2, and CCP3 that are spaced apart from each other, but embodiments are not limited thereto. In FIG. 7, it is shown that the division pattern BMP does not overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 for converting third color light provided from the first light emitting element ED-1 into first color light, a second light control unit CCP2 including a second quantum dot QD2 for converting the third color light provided from the second light emitting element ED-2 into second color light, and a third light control unit CCP3 transmitting the third color light provided from the third light emitting element ED-3.

In an embodiment, the first light control unit CCP1 may provide red light, which is the first color light, and the second light control unit CCP2 may provide green light, which is the second color light. The third light control unit CCP3 may transmit and provide blue light, which may be the third color light provided from the third light emitting element ED-3. For example, the first quantum dot QD1 may be a red quantum dot and the second quantum dot QD2 may be a green quantum dot. The quantum dots QD1 and QD2 may each be a quantum dot as described herein.

The light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include a quantum dot but may include the scatterers SP.

The scatterers SP may be inorganic particles. For example, the scatterers SP may include at least one of TiO₂, ZnO, Al₂O₃, SiO₂, or hollow silica. The scatterers SP may include any of TiO₂, ZnO, Al₂O₃, SiO₂, or hollow silica, or the scatterers SP may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3 in which the quantum dots QD1 and QD2 and the scatterers SP are dispersed. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3. The base resins BR1, BR2, and BR3 are each a medium in which the quantum dots QD1 and QD2 and the scatterers SP are dispersed, and may be formed of various resin compositions, which may be generally referred to as a binder. For example, the base resins BR1, BR2, and BR3 may be an acrylic resin, a urethane-based resin, a silicone-based resin, an epoxy-based resin, etc. The base resins BR1, BR2, and BR3 may be a transparent resin. In an embodiment, the first base resin BR1, the second base resin BR2, and the third base resin BR3 may each be the same as or different from each other.

The light control layer CCL may include a barrier layer BFL1. The barrier layer BFL1 may prevent moisture and/or oxygen (hereinafter referred to as “moisture/oxygen”) from being introduced. The barrier layer BFL1 may be disposed on the light control units CCP1, CCP2, and CCP3 to prevent the light control units CCP1, CCP2, and CCP3 from being exposed to moisture/oxygen. The barrier layer BFL1 may cover the light control units CCP1, CCP2, and CCP3. A color filter layer CFL may include a barrier layer BFL2 disposed on the light control units CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured, etc. The barrier layers BFL1 and BFL2 may each independently further include an organic layer. The barrier layers BFL1 and BFL2 may each independently include be formed of a single layer or of multiple layers.

In the display device DD according to an embodiment, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. For example, the color filter layer CFL may include a first filter CF1 transmitting first color light, a second filter CF2 transmitting second color light, and a third filter CF3 transmitting third color light. For example, the first filter CF1 may be a red filter, the second filter CF2 may be a green filter, and the third filter CF3 may be a blue filter. The filters CF1, CF2, and CF3 may each include a photosensitive polymer resin, and a pigment or dye. The first filter CF1 may include a red pigment or a red dye, the second filter CF2 may include a green pigment or a green dye, and the third filter CF3 may include a blue pigment or a blue dye. However, embodiments are not limited thereto, and the third filter CF3 may not include a pigment or a dye. The third filter CF3 may include a photosensitive polymer resin, and may not include a pigment or a dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated and may be provided as a single body. The first to third filters CF1, CF2, and CF3 may be disposed corresponding to the red light emitting region PXA-R, the green light emitting region PXA-G, and the blue light emitting region PXA-B, respectively.

Although not shown in the drawings, the color filter layer CFL may include a light blocking unit (not shown). The color filter layer CFL may include the light blocking unit (not shown) that is disposed to overlap the boundaries between the neighboring filters CF1, CF2, and CF3. The light blocking unit (not shown) may be a black matrix. The light blocking unit (not shown) may include an organic light blocking material or an inorganic light blocking material, each independently including a black pigment or a black dye. The light blocking unit (not shown) may separate the boundaries between the adjacent filters CF1, CF2, and CF3. In an embodiment, the light blocking unit (not shown) may be formed of a blue filter.

A base substrate BL may be disposed on the color filter layer CFL. The base substrate BL may provide a base surface on which the color filter layer CFL and the light control layer CCL are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

In the light emitting elements ED-1, ED-2, and ED-3 included in the display device DD according to an embodiment, the amine compound according to an embodiment as described herein is included in the hole transport region HTR and the p-type charge generation layer pCGL (pCGL-1, pCGL-2, and pCGL-3), and thicknesses of the p-type charge generation layers pCGL-1, pCGL-2, and pCGL-3 respectively corresponding to the first to third light emitting regions PXA-R, PXA-G, and PXA-B satisfies Equation 1 as described herein, resulting in increased luminous efficiency and lifespan. Accordingly, the display device DD of an embodiment may exhibit excellent display efficiency.

Hereinafter, an amine compound according to an embodiment and a light emitting element according to an embodiment will be described with reference to the Examples and the Comparative Examples. The Examples described below are only provided as illustrations to assist in understanding the disclosure, and the scope thereof is not limited thereto.

### EXAMPLES

1. Manufacture and Evaluation of Light Emitting Elements

(1) Manufacture of Light Emitting Elements

1) Manufacture of Light Emitting Element of Example 1-1

An ITO having a thickness of 1,000 Å was patterned on a glass substrate (50 mm×50 mm×0.5 mm), subjected to ultrasonic cleaning using acetone isopropyl alcohol and ultrapure water for 15 minutes, and UV ozone-treated for 10 minutes to form a first electrode. A p-dopant (F4-TCNQ) was formed to be 10 nm thick, and A15 was deposited to be 30 nm thick to form a hole transport layer. A first red emission layer having a thickness of 40 nm, a first green emission layer having a thickness of 30 nm, and a first blue emission layer having a thickness of 20 nm were formed. The first red emission layer was formed by doping E-2-21 with 2% of M-a11, the first green emission layer was formed by doping E-2-25 with 10% of M-a13, and the first blue emission layer was formed by doping E19 with 2% of BD. BPHEN was deposited to be 30 nm thick to form a first electron transport layer.

BPHEN was deposited to be 10 nm thick, and 1% of n-dopant (Yb) was applied for doping to form an n-type charge generation layer. A first p-type charge generation layer, a second p-type charge generation layer, and a third p-type charge generation layer were formed. The first p-type charge generation layers was formed by depositing p-dopant (F4-TCNQ) to be 10 nm thick and B19 to be 70 nm thick. The second p-type charge generation layer was formed by depositing p-dopant (F4-TCNQ) to be 10 nm thick and B19 to be 45 nm thick, and the third p-type charge generation layer was formed by depositing p-dopant (F4-TCNQ) to be 10 nm thick and B-19 to be 35 nm thick.

On the first p-type charge generation layer, the second p-type charge generation layer, and the third p-type charge generation layer, a second red emission layer, a second green emission layer, and a second blue emission layer were respectively formed in the same manner as the first red emission layer, the first green emission layer, and the first blue emission layer were formed. TPBi was deposited to be 30 nm thick to form a second electron transport layer, and Ag and Mg were co-deposited to be 10 nm thick to form a second electrode.

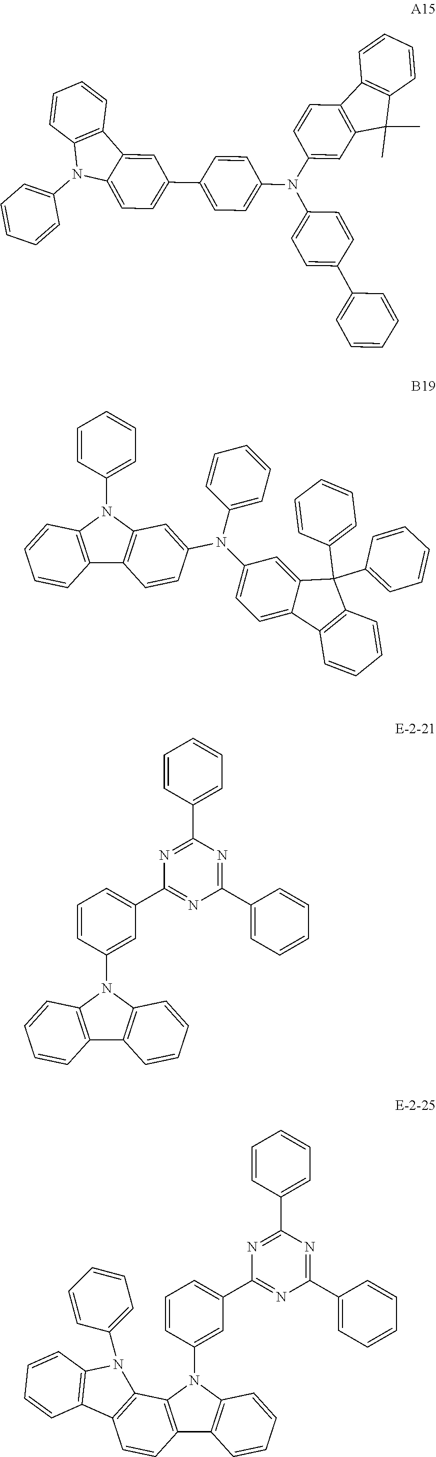 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cccc(-n4c5ccccc5c5ccc6c7ccccc7n(-c7ccccc7)c6c54)c3)n2)cc1]

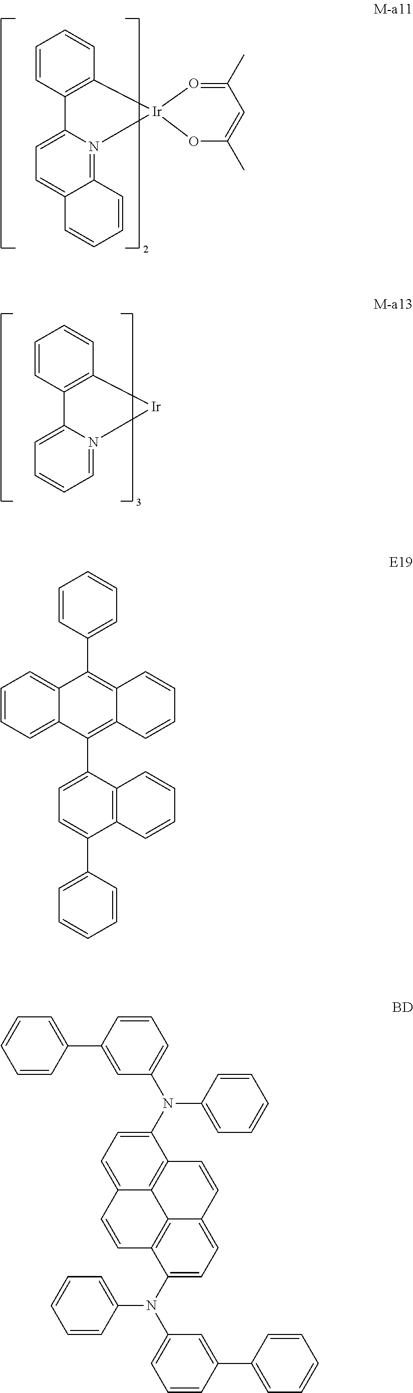

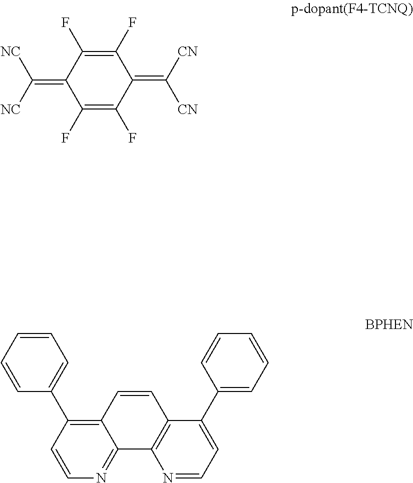 [SMILES: N#CC(C#N)=c1c(F)c(F)c(=C(C#N)C#N)c(F)c1F ; c1ccc(-c2ccnc3c2ccc2c(-c4ccccc4)ccnc23)cc1]

2) Manufacture of Light Emitting Element of Example 1-2

Example 1-2 was prepared in the same manner as in Example 1-1, except that A6 was used instead of A15 for forming a hole transport layer, and B8 was used instead of B19 for forming first to third p-type charge generation layers.

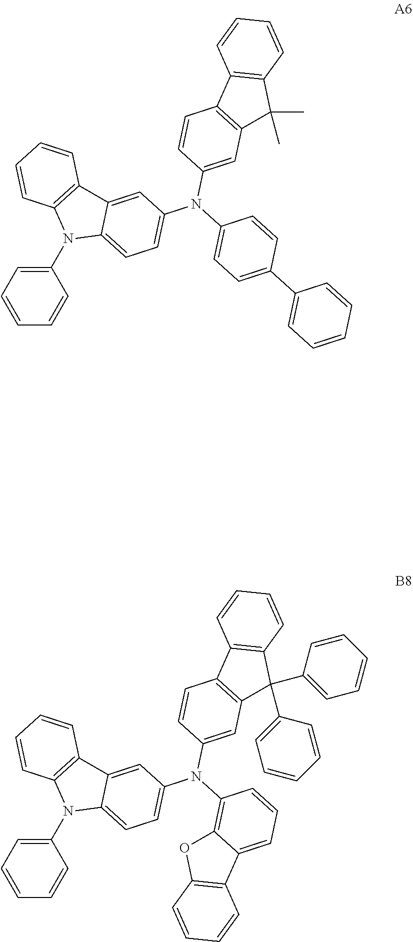 [SMILES: CC1(C)c2ccccc2-c2ccc(N(c3ccc(-c4ccccc4)cc3)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4cccc5c4oc4ccccc45)ccc32)cc1]

3) Manufacture of Light Emitting Element of Example 1-3

Example 1-3 was prepared in the same manner as in Example 1-1, except that A13 was used instead of A15 for forming a hole transport layer, and B15 was used instead of B19 for forming first to third p-type charge generation layers.

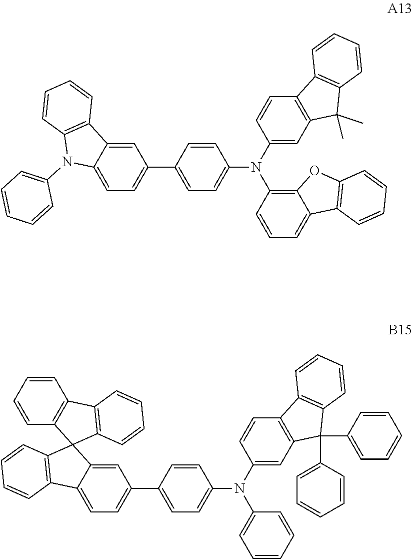 [SMILES: CC1(C)c2ccccc2-c2ccc(N(c3ccc(-c4ccc5c(c4)c4ccccc4n5-c4ccccc4)cc3)c3cccc4c3oc3ccccc34)cc21 ; c1ccc(N(c2ccc(-c3ccc4c(c3)C3(c5ccccc5-c5ccccc53)c3ccccc3-4)cc2)c2ccc3c(c2)C(c2ccccc2)(c2ccccc2)c2ccccc2-3)cc1]

4) Manufacture of Light Emitting Element of Example 1-4

Example 1-4 was prepared in the same manner as in Example 1-1, except that B2 was used instead of B19 for forming first to third p-type charge generation layers.

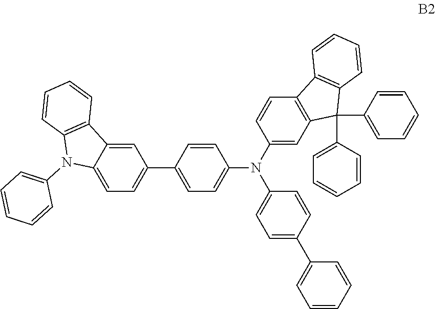 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

5) Manufacture of Light Emitting Element of Comparative Example 1-1

Comparative Example 1-1 was prepared in the same manner as in Example 1-1, except that NPB was used as a material for first to third p-type charge generation layers.

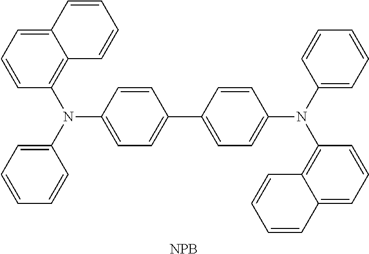 [SMILES: c1ccc(N(c2ccc(-c3ccc(N(c4ccccc4)c4cccc5ccccc45)cc3)cc2)c2cccc3ccccc23)cc1 ; "NPB"]

6) Manufacture of Light Emitting Element of Comparative Example 1-2

Comparative Example 1-2 was prepared in the same manner as in Example 1-1, except that H-1-5 was used was used as a material for first to third p-type charge generation layers.

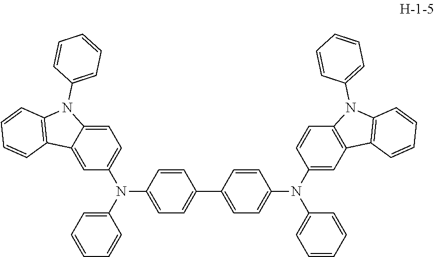 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

7) Manufacture of Light Emitting Element of Comparative Example 1-3

Comparative Example 1-3 was prepared in the same manner as in Example 1-1, except that A15 was used was used to form first to third p-type charge generation layers having a thickness of 30 nm without p-dopant (F4-TCNQ).

8) Manufacture of Light Emitting Element of Comparative Example 1-4

Comparative Example 1-4 was prepared in the same manner as in Example 1-1, except that first to third p-type charge generation layers were formed to be the same in thickness. The first to third p-type charge generation layers were formed by depositing p-dopant (F4-TCNQ) to be 10 nm thick and B19 to be 35 nm thick, respectively.

(2) Evaluation of Light Emitting Elements

Table 1 shows results of evaluation on light emitting elements for Examples 1-1 to 1-4 and Comparative Examples 1-1 to 1-4.

In the characteristic evaluation results for the Examples and the Comparative Examples shown in Table 1, luminous efficiency indicates an efficiency value at a current density of 5 mA/cm², half-life indicates luminance half-life of 1,000 cd/m² (blue), 10,000 cd/m² (green), and 3,000 cd/m² (red).

TABLE 1

| | 1^{st} | | | Efficiency | Lifespan |
|---|---|---|---|---|---|
| | HTL | pCGL | Color | (%) | (%) |
| Example 1-1 | A15 | B19 | R | 120% | 140% |
| | | | G | 110% | 140% |
| | | | B | 125% | 150% |
| Example 1-2 | A6 | B8 | R | 115% | 125% |
| | | | G | 115% | 130% |
| | | | B | 110% | 140% |
| Example 1-3 | A13 | B15 | R | 110% | 130% |
| | | | G | 110% | 130% |
| | | | B | 120% | 145% |
| Example 1-4 | A15 | B2 | R | 120% | 135% |
| | | | G | 125% | 120% |
| | | | B | 125% | 140% |
| Comparative | A15 | NPB | R | 100% | 100% |
| Example 1-1 | | | G | 100% | 100% |
| | | | B | 100% | 100% |
| Comparative | A15 | HTL1 | R | 105% | 120% |
| Example 1-2 | | | G | 105% | 115% |
| | | | B | 110% | 130% |
| Comparative | A15 | A15 | R | 88% | 92% |
| Example 1-3 | | | G | 94% | 95% |
| | | | B | 92% | 92% |
| Comparative | A15 | B19 | R | 82% | 80% |
| Example 1-4 | | (Same | G | 94% | 92% |
| | | thickness) | B | 92% | 95% |

Referring to Table 1, it is seen that the light emitting elements of Examples 1-1 to 1-4 have greater luminous efficiency and longer life than Comparative Examples 1-1 to 1-4.

According to an embodiment, a display device having excellent display efficiency by including a light emitting element having increased luminous efficiency and element lifespan may be provided.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display device, comprising:
a first light emitting region emitting a first color;
a second light emitting region emitting a second color having a shorter wavelength than the first color;
a third light emitting region emitting a third color having a shorter wavelength than the second color;
a first light emitting element;
a second light emitting element; and
a third light emitting element, wherein
the first light emitting region, the second light emitting region, and the third light emitting region are spaced apart in plan view,
the first, second, and third light emitting elements respectively correspond to the first, second, and third light emitting regions,
each of the first, second, and third light emitting elements includes:
a first electrode;
a second electrode facing the first electrode;
a first light emitting unit disposed between the first electrode and the second electrode and including a hole transport region, a first emission layer, and a first electron transport region, which are sequentially stacked;
a second light emitting unit disposed on the first light emitting unit and including a second emission layer and a second electron transport region disposed on the second emission layer; and
a charge generation layer disposed between the first light emitting unit and the second light emitting unit and including a p-type charge generation layer and an n-type charge generation layer,
the p-type charge generation layer includes:
a first p-type charge generation layer overlapping the first light emitting region;
a second p-type charge generation layer overlapping the second light emitting region; and
a third p-type charge generation layer overlapping the third light emitting region,
thicknesses of the first, second, and third p-type charge generation layers satisfy Equation 1,
the hole transport region includes an amine compound represented by Formula 1, and
the p-type charge generation layer includes an amine compound represented by Formula 1 and a p-dopant:
T₁>T₂≥T₃ [Equation 1]
wherein in Equation 1,
T₁ is a thickness of the first p-type charge generation layer,
T₂ is a thickness of the second p-type charge generation layer, and
T₃ is a thickness of the third p-type charge generation layer; and 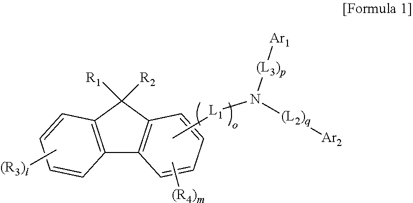
wherein in Formula 1,
Ar₁ and Ar₂ are each independently a substituted or unsubstituted silyl group, a substituted or unsubstituted aryl group having 6 to 60 ring-forming carbon atoms, or a substituted or unsubstituted heteroaryl group having 2 to 60 ring-forming carbon atoms,
L₁ to L₃ are each independently a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 60 ring-forming carbon atoms,
R₁ and R₂ are each independently a substituted or unsubstituted amine group, a substituted or unsubstituted thio group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
R₃ and R₄ are each independently a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
l is an integer from 0 to 4,
m is an integer from 0 to 3, and
o, p, and q are each independently an integer from 0 to 3,
provided that in the amine compound included in the hole transport region, R₁ and R₂ are each independently a substituted or unsubstituted alkyl group having 1 to 30 carbon atoms, and
provided that in the amine compound included in the p-type charge generation layer, R₁ and R₂ are each independently a substituted or unsubstituted amine group, a substituted or unsubstituted thio group, a substituted or unsubstituted oxy group, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring.

2. The display device of claim 1, wherein
the first p-type charge generation layer has a thickness in a range of about 700 Å to about 1,200 Å,
the second p-type charge generation layer has a thickness in a range of about 300 Å to about 800 Å, and
the third p-type charge generation layer has a thickness in a range of about 200 Å to 600 Å.

3. The display device of claim 1, wherein the amine compound included in the hole transport region is represented by Formula 1-1: 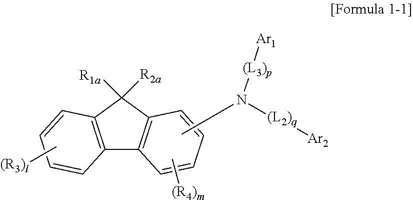
wherein in Formula 1-1,
R₁ₐ and R₂ₐ are each independently a substituted or unsubstituted alkyl group having 1 to 30 carbon atoms, and
Ar₁, Ar₂, L₂, L₃, R₃, R₄, l, m, p, and q are each the same as defined in Formula 1.

4. The display device of claim 1, wherein the amine compound included in the p-type charge generation layer is represented by Formula 1-2: 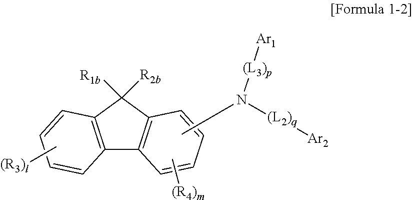
wherein in Formula 1-2,
R_{1b} and R_{2b} are each independently a substituted or unsubstituted aryl group having 6 to 30 ring-forming carbon atoms, or are bonded to an adjacent group to form an aromatic hydrocarbon ring, and
Ar₁, Ar₂, L₂, L₃, R₃, R₄, l, m, p, and q are each the same as defined in Formula 1.

5. The display device of claim 1, wherein Ar₁ and Ar₂ are each independently a substituted or unsubstituted phenyl group, a substituted or unsubstituted biphenyl group, a substituted or unsubstituted naphthyl group, a substituted or unsubstituted fluorenyl group, a substituted or unsubstituted dibenzofuran group, a substituted or unsubstituted carbazole group, or a substituted or unsubstituted triphenylsilyl group.

6. The display device of claim 1, wherein L₁ to L₃ are each independently a direct linkage, a substituted or unsubstituted phenylene group, or a substituted or unsubstituted divalent biphenyl group.

7. The display device of claim 1, wherein
the first light emitting unit includes:
a first red light emitting unit overlapping the first light emitting region;
a first green light emitting unit overlapping the second light emitting region, and
a first blue light emitting unit overlapping the third light emitting region, and
the second light emitting unit includes:
a second red light emitting unit overlapping the first light emitting region;
a second green light emitting unit overlapping the second light emitting region; and
a second blue light emitting unit overlapping the third light emitting region.

8. The display device of claim 1, wherein
the hole transport region includes a hole injection layer, a hole transport layer, an electron blocking layer, or a combination thereof, and
at least one of the hole injection layer, the hole transport layer, or the electron blocking layer includes the amine compound represented by Formula 1.

9. The display device of claim 1, wherein
the hole transport region includes a hole transport layer disposed on the first electrode, and
the hole transport layer includes the amine compound represented by Formula 1.

10. The display device of claim 1, wherein the first electron transport region and the second electron transport region each independently include an electron injection layer, an electron transport layer, a hole blocking layer, or a combination thereof.

11. The display device of claim 10, wherein
the first electron transport region includes a first electron transport layer disposed between the first emission layer and the charge generation layer, and
the second electron transport region includes:
a second electron transport layer disposed on the second emission layer; and
an electron injection layer disposed between the second electron transport layer and the second electrode.

12. The display device of claim 1, wherein the n-type charge generation layer is a common layer for the first light emitting region, the second light emitting region, and the third light emitting region.

13. The display device of claim 1, wherein
the p-type charge generation layer is disposed adjacent to a plurality of the second light emitting units, and
the n-type charge generation layer is disposed adjacent to a plurality of the first light emitting units.

14. The display device of claim 1, wherein the p-dopant includes a metal halide compound, a quinone derivative, a metal oxide, a cyano group-containing compound, or a combination thereof.

15. The display device of claim 1, wherein the amine compound represented by Formula 1 is selected from Compound Group 1 or Compound Group 2:

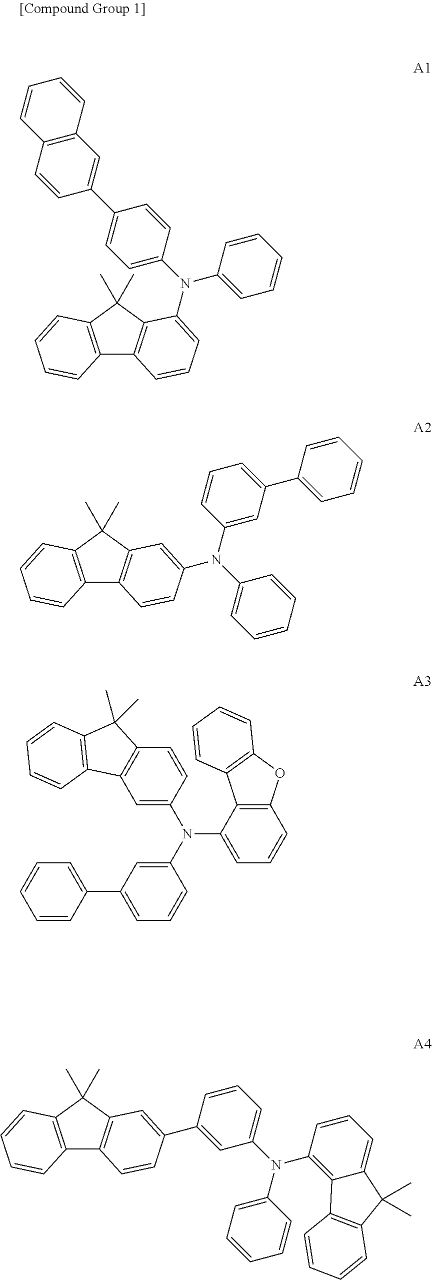 [SMILES: CC1(C)c2ccccc2-c2cccc(N(c3ccccc3)c3ccc(-c4ccc5ccccc5c4)cc3)c21 ; CC1(C)c2ccccc2-c2ccc(N(c3ccccc3)c3cccc(-c4ccccc4)c3)cc21 ; CC1(C)c2ccccc2-c2cc(N(c3cccc(-c4ccccc4)c3)c3cccc4oc5ccccc5c34)ccc21 ; CC1(C)c2ccccc2-c2ccc(-c3cccc(N(c4ccccc4)c4cccc5c4-c4ccccc4C5(C)C)c3)cc21]

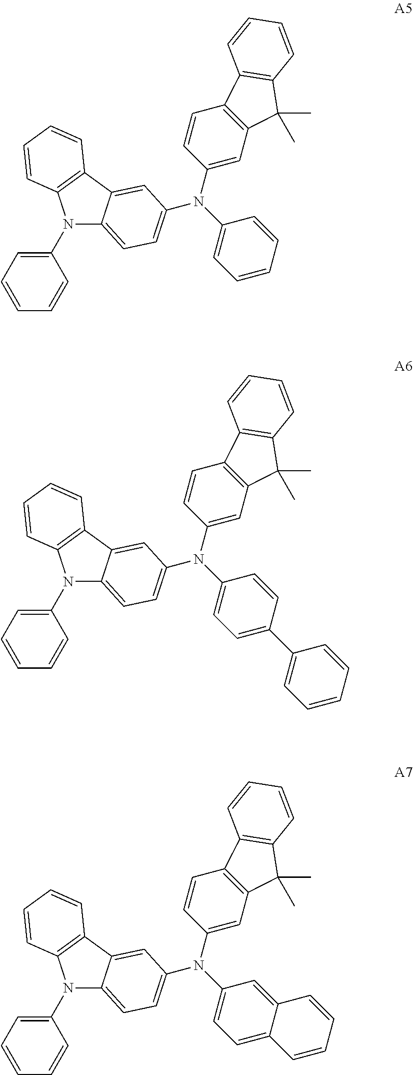 [SMILES: CC1(C)c2ccccc2-c2ccc(N(c3ccccc3)c3ccc4c(c3)c3ccccc3n4-c3ccccc3)cc21 ; CC1(C)c2ccccc2-c2ccc(N(c3ccc(-c4ccccc4)cc3)c3ccc4c(c3)c3ccccc3n4-c3ccccc3)cc21 ; CC1(C)c2ccccc2-c2ccc(N(c3ccc4ccccc4c3)c3ccc4c(c3)c3ccccc3n4-c3ccccc3)cc21]

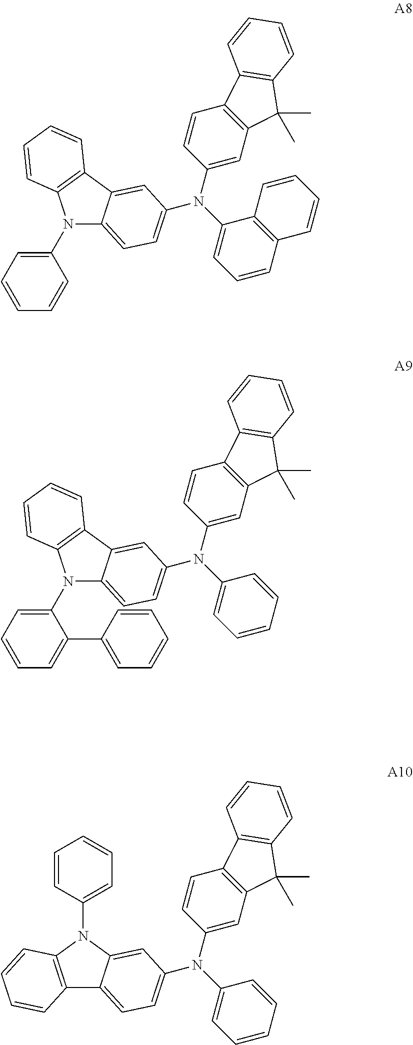 [SMILES: CC1(C)c2ccccc2-c2ccc(N(c3ccc4c(c3)c3ccccc3n4-c3ccccc3)c3cccc4ccccc34)cc21 ; CC1(C)c2ccccc2-c2ccc(N(c3ccccc3)c3ccc4c(c3)c3ccccc3n4-c3ccccc3-c3ccccc3)cc21 ; CC1(C)c2ccccc2-c2ccc(N(c3ccccc3)c3ccc4c5ccccc5n(-c5ccccc5)c4c3)cc21]

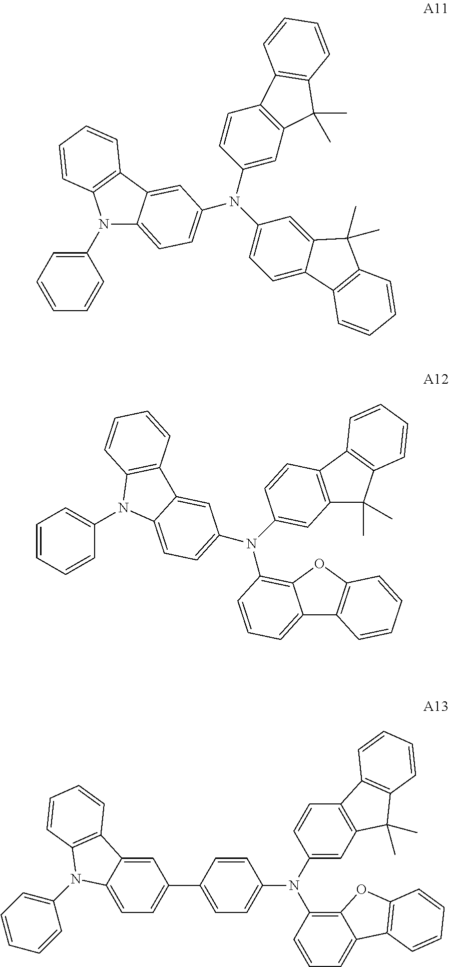 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc4c(c3)c3ccccc3n4-c3ccccc3)c3cccc4c3oc3ccccc34)cc21 ; CC1(C)c2ccccc2-c2ccc(N(c3ccc(-c4ccc5c(c4)c4ccccc4n5-c4ccccc4)cc3)c3cccc4c3oc3ccccc34)cc21]

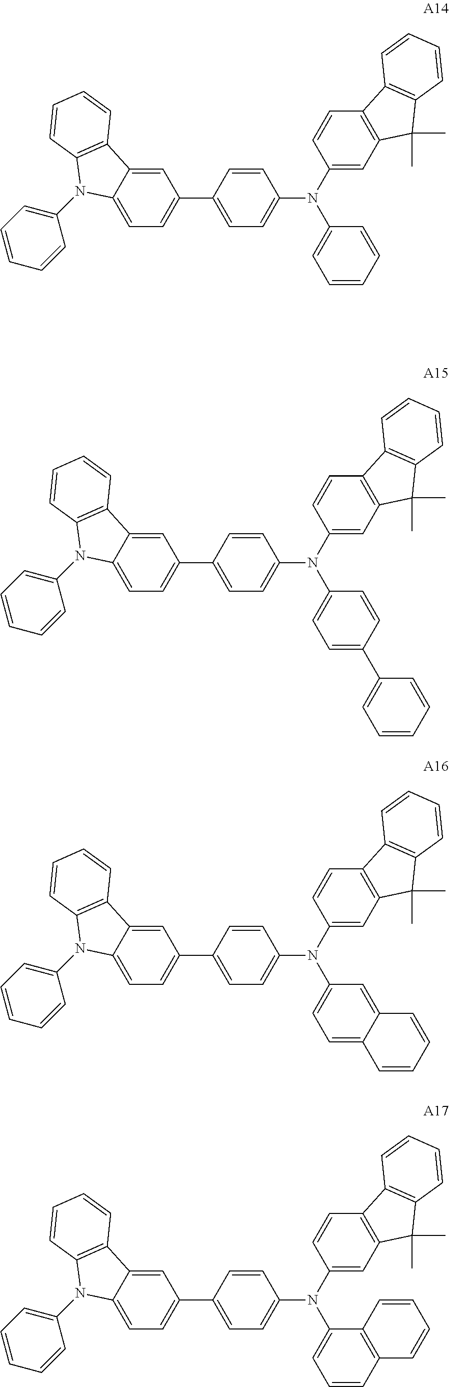 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3ccc4ccccc4c3)cc21 ; CC1(C)c2ccccc2-c2ccc(N(c3ccc(-c4ccc5c(c4)c4ccccc4n5-c4ccccc4)cc3)c3cccc4ccccc34)cc21]

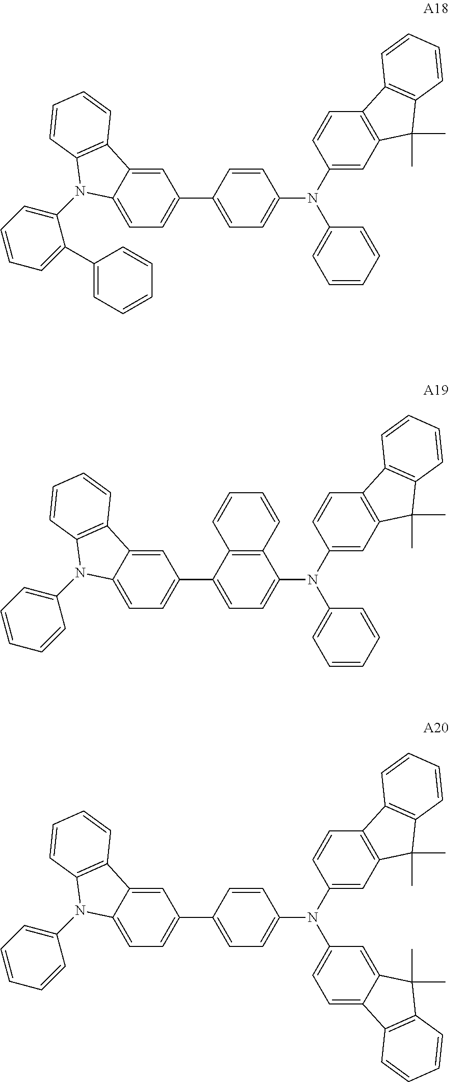 [SMILES: CC1(C)c2ccccc2-c2ccc(N(c3ccccc3)c3ccc(-c4ccc5c(c4)c4ccccc4n5-c4ccccc4-c4ccccc4)cc3)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

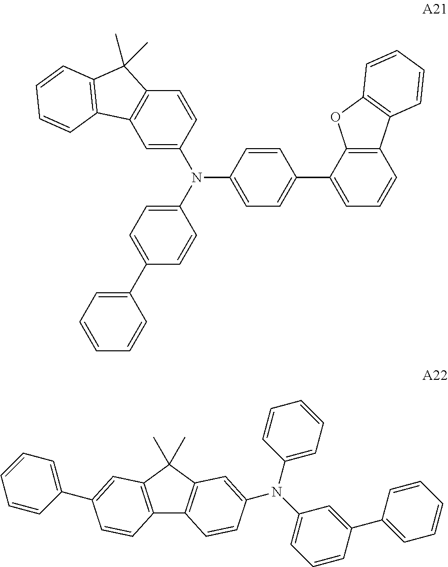 [SMILES: CC1(C)c2ccccc2-c2cc(N(c3ccc(-c4ccccc4)cc3)c3ccc(-c4cccc5c4oc4ccccc45)cc3)ccc21 ; CC1(C)c2cc(-c3ccccc3)ccc2-c2ccc(N(c3ccccc3)c3cccc(-c4ccccc4)c3)cc21]

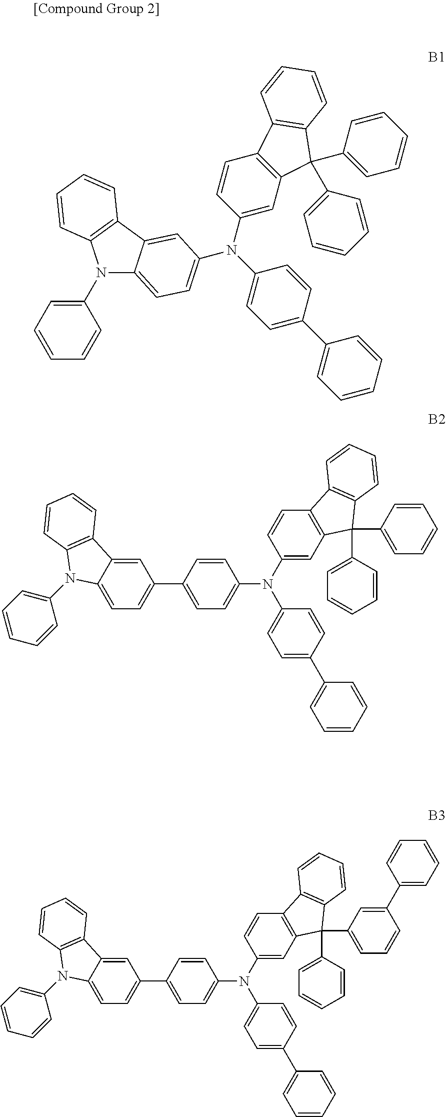 [SMILES: c1ccc(-c2ccc(N(c3ccc4c(c3)C(c3ccccc3)(c3ccccc3)c3ccccc3-4)c3ccc4c(c3)c3ccccc3n4-c3ccccc3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3cccc(-c5ccccc5)c3)c3ccccc3-4)cc2)cc1]

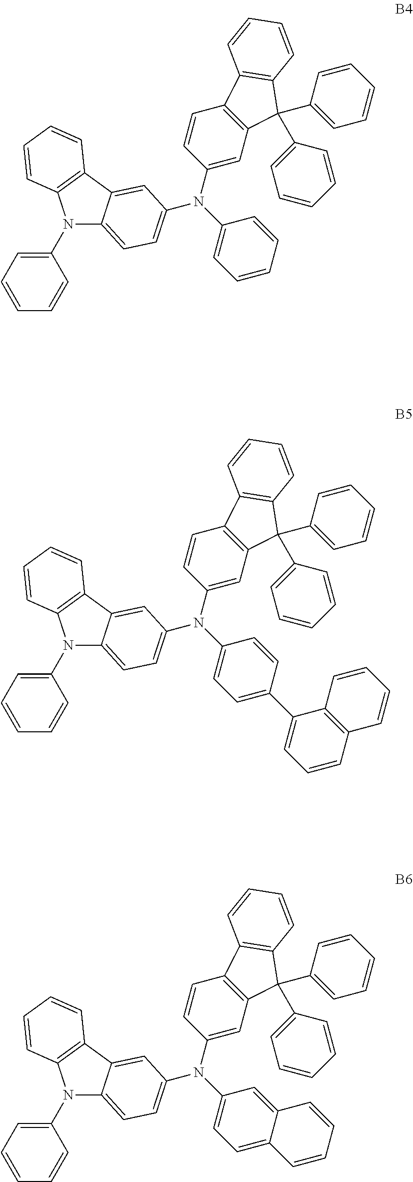 [SMILES: c1ccc(N(c2ccc3c(c2)C(c2ccccc2)(c2ccccc2)c2ccccc2-3)c2ccc3c(c2)c2ccccc2n3-c2ccccc2)cc1 ; c1ccc(-n2c3ccccc3c3cc(N(c4ccc(-c5cccc6ccccc56)cc4)c4ccc5c(c4)C(c4ccccc4)(c4ccccc4)c4ccccc4-5)ccc32)cc1 ; c1ccc(-n2c3ccccc3c3cc(N(c4ccc5c(c4)C(c4ccccc4)(c4ccccc4)c4ccccc4-5)c4ccc5ccccc5c4)ccc32)cc1]

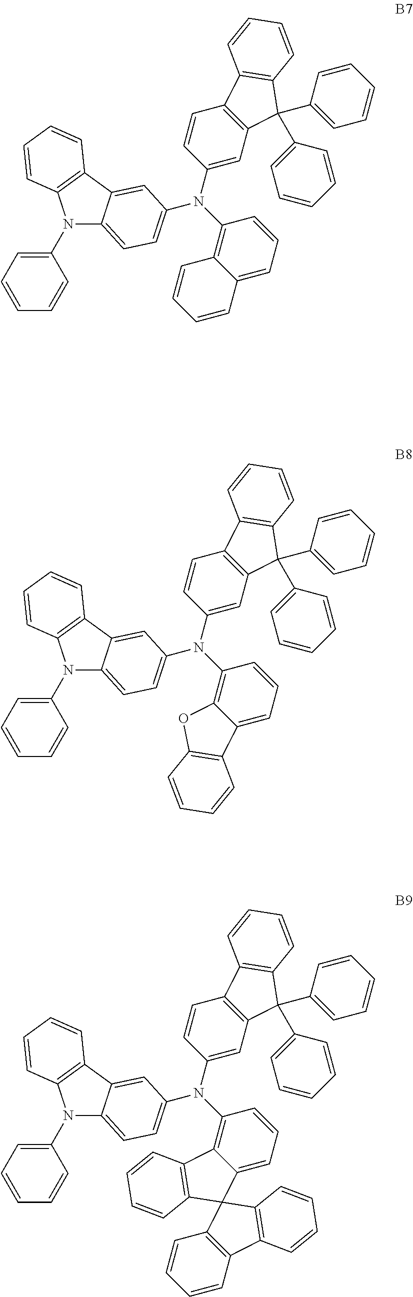 [SMILES: c1ccc(-n2c3ccccc3c3cc(N(c4ccc5c(c4)C(c4ccccc4)(c4ccccc4)c4ccccc4-5)c4cccc5ccccc45)ccc32)cc1 ; c1ccc(-n2c3ccccc3c3cc(N(c4ccc5c(c4)C(c4ccccc4)(c4ccccc4)c4ccccc4-5)c4cccc5c4oc4ccccc45)ccc32)cc1 ; c1ccc(-n2c3ccccc3c3cc(N(c4ccc5c(c4)C(c4ccccc4)(c4ccccc4)c4ccccc4-5)c4cccc5c4-c4ccccc4C54c5ccccc5-c5ccccc54)ccc32)cc1]

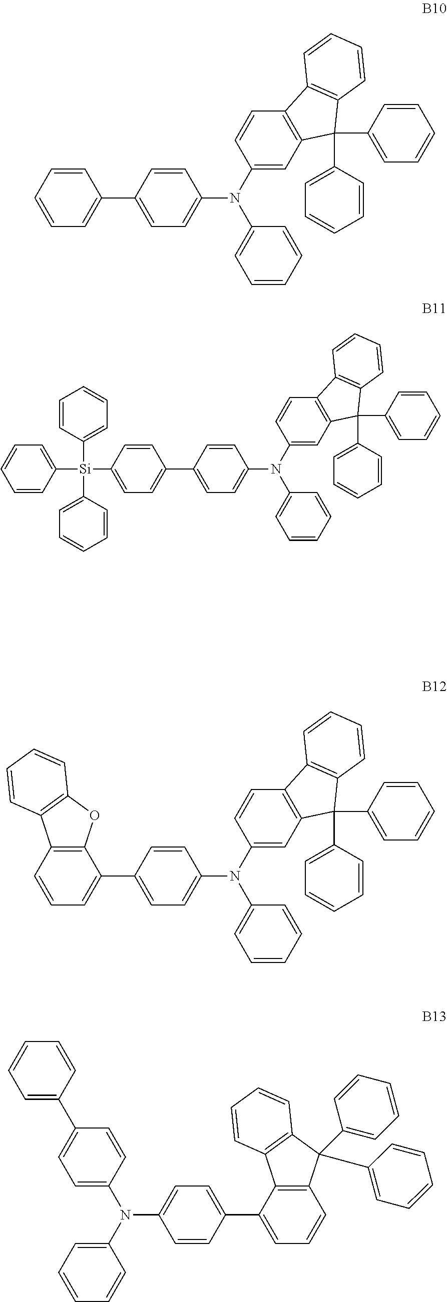 [SMILES: c1ccc(-c2ccc(N(c3ccccc3)c3ccc4c(c3)C(c3ccccc3)(c3ccccc3)c3ccccc3-4)cc2)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1 ; c1ccc(N(c2ccc(-c3cccc4c3oc3ccccc34)cc2)c2ccc3c(c2)C(c2ccccc2)(c2ccccc2)c2ccccc2-3)cc1 ; c1ccc(-c2ccc(N(c3ccccc3)c3ccc(-c4cccc5c4-c4ccccc4C5(c4ccccc4)c4ccccc4)cc3)cc2)cc1]

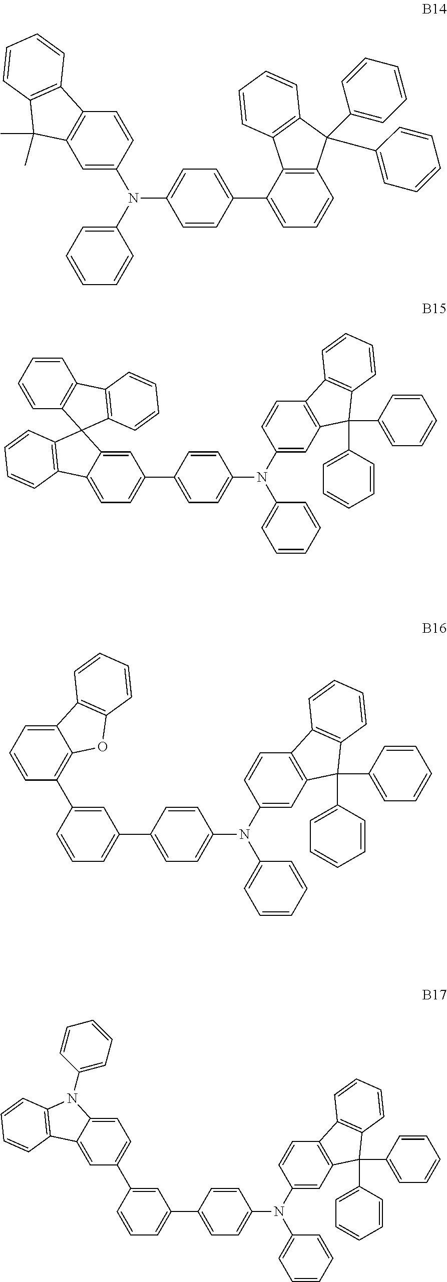 [SMILES: CC1(C)c2ccccc2-c2ccc(N(c3ccccc3)c3ccc(-c4cccc5c4-c4ccccc4C5(c4ccccc4)c4ccccc4)cc3)cc21 ; c1ccc(N(c2ccc(-c3ccc4c(c3)C3(c5ccccc5-c5ccccc53)c3ccccc3-4)cc2)c2ccc3c(c2)C(c2ccccc2)(c2ccccc2)c2ccccc2-3)cc1 ; c1ccc(N(c2ccc(-c3cccc(-c4cccc5c4oc4ccccc45)c3)cc2)c2ccc3c(c2)C(c2ccccc2)(c2ccccc2)c2ccccc2-3)cc1 ; c1ccc(N(c2ccc(-c3cccc(-c4ccc5c(c4)c4ccccc4n5-c4ccccc4)c3)cc2)c2ccc3c(c2)C(c2ccccc2)(c2ccccc2)c2ccccc2-3)cc1]

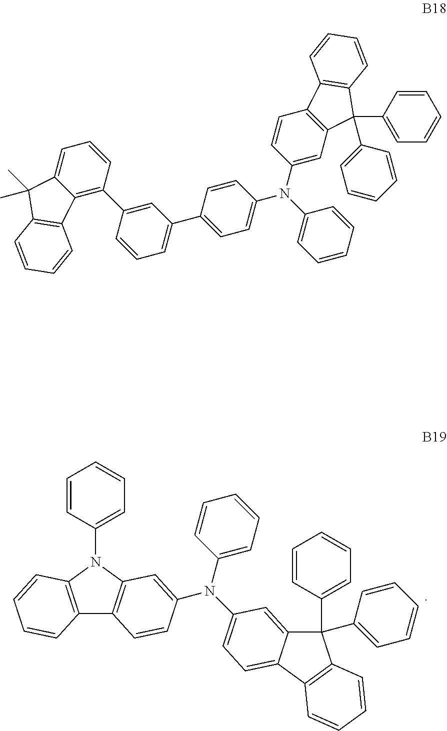 [SMILES: CC1(C)c2ccccc2-c2c(-c3cccc(-c4ccc(N(c5ccccc5)c5ccc6c(c5)C(c5ccccc5)(c5ccccc5)c5ccccc5-6)cc4)c3)cccc21 ; c1ccc(N(c2ccc3c(c2)C(c2ccccc2)(c2ccccc2)c2ccccc2-3)c2ccc3c4ccccc4n(-c4ccccc4)c3c2)cc1]

16. The display device of claim 15, wherein
the hole transport region comprises an amine compound selected from Compound Group 1, and
the p-type charge generation layer comprises an amine compound selected from Compound Group 2.

17. A display device, comprising:
a first light emitting region emitting a first color;
a second light emitting region emitting a second color having a shorter wavelength than the first color;
a third light emitting region emitting a third color having a shorter wavelength than the second color;
a first light emitting element;
a second light emitting element; and
a third light emitting element emitting, wherein
the first light emitting region, the second light emitting region, and the third light emitting region are spaced apart in plan view,
the first, second, and third light emitting elements respectively correspond to the first, second, and third light emitting regions,
each of the first, second, and third light emitting elements includes:
a first electrode;
a second electrode facing the first electrode;
a first light emitting unit disposed between the first electrode and the second electrode and including a hole transport region;
a second light emitting unit disposed between the first light emitting unit and the second electrode; and
a charge generation layer disposed between the first light emitting unit and the second light emitting unit,
the charge generation layer includes:
an n-type charge generation layer disposed as a common layer in the first emission region, the second emission region, and the third emission region; and
a p-type charge generation layer disposed on the n-type charge generation layer,
the p-type charge generation layer includes:
a first p-type charge generation layer overlapping the first light emitting region;
a second p-type charge generation layer overlapping the second light emitting region; and
a third p-type charge generation layer overlapping the third light emitting region,
thicknesses of the first, second, and third p-type charge generation layers satisfy Equation 1, and
the hole transport region and the p-type charge generation layer each independently include an amine compound represented by Formula 1:
T₁>T₂≥T₃ [Equation 1]
wherein in Equation 1,
T₁ is the thickness of the first p-type charge generation layer,
T₂ is the thickness of the second p-type charge generation layer, and
T₃ is the thickness of the third p-type charge generation layer; and 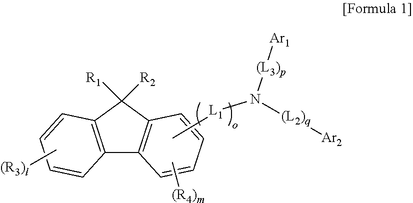
wherein in Formula 1,
Ar₁ and Ar₂ are each independently a substituted or unsubstituted silyl group, a substituted or unsubstituted aryl group having 6 to 60 ring-forming carbon atoms, or a substituted or unsubstituted heteroaryl group having 2 to 60 ring-forming carbon atoms,
L₁ to L₃ are each independently a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 60 ring-forming carbon atoms,
R₁ and R₂ are each independently a substituted or unsubstituted amine group, a substituted or unsubstituted thio group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
R₃ and R₄ are each independently a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
l is an integer from 0 to 4,
m is an integer from 0 to 3, and
o, p, and q are each independently an integer from 0 to 3,
provided that in the amine compound included in the hole transport region, R₁ and R₂ are each independently a substituted or unsubstituted alkyl group having 1 to 30 carbon atoms, and
provided that in the amine compound included in the p-type charge generation layer, R₁ and R₂, are each independently a substituted or unsubstituted amine group, a substituted or unsubstituted thio group, a substituted or unsubstituted oxy group, a substituted or unsubstituted alkenyl group having 2 to 30 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring.

18. The display device of claim 17, wherein
the hole transport region includes a hole injection layer, a hole transport layer, an electron blocking layer, or a combination thereof, and
at least one of the hole injection layer, the hole transport layer, or the electron blocking layer includes the amine compound represented by Formula 1.

19. The display device of claim 17, wherein
the hole transport region includes:
a hole injection layer disposed on the first electrode; and
a hole transport layer disposed on the hole injection layer, and
the hole injection layer includes the amine compound represented by Formula 1.

20. The display device of claim 17, wherein
the hole transport region includes at least one compound selected from Compound Group 1, and
the p-type charge generation layer includes at least one compound selected from Compound Group 2: 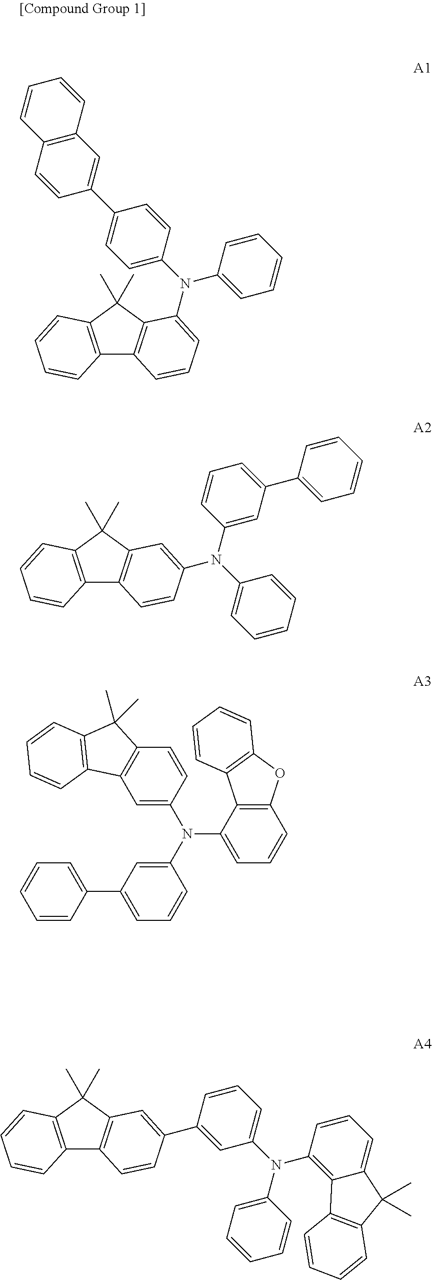 [SMILES: CC1(C)c2ccccc2-c2cccc(N(c3ccccc3)c3ccc(-c4ccc5ccccc5c4)cc3)c21 ; CC1(C)c2ccccc2-c2ccc(N(c3ccccc3)c3cccc(-c4ccccc4)c3)cc21 ; CC1(C)c2ccccc2-c2cc(N(c3cccc(-c4ccccc4)c3)c3cccc4oc5ccccc5c34)ccc21 ; CC1(C)c2ccccc2-c2ccc(-c3cccc(N(c4ccccc4)c4cccc5c4-c4ccccc4C5(C)C)c3)cc21] 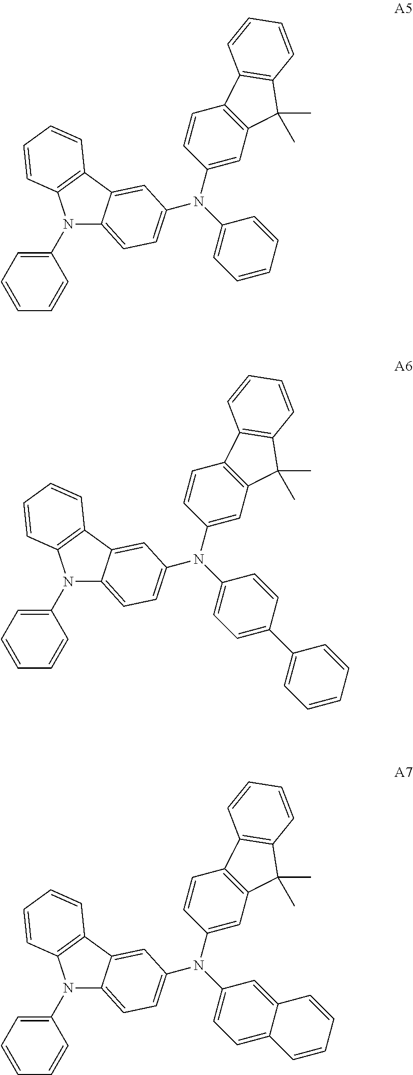 [SMILES: CC1(C)c2ccccc2-c2ccc(N(c3ccccc3)c3ccc4c(c3)c3ccccc3n4-c3ccccc3)cc21 ; CC1(C)c2ccccc2-c2ccc(N(c3ccc(-c4ccccc4)cc3)c3ccc4c(c3)c3ccccc3n4-c3ccccc3)cc21 ; CC1(C)c2ccccc2-c2ccc(N(c3ccc4ccccc4c3)c3ccc4c(c3)c3ccccc3n4-c3ccccc3)cc21] 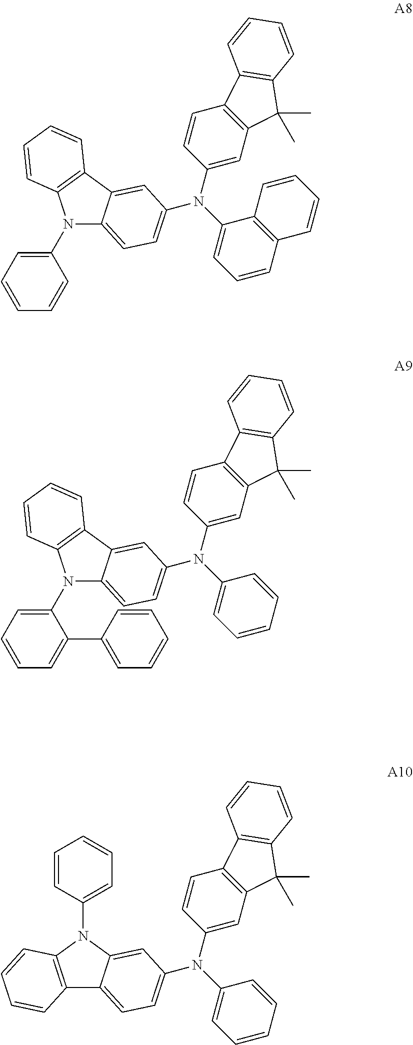 [SMILES: CC1(C)c2ccccc2-c2ccc(N(c3ccc4c(c3)c3ccccc3n4-c3ccccc3)c3cccc4ccccc34)cc21 ; CC1(C)c2ccccc2-c2ccc(N(c3ccccc3)c3ccc4c(c3)c3ccccc3n4-c3ccccc3-c3ccccc3)cc21 ; CC1(C)c2ccccc2-c2ccc(N(c3ccccc3)c3ccc4c5ccccc5n(-c5ccccc5)c4c3)cc21] 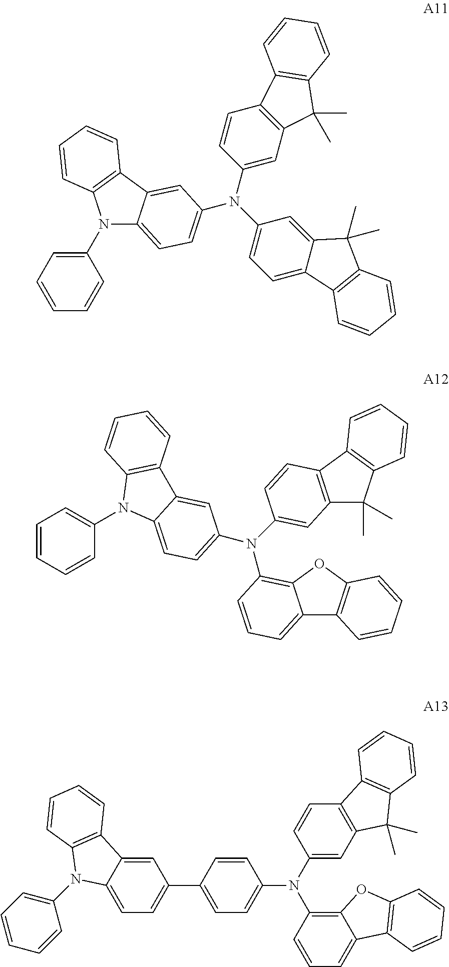 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc4c(c3)c3ccccc3n4-c3ccccc3)c3cccc4c3oc3ccccc34)cc21 ; CC1(C)c2ccccc2-c2ccc(N(c3ccc(-c4ccc5c(c4)c4ccccc4n5-c4ccccc4)cc3)c3cccc4c3oc3ccccc34)cc21] 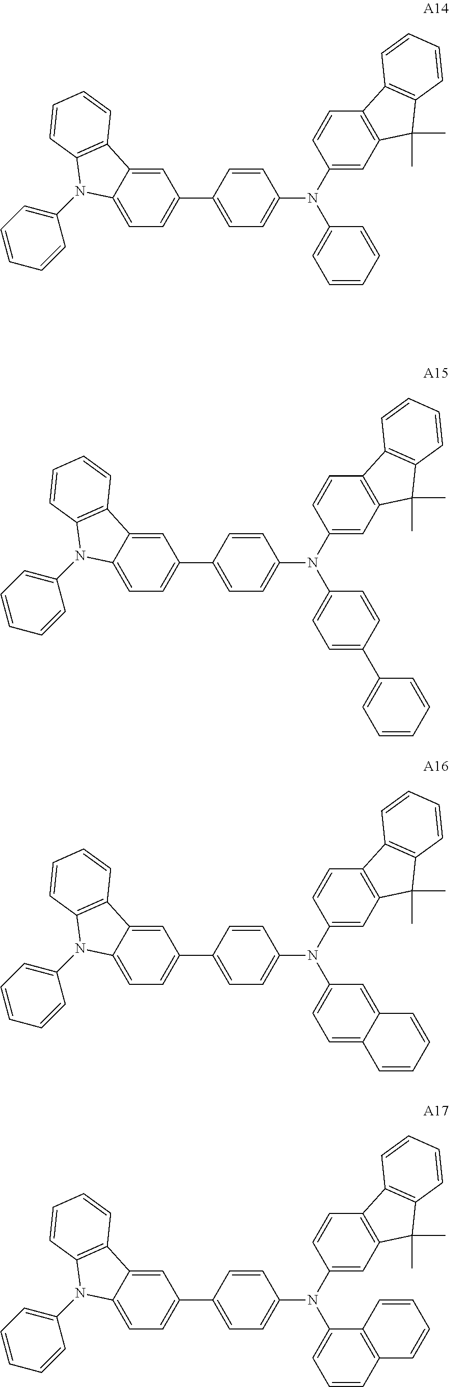 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3ccc4ccccc4c3)cc21 ; CC1(C)c2ccccc2-c2ccc(N(c3ccc(-c4ccc5c(c4)c4ccccc4n5-c4ccccc4)cc3)c3cccc4ccccc34)cc21] 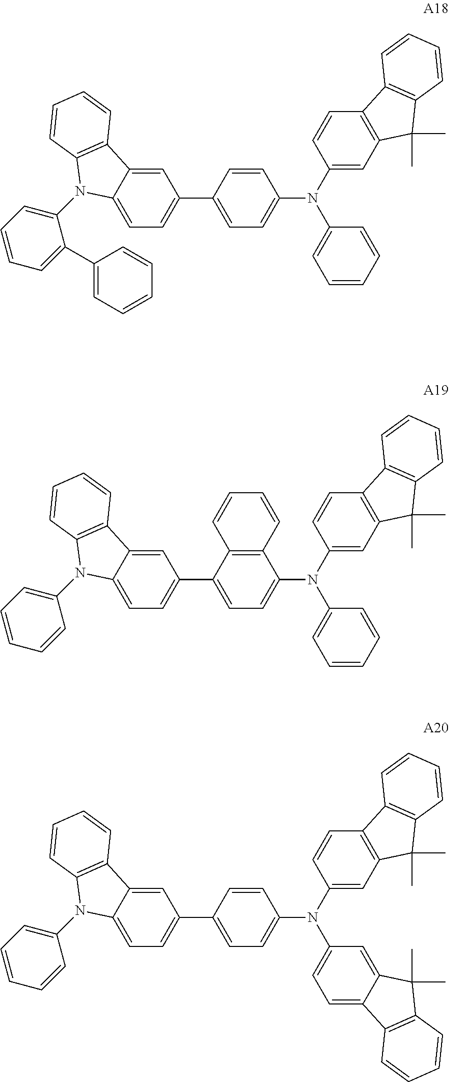 [SMILES: CC1(C)c2ccccc2-c2ccc(N(c3ccccc3)c3ccc(-c4ccc5c(c4)c4ccccc4n5-c4ccccc4-c4ccccc4)cc3)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21] 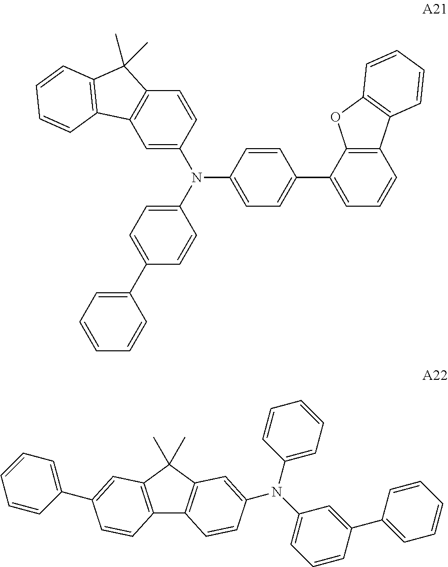 [SMILES: CC1(C)c2ccccc2-c2cc(N(c3ccc(-c4ccccc4)cc3)c3ccc(-c4cccc5c4oc4ccccc45)cc3)ccc21 ; CC1(C)c2cc(-c3ccccc3)ccc2-c2ccc(N(c3ccccc3)c3cccc(-c4ccccc4)c3)cc21] 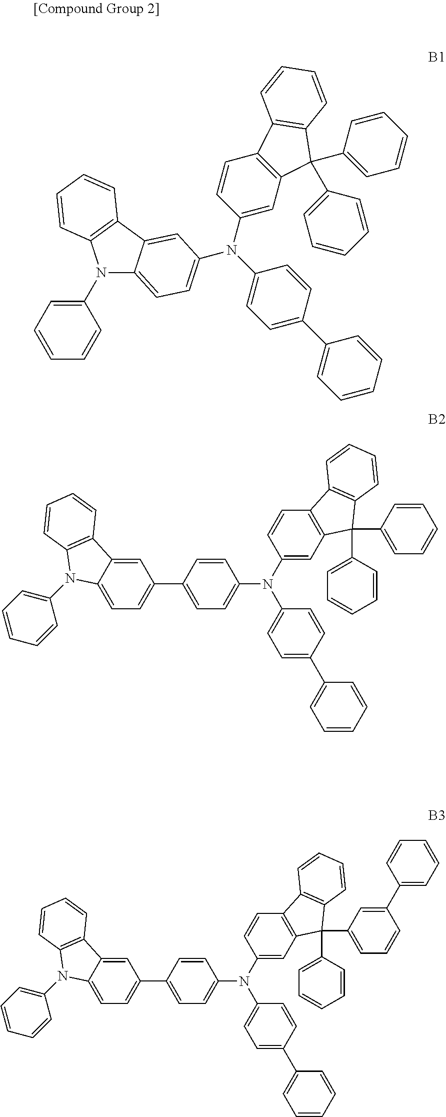 [SMILES: c1ccc(-c2ccc(N(c3ccc4c(c3)C(c3ccccc3)(c3ccccc3)c3ccccc3-4)c3ccc4c(c3)c3ccccc3n4-c3ccccc3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3cccc(-c5ccccc5)c3)c3ccccc3-4)cc2)cc1] 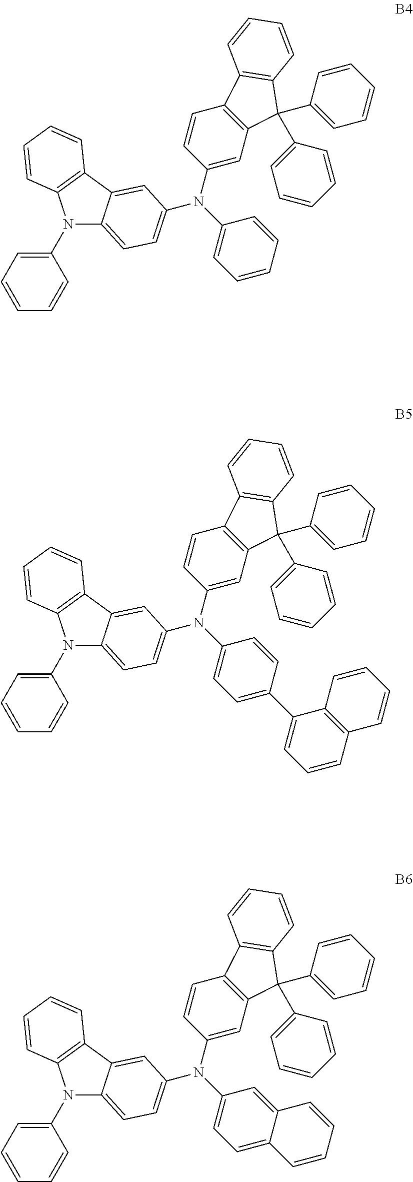 [SMILES: c1ccc(N(c2ccc3c(c2)C(c2ccccc2)(c2ccccc2)c2ccccc2-3)c2ccc3c(c2)c2ccccc2n3-c2ccccc2)cc1 ; c1ccc(-n2c3ccccc3c3cc(N(c4ccc(-c5cccc6ccccc56)cc4)c4ccc5c(c4)C(c4ccccc4)(c4ccccc4)c4ccccc4-5)ccc32)cc1 ; c1ccc(-n2c3ccccc3c3cc(N(c4ccc5c(c4)C(c4ccccc4)(c4ccccc4)c4ccccc4-5)c4ccc5ccccc5c4)ccc32)cc1] 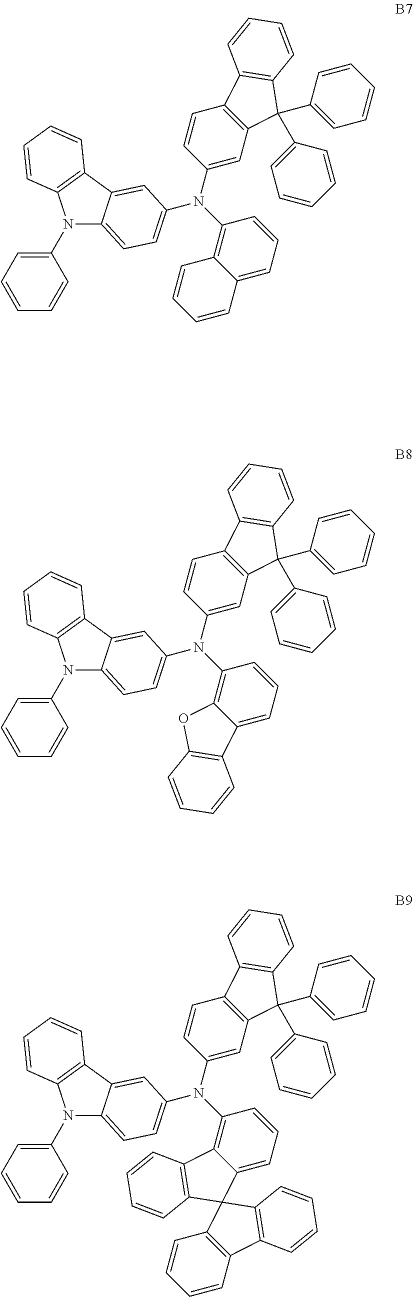 [SMILES: c1ccc(-n2c3ccccc3c3cc(N(c4ccc5c(c4)C(c4ccccc4)(c4ccccc4)c4ccccc4-5)c4cccc5ccccc45)ccc32)cc1 ; c1ccc(-n2c3ccccc3c3cc(N(c4ccc5c(c4)C(c4ccccc4)(c4ccccc4)c4ccccc4-5)c4cccc5c4oc4ccccc45)ccc32)cc1 ; c1ccc(-n2c3ccccc3c3cc(N(c4ccc5c(c4)C(c4ccccc4)(c4ccccc4)c4ccccc4-5)c4cccc5c4-c4ccccc4C54c5ccccc5-c5ccccc54)ccc32)cc1] 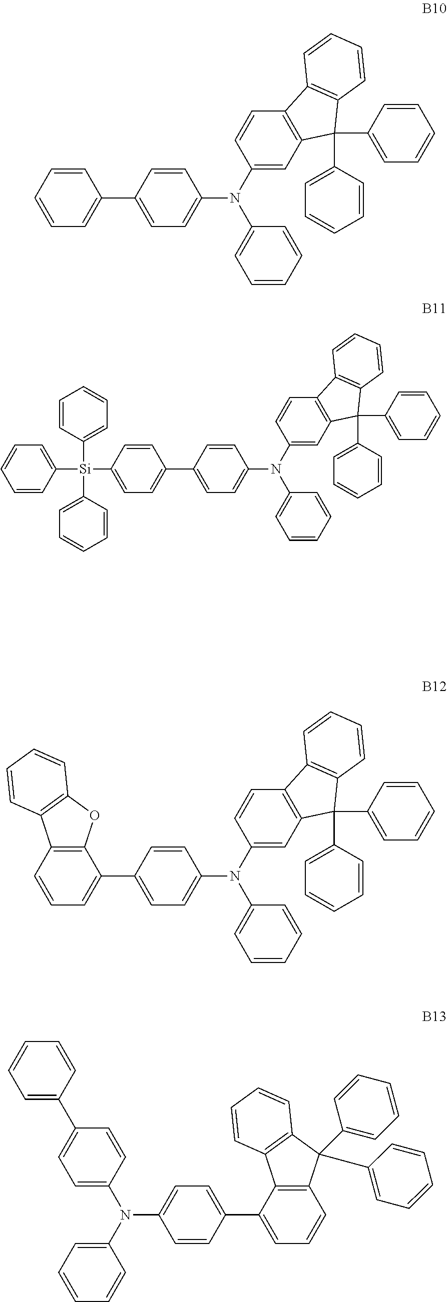 [SMILES: c1ccc(-c2ccc(N(c3ccccc3)c3ccc4c(c3)C(c3ccccc3)(c3ccccc3)c3ccccc3-4)cc2)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1 ; c1ccc(N(c2ccc(-c3cccc4c3oc3ccccc34)cc2)c2ccc3c(c2)C(c2ccccc2)(c2ccccc2)c2ccccc2-3)cc1 ; c1ccc(-c2ccc(N(c3ccccc3)c3ccc(-c4cccc5c4-c4ccccc4C5(c4ccccc4)c4ccccc4)cc3)cc2)cc1] 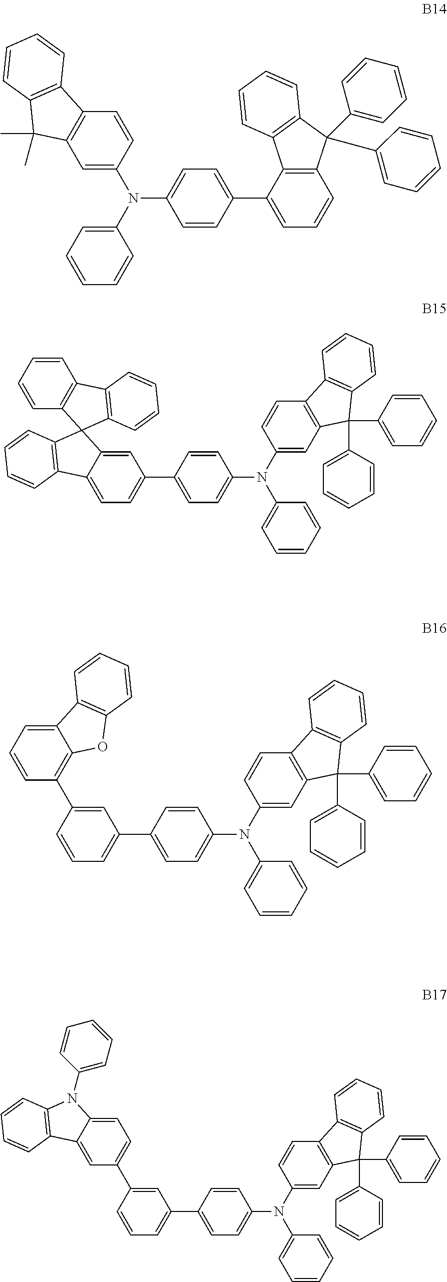 [SMILES: CC1(C)c2ccccc2-c2ccc(N(c3ccccc3)c3ccc(-c4cccc5c4-c4ccccc4C5(c4ccccc4)c4ccccc4)cc3)cc21 ; c1ccc(N(c2ccc(-c3ccc4c(c3)C3(c5ccccc5-c5ccccc53)c3ccccc3-4)cc2)c2ccc3c(c2)C(c2ccccc2)(c2ccccc2)c2ccccc2-3)cc1 ; c1ccc(N(c2ccc(-c3cccc(-c4cccc5c4oc4ccccc45)c3)cc2)c2ccc3c(c2)C(c2ccccc2)(c2ccccc2)c2ccccc2-3)cc1 ; c1ccc(N(c2ccc(-c3cccc(-c4ccc5c(c4)c4ccccc4n5-c4ccccc4)c3)cc2)c2ccc3c(c2)C(c2ccccc2)(c2ccccc2)c2ccccc2-3)cc1] 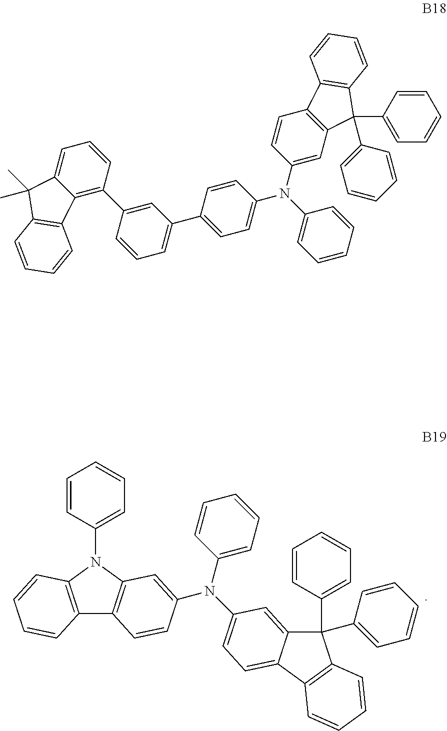 [SMILES: CC1(C)c2ccccc2-c2c(-c3cccc(-c4ccc(N(c5ccccc5)c5ccc6c(c5)C(c5ccccc5)(c5ccccc5)c5ccccc5-6)cc4)c3)cccc21 ; c1ccc(N(c2ccc3c(c2)C(c2ccccc2)(c2ccccc2)c2ccccc2-3)c2ccc3c4ccccc4n(-c4ccccc4)c3c2)cc1]
